(19) United States
(12) Patent Application Publication
(10) Pub. No.: US 2026/0147277 A1
(43) Pub. Date: May 28, 2026

(54) TRANSFER FILM, PATTERN FORMING METHOD, LAMINATE, AND SEMICONDUCTOR PACKAGE

(71) Applicant: FUJIFILM Corporation, Tokyo (JP)

(72) Inventor: Keigo Yamaguchi, Shizuoka (JP)

(21) Appl. No.: 19/456,188

(22) Filed: Jan. 22, 2026

Related U.S. Application Data
(63) Continuation of application No. PCT/JP2024/030470, filed on Aug. 27, 2024.

(30) Foreign Application Priority Data
Aug. 30, 2023 (JP) 2023-140312

(51) Int. Cl. G03F 7/038; B32B 27/08; B32B 27/20; B32B 27/26; B32B 27/30; G03F 7/11; G03F 7/16; H10W 70/695

(52) U.S. Cl. CPC G03F 7/0388; B32B 27/08; B32B 27/20; B32B 27/26; B32B 27/306; G03F 7/0387; G03F 7/11; G03F 7/161; B32B 2250/03; B32B 2250/24; B32B 2307/206; B32B 2307/7376; B32B 2457/14; H10W 70/695

(57) ABSTRACT

An object of the present invention is to provide a transfer film capable of forming a film which contributes to suppressing migration between wirings. The transfer film of the present invention includes, in the following order, a temporary support, a water-soluble resin layer, and a photosensitive composition layer, in which the photosensitive composition layer contains at least one specific compound selected from the group consisting of a polyimide precursor, a polyimide, a polybenzoxazole precursor, a polybenzoxazole, a phenol resin, an epoxy resin, a polyphenylene ether resin, a silicone resin, a benzocyclobutene resin, a fluorene resin, a liquid crystal polymer, a polyethersulfone, a polyarylate, a polyetherimide, a polybenzimidazole, a polyphenylsulfone, a polycarbonate, an acrylonitrile-butadiene-styrene copolymer resin, and a polyphenylene sulfide.

### CROSS-REFERENCE TO RELATED APPLICATIONS

This application is a Continuation of PCT International Application No. PCT/JP2024/030470 filed on Aug. 27, 2024, which claims priority under 35 U.S.C. § 119(a) to Japanese Patent Application No. 2023-140312 filed on Aug. 30, 2023. The above applications are hereby expressly incorporated by reference, in their entirety, into the present application.

### BACKGROUND OF THE INVENTION

### 1. Field of the Invention

The present invention relates to a transfer film, a pattern forming method, a laminate, and a semiconductor package.

### 2. Description of the Related Art

In a display device provided with a touch panel such as a capacitive input device (for example, a display device such as an organic electroluminescence (EL) display device and a liquid crystal display device), a conductive pattern such as an electrode pattern corresponding to a sensor in a visual recognition portion and a wiring for a peripheral wiring portion and a lead-out wiring portion is provided inside the touch panel. An insulating film is used for forming, protecting, and the like of such an electrode pattern and a conductive pattern. Similarly, in a build-up substrate or the like of a multi-layer printed wiring board and a semiconductor package, the insulating film is provided between each layer for the purpose of insulating and protecting wirings.

As a composition capable of forming the insulating layer as described above, for example, JP2020-045385A discloses a resin composition for an insulating film of a high-frequency circuit board, the resin composition containing a resin, a porous compound, and a heterocyclic compound.

### SUMMARY OF THE INVENTION

From the viewpoint of manufacturing efficiency, the insulating film as described above is preferably formed by a transfer film. In addition, as described above, for example, in the multi-layer printed substrate and the semiconductor package, the insulating film is provided above and below a wiring layer, but in such an aspect, it is required to suppress migration between the wirings.

As a result of manufacturing the transfer film disclosed in JP2020-045385A and examining characteristics thereof, the present inventors have found that there is room for improvement in migration resistance evaluated using a film formed by the transfer film.

Therefore, an object of the present invention is to provide a transfer film capable of forming a film which contributes to suppressing migration between wirings.

Another object of the present invention is to provide a pattern forming method, a laminate, and a semiconductor package, relating to the above-described transfer film.

As a result of conducting an extensive investigation to achieve the objects, the present inventors have found that the objects can be achieved by the following constitution.

[1] A transfer film comprising, in the following order:
a temporary support;
a water-soluble resin layer; and
a photosensitive composition layer,
in which the photosensitive composition layer contains at least one specific compound selected from the group consisting of a polyimide precursor, a polyimide, a polybenzoxazole precursor, a polybenzoxazole, a phenol resin, an epoxy resin, a polyphenylene ether resin, a silicone resin, a benzocyclobutene resin, a fluorene resin, a liquid crystal polymer, a polyethersulfone, a polyarylate, a polyetherimide, a polybenzimidazole, a polyphenylsulfone, a polycarbonate, an acrylonitrile-butadiene-styrene copolymer resin, and a polyphenylene sulfide.

[2] The transfer film according to [1],
in which the photosensitive composition layer contains a photopolymerization initiator.

[3] The transfer film according to [1] or [2],
in which a surface free energy measured by a measurement X is 40 mJ/m² or more,
the measurement X: in a case where a laminate is obtained by bonding the transfer film and a base material in a state in which the photosensitive composition layer of the transfer film faces the base material, the temporary support is peeled off from the laminate, an entire surface of the photosensitive composition layer is exposed from an exposed water-soluble resin layer side to remove the water-soluble resin layer, and an exposed photosensitive composition layer is heated at 200° C. for 1.5 hours in a nitrogen atmosphere to obtain a cured layer, a surface free energy of a surface of the cured layer, opposite to the base material side, is measured.

[4] The transfer film according to [3],
in which a polarity component of the surface free energy is 10 mJ/m² or more.

[5] The transfer film according to any one of [1] to [4],
in which at least one of a requirement 1 or a requirement 2 is satisfied,
the requirement 1: the specific compound has an ethylenically unsaturated double bond,
the requirement 2: the photosensitive composition layer contains a compound having an ethylenically unsaturated double bond.

[6] The transfer film according to [5],
in which a molecular weight of the compound having an ethylenically unsaturated double bond is 800 or less.

[7] The transfer film according to any one of [1] to [6],
in which the specific compound includes at least one selected from the group consisting of a polyimide precursor, a polyimide, a polybenzoxazole precursor, and a polybenzoxazole.

[8] The transfer film according to [2],
in which the photopolymerization initiator includes a compound represented by Formula (P1) described later.

[9] The transfer film according to any one of [1] to [8],
in which the photosensitive composition layer contains a chain transfer agent.

[10] The transfer film according to any one of [1] to [9],
in which the photosensitive composition layer contains a filler.

[11] The transfer film according to [10],
in which the filler includes at least one selected from the group consisting of silicon dioxide, boron nitride, barium sulfate, and silicate.

[12] The transfer film according to [10] or [11],
in which an average particle diameter of the filler is 300 nm or less.

[13] The transfer film according to any one of [10] to [12],
in which an average particle diameter of the filler is 150 nm or less.

[14] The transfer film according to any one of [10] to [13],
in which a content of the filler is 30.0% by mass or more with respect to a total mass of the photosensitive composition layer.

[15] The transfer film according to any one of [10] to [14],
in which a content of the filler is 90.0% by mass or less with respect to a total mass of the photosensitive composition layer.

[16] The transfer film according to any one of [1] to [15],
in which a film thickness of the photosensitive composition layer is 3 to 30 μm.

[17] The transfer film according to any one of [1] to [16],
in which a film thickness of the water-soluble resin layer is 5 μm or less.

[18] The transfer film according to any one of [1] to [17],
in which the water-soluble resin layer contains polyvinyl alcohol.

[19] The transfer film according to [18],
in which a content of the polyvinyl alcohol is 15.0% to 90.0% by mass with respect to a total mass of the water-soluble resin layer.

[20] The transfer film according to any one of [1] to [19],
in which the water-soluble resin layer contains hydroxypropyl methyl cellulose.

[21] The transfer film according to any one of [1] to [20],
in which the transfer film is used for forming an insulating film.

[22] A pattern forming method comprising:
a step 1 of obtaining a laminate by bonding the transfer film according to any one of [1] to [21] and a base material in a state in which the photosensitive composition layer of the transfer film faces the base material;
a step 2 of removing the temporary support from the laminate obtained in the step 1;
a step 3 of exposing the photosensitive composition layer from the water-soluble resin layer side of the laminate from which the temporary support is removed in the step 2 in a patterned manner; and
a step 4 of removing the water-soluble resin layer and an unexposed photosensitive composition layer from the pattern-exposed laminate to form a pattern having a via.

[23] A laminate comprising:
a pattern formed by the pattern forming method according to [22].

[24] A semiconductor package comprising:
the laminate according to [23].

According to the present invention, it is possible to provide a transfer film capable of forming a film which contributes to suppressing migration between wirings. In addition, according to the present invention, it is also possible to provide a pattern forming method, a laminate, and a semiconductor package, relating to the above-described transfer film.

### BRIEF DESCRIPTION OF THE DRAWINGS

FIG. 1 is a schematic view showing an example of a layer configuration of a transfer film.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, a numerical range expressed using “to” means a range that includes the preceding and succeeding numerical values of “to” as a lower limit value and an upper limit value, respectively.

In addition, in the present specification, in a case where there are two or more components corresponding to a certain component, “content” of such a component means the total content of the two or more components.

In the present specification, regarding numerical ranges that are described stepwise, an upper limit value or a lower limit value described in a numerical range may be replaced with an upper limit value or a lower limit value of another stepwise numerical range. In addition, regarding the numerical range described in the present specification, an upper limit value or a lower limit value described in a numerical value may be replaced with a value described in Examples.

In the present specification, a combination of two or more preferred aspects is a more preferred aspect.

A term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C.

In the present specification, “transparent” means that an average transmittance of visible light having a wavelength of 400 nm to 700 nm is 80% or more, preferably 90% or more. In addition, the average transmittance of visible light is a value measured by using a spectrophotometer, and for example, can be measured by using a spectrophotometer U-3310 manufactured by Hitachi, Ltd.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, “solid content” of a photosensitive composition layer means components which form a film formed from the photosensitive composition layer. Typically, in a case where the photosensitive composition layer contains a solvent (for example, an organic solvent, water, and the like), the “solid content” means all components excluding the solvent. In addition, in a case where the components are components which form the film, the components are considered to be solid contents even in a case where the components are liquid components.

In the present specification, “solid content” of a water-soluble resin layer means all components excluding a solvent (for example, an organic solvent, water, and the like), from components that form the water-soluble resin layer.

In the present specification, unless otherwise specified, a content ratio of each repeating unit of a resin is a molar ratio.

In the present specification, unless otherwise specified, a molecular weight in a case of a molecular weight distribution is a weight-average molecular weight. In the present specification, a weight-average molecular weight (Mw) and a number-average molecular weight (Mn) are values in terms of polystyrene by gel permeation chromatography (GPC).

In the present specification, “(meth)acrylic acid” is a concept including both acrylic acid and methacrylic acid; “(meth)acryloyl group” is a concept including both an acryloyl group and a methacryloyl group; “(meth)acrylate” is a concept including both acrylate and methacrylate; and “(meth)acrylamide group” is a concept including both an acrylamide group and a methacrylamide group.

A bonding direction of a divalent group (for example, —CO—O—) described in the present specification is not limited unless otherwise specified. For example, in a case where Y in a compound represented by a formula “X—Y—Z” is —CO—O—, the compound may be “X—O—CO—Z” or “X—CO—O—Z”.

The compounds described in the present specification may include, unless otherwise specified, isomers (compounds having the same number of atoms but having different structures), optical isomers, and isotopes thereof. In addition, only one kind or a plurality of kinds of the isomers and the isotopes may be included.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by producing a section to be measured using an ultramicrotome, measuring thicknesses of any five points, and arithmetically averaging the values.

In the present specification, a boiling point means a boiling point at normal pressure (1 atm, 760 mmHg) unless otherwise specified.

In the present specification, a refractive index is a value measured with an ellipsometer at a wavelength of 550 nm unless otherwise specified.

### [Transfer Film]

Hereinafter, the transfer film according to the embodiment of the present invention will be described in detail.

The transfer film according to the embodiment of the present invention includes, in the following order, a temporary support, a water-soluble resin layer, and a photosensitive composition layer, in which the photosensitive composition layer contains at least one specific compound selected from the group consisting of a polyimide precursor, a polyimide, a polybenzoxazole precursor, a polybenzoxazole, a phenol resin, an epoxy resin, a polyphenylene ether resin, a silicone resin, a benzocyclobutene resin, a fluorene resin, a liquid crystal polymer, a polyethersulfone, a polyarylate, a polyetherimide, a polybenzimidazole, a polyphenylsulfone, a polycarbonate, an acrylonitrile-butadiene-styrene copolymer resin, and a polyphenylene sulfide.

The reason why the transfer film having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

In the transfer film according to the embodiment of the present invention, a film formed by containing a predetermined specific compound in a photosensitive composition layer has excellent heat resistance. Furthermore, in the transfer film, since the water-soluble resin layer is included on the photosensitive composition layer, characteristics of a surface of a cured film derived from the photosensitive composition layer on the water-soluble resin layer side are affected. As a result, adhesiveness between the above-described cured film and a layer laminated on a surface side of the cured film, on which the water-soluble resin layer is removed, is improved, and the influence of moisture and the like can be blocked. It is presumed that, due to these actions, a film formed from the transfer film according to the embodiment of the present invention can suppress migration between wirings.

Hereinafter, the characteristic that the film formed from the transfer film according to the embodiment of the present invention can suppress migration between wirings is also simply referred to as “excellent migration suppression”.

As described above, the transfer film according to the embodiment of the present invention includes, in the following order, a temporary support, a water-soluble resin layer, and a photosensitive composition layer.

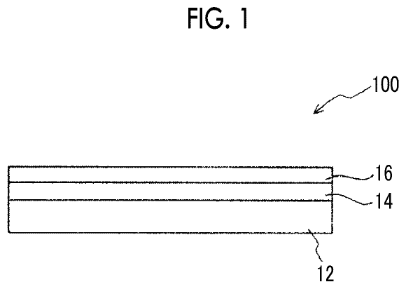

FIG. 1 is a schematic cross-sectional view showing an example of the embodiment of the transfer film.

A transfer film 100 shown in FIG. 1 has a configuration in which a temporary support 12, a water-soluble resin layer 14, and a photosensitive composition layer 16 are laminated in this order.

The transfer film 100 shown in FIG. 1 may include other layers (not shown), and for example, may include a cover film on a surface of the photosensitive composition layer 16 opposite to the water-soluble resin layer 14. It is preferable that the photosensitive composition layer 16 and the water-soluble resin layer 14 are adjacent to each other. Hereinafter, each member included in the transfer film will be described in detail.

### [Temporary Support]

The transfer film includes a temporary support.

The temporary support is a member which supports the photosensitive composition layer, and is finally removed by a peeling treatment. From the viewpoint of excellent pattern formability, it is preferable that the temporary support is removed before exposure. The above-described pattern formability is intended to mean a characteristic that a pattern having a size designed by photolithography is easily formed, and for example, means that a pattern corresponding to a size of an opening portion of a mask is easily formed in a case where the pattern is formed using the mask.

The temporary support may have a monolayer structure or a multilayer structure.

The temporary support is preferably a film and more preferably a resin film.

As the temporary support, a film which has flexibility and does not generate significant deformation, contraction, or stretching under pressure or under pressure and heating is also preferable. Examples of the above-described film include a polyethylene terephthalate (PET) film (for example, a biaxially stretched polyethylene terephthalate film and the like), a polymethyl methacrylate film, a cellulose triacetate film, a polystyrene film, a polyimide film, and a polycarbonate film; and a polyethylene terephthalate film is preferable. In addition, it is preferable that the temporary support does not have deformation such as wrinkles and scratches.

It is preferable that the temporary support has high transparency. Specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit thereof is preferably less than 100%. Examples of a preferred value of any of the transmittances at each of the wavelengths described above include 87%, 92%, and 98%.

It is preferable that a haze of the temporary support is small. Specifically, a haze value of the temporary support is preferably 2% or less, more preferably 0.5% or less, and still more preferably 0.1% or less. The lower limit thereof is preferably 0% or more.

It is preferable that the number of fine particles, foreign substances, and defects included in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is preferably 5 to 200 μm, and from the viewpoint of ease of handling and general-purpose properties, it is more preferably 5 to 150 μm, still more preferably 5 to 50 μm, and particularly preferably 5 to 35 μm.

The thickness of the temporary support can be calculated as an average value of 5 random points measured by cross-sectional observation with a scanning electron microscope (SEM).

In order to improve adhesiveness between the temporary support and the adjacent layer, the temporary support may be surface-modified by UV irradiation, corona discharge, plasma, or the like.

In a case where the surface is modified by UV irradiation, an exposure amount of the UV irradiation is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode, all of which emit light in a wavelength range of 150 to 450 nm.

The lamp output and the illuminance can be appropriately adjusted.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

The temporary support may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

Examples of the temporary support include temporary supports described in paragraphs 0017 and 0018 of JP2014-085643A, paragraphs 0019 to 0026 of JP2016-027363A, paragraphs 0041 to 0057 of WO2012/081680A, and paragraphs 0029 to 0040 of WO2018/179370A, the contents of which are incorporated in the present specification.

The temporary support may have a layer (lubricant layer) containing fine particles on one or both surfaces of the temporary support, for the purpose of imparting handleability. A diameter of the fine particles contained in the lubricant layer is preferably 0.05 to 0.8 μm. A film thickness of the lubricant layer is preferably 0.05 to 1.0 μm.

Examples of a commercially available product of the temporary support include LUMIRROR 16FB40, LUMIRROR 16KS40, LUMIRROR #38-U48, LUMIRROR #75-U34, and LUMIRROR #25T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

### [Water-Soluble Resin Layer]

The transfer film includes a water-soluble resin layer. The water-soluble resin layer is a layer containing a water-soluble resin.

From the viewpoint of being easily removed in a case of forming a pattern by the transfer film, the water-soluble resin layer is preferably soluble in water or an alkali developer. The alkali developer will be described later.

### <Water-Soluble Resin>

The water-soluble resin is intended to be a resin having a solubility of 0.1 g or more in 100 g of water at a liquid temperature of 22° C. and a pH of 7.0.

Examples of the water-soluble resin include polyvinyl alcohol (PVA), polyvinylpyrrolidone (PVP), a water-soluble cellulose derivative, a water-soluble salt of carboxyalkyl starch, polyacrylamide, a water-soluble polyamide, a water-soluble salt of poly(meth)acrylic acid, gelatin, polyethylene oxide, a polyvinyl ether/maleic acid anhydride polymer, and a styrene/maleic acid copolymer; and PVA, PVP, or a water-soluble cellulose ether is preferable.

Examples of the above-described water-soluble cellulose derivative include a water-soluble cellulose ether and a water-soluble salt of carboxyalkyl cellulose. Examples of the water-soluble cellulose ether include hydroxypropyl methyl cellulose (HPMC), hydroxyethyl methyl cellulose (HEMC), methyl cellulose (MC), and hydroxyethyl cellulose (HEC); and HPMC is preferable.

Examples of the water-soluble salt of carboxyalkyl cellulose include a metal salt (for example, an alkali metal salt and an alkaline earth metal salt) of carboxymethyl cellulose (CMC) and carboxyethyl cellulose.

As the water-soluble cellulose derivative, a water-soluble cellulose ether or a metal salt of carboxymethyl cellulose is preferable, and HPMC is more preferable.

The water-soluble resin may be used alone or in combination of two or more kinds thereof, and it is preferable to use two or more kinds thereof in combination.

The water-soluble resin layer preferably contains at least one selected from PVA and PVP, more preferably contains PVA, and still more preferably contains PVA and PVP.

The water-soluble resin layer preferably contains a water-soluble cellulose derivative, and more preferably contains HPMC.

By containing a crystalline polymer such as PVA, oxygen permeability of the water-soluble resin layer is reduced. As a result, for example, in a case where the photosensitive composition layer contains a photopolymerization initiator, inactivation of a radical by oxygen in the step of exposing the photosensitive composition layer from the water-soluble resin layer side in a patterned manner, which will be described later, is suppressed, and thus the pattern formability is improved. Among these, in a case where a compound represented by Formula (P1) described later is used as the photopolymerization initiator, the pattern formability (particularly, fine pattern formability) is particularly significantly improved. The reason is presumed as follows. A radical generated from the compound represented by Formula (P1) has a large molecular structure, and diffusion of the radical is suppressed, so that the inactivation of the radical by oxygen is a dominant factor that reduces the pattern formability. By combining the water-soluble resin layer as described above, the inactivation of the radical by oxygen is also suppressed, so that the pattern formability (particularly, the fine pattern formability) is significantly excellent.

A content of the water-soluble resin in the water-soluble resin layer is preferably 70.0% by mass or more, more preferably 80.0% by mass or more, and still more preferably 90.0% by mass or more with respect to the total mass of the water-soluble resin layer. The upper limit of the content of the water-soluble resin is 100% by mass or less, preferably 99.0% by mass or less with respect to the total mass of the water-soluble resin layer.

A content of PVA is preferably 15.0% to 90.0% by mass, more preferably 40.0% to 80.0% by mass, and still more preferably 60.0% to 70.0% by mass with respect to the total mass of the water-soluble resin layer.

A content of PVP is preferably 10.0% to 50.0% by mass, more preferably 20.0% to 40.0% by mass, and still more preferably 25.0% to 35.0% by mass with respect to the total mass of the water-soluble resin layer.

A content of the water-soluble cellulose derivative is preferably 0.01% to 10.0% by mass, more preferably 0.1% to 5.0% by mass, and still more preferably 0.5% to 3.0% by mass with respect to the total mass of the water-soluble resin layer.

### <Surfactant>

It is also preferable that the water-soluble resin layer contains a surfactant.

Examples of the surfactant include a fluorine-based surfactant, a hydrocarbon-based surfactant, and a silicone-based surfactant. As the surfactant, a silicone-based surfactant is preferable. From the viewpoint of improving environmental suitability, it is also preferable that the surfactant does not contain a fluorine atom.

Examples of the fluorine-based surfactant include an acrylic compound which has a molecular structure including a functional group having a fluorine atom and in which the functional group having a fluorine atom is broken to volatilize a fluorine atom by applying heat to the molecular structure. Examples of such a fluorine-based surfactant include MEGAFACE DS series (manufactured by DIC Corporation; The Chemical Daily, Feb. 22, 2016; Nikkei Business Daily, Feb. 23, 2016), MEGAFACE DS-21, and the like).

In addition, the fluorine-based surfactant may be a polymer of a fluorine atom-containing vinyl ether compound having a fluorinated alkyl group or a fluorinated alkylene ether group, and a hydrophilic vinyl ether compound. The fluorine-based surfactant may be a block polymer.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) may be used.

In addition, examples of the fluorine-based surfactant also include a fluorine-containing polymer having a group having an ethylenically unsaturated double bond in a side chain. Specific examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of a commercially available product of the fluorine-based surfactant include MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, and F-780 (all of which are manufactured by DIC Corporation); EXP.MFS-324, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (Uni-chem Co., Ltd.).

Examples of the hydrocarbon-based surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of a commercially available product of the hydrocarbon-based surfactant include PLURONIC (registered trademark) L10, L31, L61, L62, 10R5, 17R2, and 25R2, TETRONIC 304, 701, 704, 901, 904, and 150R1, and HYDROPALAT WE 3323 (all of which are manufactured by BASF); Solsperse 20000 (manufactured by Nippon Lubrizol Corporation); NCW-101, NCW-1001, and NCW-1002 (all of which are manufactured by FUJIFILM Wako Pure Chemical Corporation); Pionin D-1105, D-6112, D-6112-W, and D-6315 (all of which are manufactured by TAKEMOTO OIL & FAT Co., Ltd.); and OLFINE E1010, and SURFYNOL 104, 400, and 440 (all of which are manufactured by Nissin Chemical Co., Ltd.).

Examples of the silicone-based surfactant include a linear polymer including a siloxane bond, a modified siloxane polymer in which an organic group is introduced into a side chain and/or a terminal, and a polymer having a repeating unit having a hydrophilic group in a side chain and a repeating unit having a siloxane bond-containing group in a side chain. As the silicone-based surfactant, a polymer having a repeating unit having a hydrophilic group in a side chain and a repeating unit having a siloxane bond-containing group in a side chain is preferable. The above-described polymer may be either a random copolymer or a block copolymer.

Examples of a commercially available product of the silicone-based surfactant include EXP.S-309-2, EXP.S-315, EXP.S-503-2, EXP. S-505-2, and S-506 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101 KP-103, KP-104, KP-105, KP-106, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK325, BYK330, BYK313, BYK315N, BYK331, BYK333, BYK345, BYK347, BYK348, BYK349, BYK370, BYK377, BYK378, and BYK323 (all of which are manufactured by BYK Chemie).

In addition, examples of the surfactant also include a nonionic surfactant other than those described above.

Examples of the surfactant also include surfactants described in paragraph 0017 of JP04502784B and paragraphs 0060 to 0071 of JP2009-237362A.

The surfactant may be used alone, or two or more types thereof may be used in combination.

A content of the surfactant is preferably 0.1% to 10.0% by mass, more preferably 0.5% to 5.0% by mass, and still more preferably 1.0% to 3.0% by mass with respect to the total mass of the water-soluble resin layer.

### <Other Additives>

The water-soluble resin layer may contain other additives other than those described above, as long as water solubility is not impaired. Examples of the other additives include a solvent, a plasticizer, a polymerization inhibitor, and impurities.

The water-soluble resin layer may contain a solvent.

Examples of the solvent include water and an organic solvent.

The above-described organic solvent is also preferably a hydrophilic organic solvent which is mixed with water in arbitrary ratio. Examples of the hydrophilic organic solvent include an alcohol solvent having 1 to 3 carbon atoms, acetone, ethylene glycol, glycerin, and tetrahydrofuran.

The solvent may be used alone, or two or more types thereof may be used in combination.

In a case where a composition containing an alkali aqueous solution as the solvent is used in a case of forming the water-soluble resin layer, the water-soluble resin layer may contain a basic compound component contained in the alkali aqueous solution.

A film thickness of the water-soluble resin layer is not particularly limited, but is preferably 10 μm or less and more preferably 5 μm or less from the viewpoint of more excellent pattern formability. The lower limit of the film thickness of the water-soluble resin layer is preferably 0.3 μm or more, and more preferably 0.5 μm or more.

From the viewpoint of excellent pattern formability in a case of exposing the photosensitive composition layer from the water-soluble resin layer side, it is preferable that the water-soluble resin layer has high transparency. Specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit thereof is preferably less than 100%. Examples of a preferred value of any of the transmittances at each of the wavelengths described above include 87%, 92%, and 98%.

It is preferable that a haze of the water-soluble resin layer is small. Specifically, a haze value of the water-soluble resin layer is preferably 2% or less, more preferably 0.5% or less, and still more preferably 0.1% or less. The lower limit thereof is preferably 0% or more.

### [Photosensitive Composition Layer]

The transfer film includes a photosensitive composition layer.

The photosensitive composition layer is not particularly limited as long as it is a layer containing the specific compound and a component exhibiting photosensitivity. The above-described specific compound may have photosensitivity.

### <Specific Compound>

The photosensitive composition layer contains at least one specific compound selected from the group consisting of a polyimide precursor, a polyimide, a polybenzoxazole precursor, a polybenzoxazole, a phenol resin, an epoxy resin, a polyphenylene ether resin, a silicone resin, a benzocyclobutene resin, a fluorene resin, a liquid crystal polymer, a polyethersulfone, a polyarylate, a polyetherimide, a polybenzimidazole, a polyphenylsulfone, a polycarbonate, an acrylonitrile-butadiene-styrene copolymer resin, and a polyphenylene sulfide.

From the viewpoint of more excellent heat resistance, dielectric characteristics, and migration suppression, the specific compound preferably includes at least one selected from the group consisting of a polyimide precursor, a polyimide, a polybenzoxazole precursor, and a polybenzoxazole, more preferably includes at least one selected from a polyimide precursor or a polyimide, and is still more preferably a polyimide precursor.

The polyimide precursor and the polybenzoxazole precursor described above are each a compound which is converted into a polyimide and a polybenzoxazole by a heating treatment, a light treatment, or a chemical treatment.

From the viewpoint of excellent photosensitivity, the specific compound also preferably contains an ethylenically unsaturated double bond, and more preferably has a group having an ethylenically unsaturated double bond.

Examples of the group having an ethylenically unsaturated double bond include a (meth)acryloyl group, a (meth)acrylamide group, a vinyl group, a styryl group, an allyl group, and a vinyl ether group; and a (meth)acryloyl group is preferable.

### (Polyimide and Polyimide Precursor)

The polyimide is a resin having an imide structure.

The polyimide is preferably a resin having a cyclic imide structure, and may have a substituent. As the polyimide, a resin synthesized from a polyimide precursor having a repeating unit represented by Formula (1) (for example, a resin obtained by a ring closure reaction) is preferable.

The polyimide precursor preferably has a repeating unit represented by Formula (1).

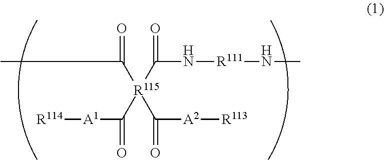

In Formula (1), A¹ and A² each independently represent an oxygen atom or —NH—, R¹¹¹ represents a divalent organic group, R¹¹³ and R¹¹⁴ each independently represent a hydrogen atom or a monovalent organic group, and R¹¹⁵ represents a tetravalent organic group.

In Formula (1), A¹ and A² each independently represent an oxygen atom or —NH—.

As A¹ and A², an oxygen atom is preferable.

In Formula (1), R¹¹¹ represents a divalent organic group.

Examples of the above-described divalent organic group include a divalent aliphatic group, a divalent aromatic ring group, and a group formed by a combination of these groups. As the divalent organic group, a divalent aliphatic group having 2 to 20 carbon atoms, a divalent aromatic ring group having 6 to 20 carbon atoms, or a group formed by a combination of these groups is preferable, and a divalent aromatic ring group having 6 to 20 carbon atoms is more preferable. The above-described aliphatic group may be linear, branched, or cyclic. The above-described aromatic ring group may be monocyclic or polycyclic. The above-described aliphatic group and aromatic ring group may have a heteroatom. The heteroatom may be included in a divalent organic group as a group such as —O—, —CO—, —S—, —SO₂—, and —NHCO—.

As R¹¹¹, a divalent organic group derived from a diamine is also preferable. The above-described diamine is preferably a diamine used for producing the polyimide precursor, and more preferably an aliphatic diamine or an aromatic diamine.

The above-described diamine is preferably a diamine having a linear aliphatic group having 2 to 20 carbon atoms, a branched aliphatic group having 3 to 20 carbon atoms, a cyclic aliphatic group having 3 to 20 carbon atoms, an aromatic ring group having 6 to 20 carbon atoms, or a group formed by a combination of these groups; and more preferably a diamine having an aromatic ring group having 6 to 20 carbon atoms (aromatic diamine). Examples of the above-described aromatic ring group include groups having the following structures.

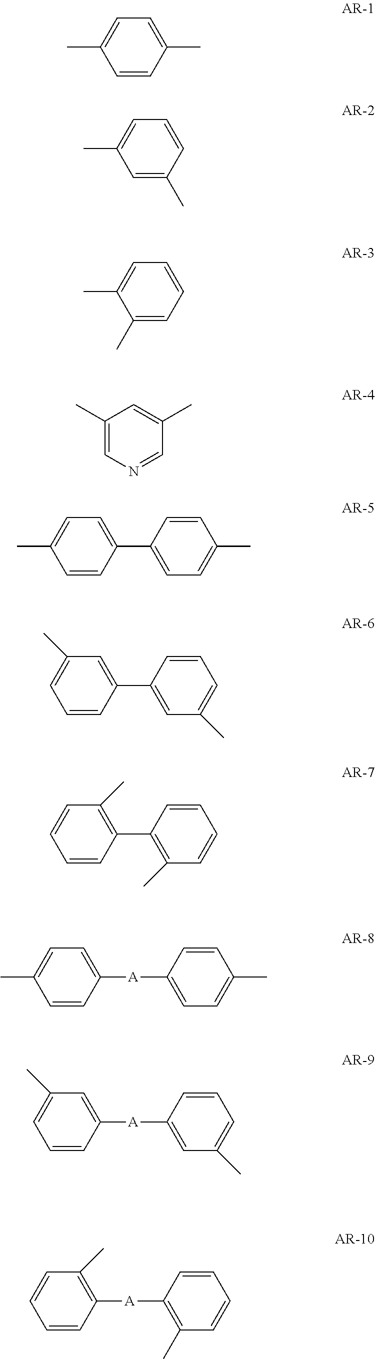

In AR-8 to AR-10, A represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond. As A, an alkylene group having 1 to 3 carbon atoms, which may have a fluorine atom, —O—, —CO—, —S—, or —SO₂— is preferable, —CH₂—, —O—, —S—, —SO₂—, —C(CF₃)₂—, or —C(CH₃)₂— is more preferable, and —O— is still more preferable.

R¹¹¹ is also preferably *—Ar⁰-L-Ar⁰—*.

Ar⁰'s each independently represent a divalent aromatic hydrocarbon group. L⁰ represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond. * represents a bonding position.

Ar⁰'s may be the same or different from each other.

The number of carbon atoms in the divalent aromatic hydrocarbon group represented by Ar⁰ is preferably 6 to 22, more preferably 6 to 18, and still more preferably 6 to 10. As the above-described aromatic hydrocarbon group, a phenylene group is preferable.

L⁰ has the same meaning as A described above, and a suitable aspect thereof is also the same.

Examples of the diamine include 1,2-diaminoethane, 1,2-diaminopropane, 1,3-diaminopropane, 1,4-diaminobutane, 1,6-diaminohexane; 1,2- or 1,3-diaminocyclopentane, 1,2-, 1,3-, or 1,4-diaminocyclohexane, 1,2-, 1,3-, or 1,4-bis(aminomethyl)cyclohexane, bis(4-aminocyclohexyl)methane, bis(3-aminocyclohexyl)methane, 4,4′-diamino-3,3′-dimethylcyclohexylmethane, isophorone diamine; m- or p-phenylenediamine, diaminotoluene, 4,4′- or 3,3′-diaminobiphenyl, 4,4′-diaminodiphenyl ether, 3,3′-diaminodiphenyl ether, 4,4′- or 3,3′-diaminodiphenylmethane, 4,4′- or 3,3′-diaminodiphenyl sulfone, 4,4′- or 3,3′-diaminodiphenyl sulfide, 4,4′- or 3,3′-diaminobenzophenone, 3,3′-dimethyl-4,4′-diaminobiphenyl, 2,2′-dimethyl-4,4′-diaminobiphenyl (4,4′-diamino-2,2′-dimethylbiphenyl), 3,3′-dimethoxy-4,4′-diaminobiphenyl, 2,2-bis(4-aminophenyl)propane, 2,2-bis(4-aminophenyl)hexafluoropropane, 2,2-bis(3-hydroxy-4-aminophenyl)propane, 2,2-bis(3-hydroxy-4-aminophenyl)hexafluoropropane, 2,2-bis(3-amino-4-hydroxyphenyl)propane, 2,2-bis(3-amino-4-hydroxyphenyl)hexafluoropropane, bis(3-amino-4-hydroxyphenyl)sulfone, bis(4-amino-3-hydroxyphenyl)sulfone, 4,4′-diamino-p-terphenyl, 4,4′-bis(4-aminophenoxy)biphenyl, bis[4-(4-aminophenoxy)phenyl]sulfone, bis[4-(3-aminophenoxy)phenyl]sulfone, bis[4-(2-aminophenoxy)phenyl]sulfone, 1,4-bis(4-aminophenoxy)benzene, 9,10-bis(4-aminophenyl)anthracene, 3,3′-dimethyl-4,4′-diaminodiphenyl sulfone, 1,3-bis(4-aminophenoxy)benzene, 1,3-bis(3-aminophenoxy)benzene, 1,3-bis(4-aminophenyl)benzene, 3,3′-diethyl-4,4′-diaminodiphenylmethane, 3,3′-dimethyl-4,4′-diaminodiphenylmethane, 4,4′-diaminooctafluorobiphenyl, 2,2-bis[4-(4-aminophenoxy)phenyl]propane, 2,2-bis[4-(4-aminophenoxy)phenyl]hexafluoropropane, 9,9-bis(4-aminophenyl)-10-hydroanthracene, 3,3′,4,4′-tetraaminobiphenyl, 3,3′,4,4′-tetraaminodiphenyl ether, 1,4-diaminoanthraquinone, 1,5-diaminoanthraquinone, 3,3′-dihydroxy-4,4′-diaminobiphenyl, 9,9′-bis(4-aminophenyl)fluorene, 4,4′-dimethyl-3,3′-diaminodiphenyl sulfone, 3,3′,5,5′-tetramethyl-4,4′-diaminodiphenylmethane, 2-(3′,5′-diaminobenzoyloxy)ethyl methacrylate, 2,4- or 2,5-diaminocumene, 2,5-dimethyl-p-phenylenediamine, acetoguanamine, 2,3,5,6-tetramethyl-p-phenylenediamine, 2,4,6-trimethyl-m-phenylenediamine, bis(3-aminopropyl)tetramethyldisiloxane, 2,7-diaminofluorene, 2,5-diaminopyridine, 1,2-bis(4-aminophenyl)ethane, diaminobenzanilide, esters of diaminobenzoic acid, 1,5-diaminonaphthalene, diaminobenzotrifluoride, 1,3-bis(4-aminophenyl)hexafluoropropane, 1,4-bis(4-aminophenyl)octafluorobutane, 1,5-bis(4-aminophenyl)decafluoropentane, 1,7-bis(4-aminophenyl)tetradecafluoroheptane, 2,2-bis[4-(3-aminophenoxy)phenyl]hexafluoropropane, 2,2-bis[4-(2-aminophenoxy)phenyl]hexafluoropropane, 2,2-bis[4-(4-aminophenoxy)-3, 5-dimethylphenyl]hexafluoropropane, 2,2-bis[4-(4-aminophenoxy)-3, 5-bis(trifluoromethyl)phenyl]hexafluoropropane, p-bis(4-amino-2-trifluoromethylphenoxy)benzene, 4,4′-bis(4-amino-2-trifluoromethylphenoxy)biphenyl, 4,4′-bis(4-amino-3-trifluoromethylphenoxy)biphenyl, 4,4′-bis(4-amino-2-trifluoromethylphenoxy)diphenyl sulfone, 4,4′-bis(3-amino-5-trifluoromethylphenoxy)diphenyl sulfone, 2,2-bis[4-(4-amino-3-trifluoromethylphenoxy)phenyl]hexafluoropropane, 3,3′,5,5′-tetramethyl-4,4′-diaminobiphenyl, 4,4′-diamino-2,2′-bis(trifluoromethyl)biphenyl, 2,2′,5,5′,6,6′-hexafluorotolidine, and 4,4′-diaminoquaterphenyl.

In addition, examples of the diamine also include a compound represented by any of Formulae (DA-1) to (DA-18).

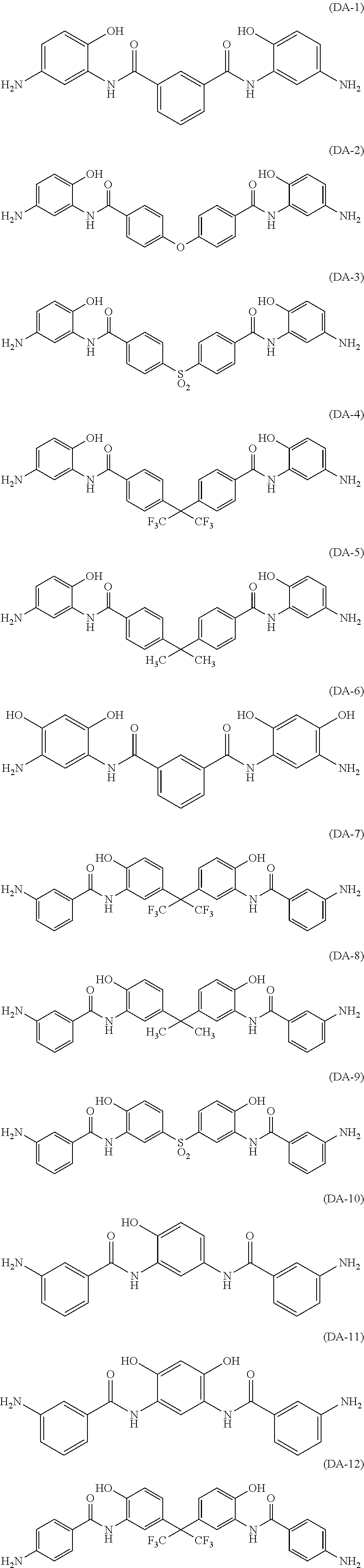

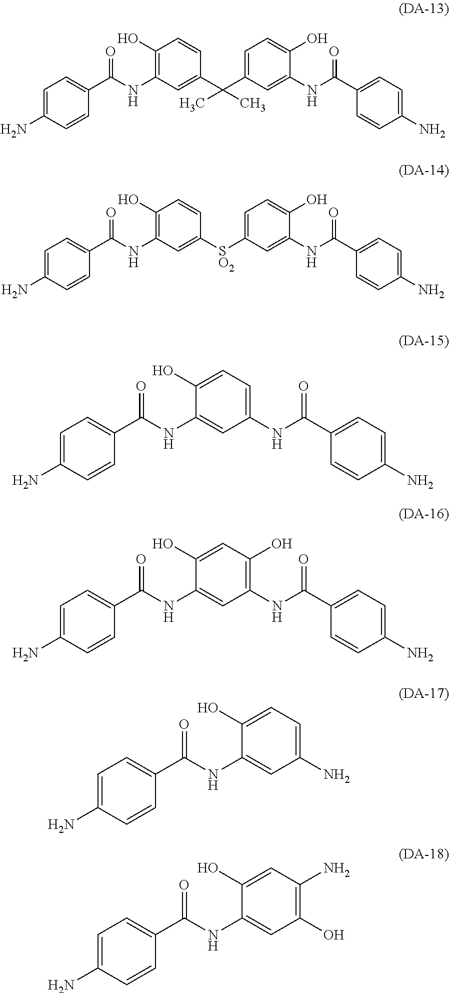 [SMILES: CC(C)(c1ccc(O)c(NC(=O)c2ccc(N)cc2)c1)c1ccc(O)c(NC(=O)c2ccc(N)cc2)c1 ; Nc1ccc(C(=O)Nc2cc(S(=O)(=O)c3ccc(O)c(NC(=O)c4ccc(N)cc4)c3)ccc2O)cc1 ; Nc1ccc(C(=O)Nc2ccc(O)c(NC(=O)c3ccc(N)cc3)c2)cc1 ; Nc1ccc(C(=O)Nc2cc(NC(=O)c3ccc(N)cc3)c(O)cc2O)cc1 ; Nc1ccc(C(=O)Nc2cc(N)ccc2O)cc1 ; Nc1ccc(C(=O)Nc2cc(O)c(N)cc2O)cc1]

In addition, examples of the diamine also include a diamine having two or more alkylene glycol units in the main chain; and as the diamine having two or more alkylene glycol units in the main chain, a diamine including two or more of one or both of an ethylene glycol chain and a propylene glycol chain in one molecule is preferable. In addition, a diamine not including an aromatic ring is also preferable.

Examples of the above-described diamine include JEFFAMINE (registered trademark) series (KH-511, ED-600, ED-900, ED-2003, EDR-148, EDR-176, D-200, D-400, D-2000, and D-4000, manufactured by HUNTSMAN Corporation); 1-(2-(2-(2-aminopropoxy)ethoxy)propoxy)propane-2-amine, and 1-(1-(1-(2-aminopropoxy)propane-2-yl)oxy)propane-2-amine.

In Formula (1), R¹¹³ and R¹¹⁴ each independently represent a hydrogen atom or a monovalent organic group.

It is preferable that at least one of R¹¹³ or R¹¹⁴ represents a group having a polymerizable group, and it is more preferable that both R¹¹³ and R¹¹⁴ represent a group having a polymerizable group. Examples of the polymerizable group include the groups exemplified as the polymerizable group which may be included in the above-described resin.

The above-described monovalent organic group may be a monovalent organic group X described later.

R¹¹³ and R¹¹⁴ are each preferably a group having an ethylenically unsaturated double bond, and more preferably a vinyl group, an allyl group, a (meth)acryloyl group, or a group represented by Formula (III).

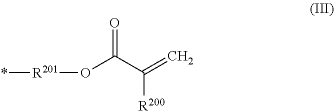

In Formula (III), R²⁰⁰ represents a hydrogen atom or a methyl group, R²⁰¹ represents an alkylene group having 2 to 12 carbon atoms, —CH₂CH(OH)CH₂—, or a (poly)oxyalkylene group having 4 to 30 carbon atoms, and * represents a bonding position.

In Formula (III), R²⁰⁰ represents a hydrogen atom or a methyl group.

R²⁰⁰ is preferably a methyl group.

In Formula (III), R²⁰¹ represents an alkylene group having 2 to 12 carbon atoms, —CH₂CH(OH)CH₂—, or a (poly)oxyalkylene group having 4 to 30 carbon atoms.

The number of carbon atoms in the alkylene group constituting the above-described (poly)oxyalkylene group is preferably 1 to 12, more preferably 1 to 6, and still more preferably 1 to 3. The repetition number of the oxyalkylene constituting the above-described (poly)oxyalkylene group is preferably 1 to 12, more preferably 1 to 6, and still more preferably 1 to 3.

The (poly)oxyalkylene group is a concept including both an oxyalkylene group and a polyoxyalkylene group.

Examples of R²⁰¹ include an ethylene group, a propylene group, a trimethylene group, a tetramethylene group, a 1,2-butanediyl group, a 1,3-butanediyl group, a pentamethylene group, a hexamethylene group, an octamethylene group, a dodecamethylene group, and —CH₂CH(OH)CH₂—; and an ethylene group, a propylene group, a trimethylene group, or —CH₂CH(OH)CH₂— is preferable, and an ethylene group is more preferable.

Examples of the monovalent organic group represented by R¹¹³ or R¹¹⁴ include an aliphatic group, an aromatic ring group, and an arylalkyl group, each of which has 1 to 3 acid groups. Examples thereof include an aromatic ring group having 6 to 20 carbon atoms, which has an acid group, and an arylalkyl group having 7 to 25 carbon atoms, which has an acid group. More specific examples thereof include a phenyl group having an acid group and a benzyl group having an acid group. The acid group is preferably a hydroxyl group or a carboxy group.

As R¹¹³ and R¹¹⁴, a hydrogen atom, a 2-hydroxybenzyl group, a 3-hydroxybenzyl group, or a 4-hydroxybenzyl group is also preferable.

Examples of the monovalent organic group represented by R¹¹³ or R¹¹⁴ also include a leaving group which is eliminated by action of acid.

In Formula (1), R¹¹⁵ represents a tetravalent organic group.

As the tetravalent organic group, a tetravalent organic group having an aromatic ring is preferable; and a group represented by Formula (5) or a group represented by Formula (6) is more preferable.

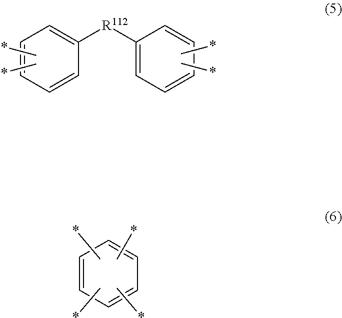

In Formula (5), R¹¹² represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond, and * represents a bonding position.

In Formula (6), * represents a bonding position.

In Formula (5), R¹¹² has the same meaning as A described above, and a suitable aspect thereof is also the same.

Examples of the tetravalent organic group also include a tetracarboxylic acid residue remaining after removing an acid dianhydride group from a tetracarboxylic acid dianhydride. The tetracarboxylic acid dianhydride is preferably a compound represented by Formula (7).

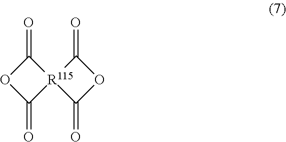

In Formula (7), R¹¹⁵ represents a tetravalent organic group.

R¹¹⁵ in Formula (7) has the same meaning as R¹¹⁵ in Formula (1), and a suitable aspect thereof is also the same.

Examples of the tetracarboxylic acid dianhydride include pyromellitic acid, pyromellitic acid dianhydride (PMDA), 3,3′,4,4′-biphenyltetracarboxylic acid dianhydride, 3,3′,4,4′-diphenylsulfide tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-diphenylmethane tetracarboxylic acid dianhydride, 2,2′,3,3′-diphenylmethane tetracarboxylic acid dianhydride, 2,3,3′,4′-biphenyltetracarboxylic acid dianhydride, 2,3,3′,4′-benzophenone tetracarboxylic acid dianhydride, 4,4′-oxydiphthalic acid dianhydride, 2,3,6,7-naphthalene tetracarboxylic acid dianhydride, 1,4,5,7-naphthalene tetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl) hexafluoropropane dianhydride, 1,3-diphenylhexafluoropropane-3,3,4,4-tetracarboxylic acid dianhydride, 1,4,5,6-naphthalene tetracarboxylic acid dianhydride, 2,2′,3,3′-diphenyl tetracarboxylic acid dianhydride, 3,4,9,10-perylene tetracarboxylic acid dianhydride, 1,2,4,5-naphthalene tetracarboxylic acid dianhydride, 1,4,5,8-naphthalene tetracarboxylic acid dianhydride, 1,8,9,10-phenanthrene tetracarboxylic acid dianhydride, 1,1-bis(2,3-dicarboxyphenyl)ethane dianhydride, 1,1-bis(3,4-dicarboxyphenyl)ethane dianhydride, 1,2,3,4-benzene tetracarboxylic acid dianhydride, alkyl derivatives thereof, having 1 to 6 carbon atoms, and alkoxy derivatives thereof, having 1 to 6 carbon atoms.

Examples of the tetracarboxylic acid dianhydride also include a compound represented by any of Formulae (DAA-1) to (DAA-5).

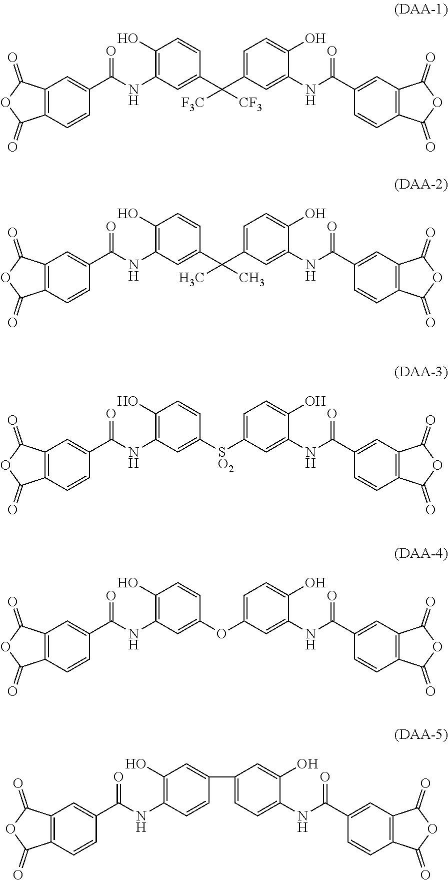 [SMILES: O=C(Nc1cc(C(c2ccc(O)c(NC(=O)c3ccc4c(c3)C(=O)OC4=O)c2)(C(F)(F)F)C(F)(F)F)ccc1O)c1ccc2c(c1)C(=O)OC2=O ; CC(C)(c1ccc(O)c(NC(=O)c2ccc3c(c2)C(=O)OC3=O)c1)c1ccc(O)c(NC(=O)c2ccc3c(c2)C(=O)OC3=O)c1 ; O=C(Nc1cc(S(=O)(=O)c2ccc(O)c(NC(=O)c3ccc4c(c3)C(=O)OC4=O)c2)ccc1O)c1ccc2c(c1)C(=O)OC2=O ; O=C(Nc1cc(Oc2ccc(O)c(NC(=O)c3ccc4c(c3)C(=O)OC4=O)c2)ccc1O)c1ccc2c(c1)C(=O)OC2=O ; O=C(Nc1ccc(-c2ccc(NC(=O)c3ccc4c(c3)C(=O)OC4=O)c(O)c2)cc1O)c1ccc2c(c1)C(=O)OC2=O]

### (Monovalent Organic Group X)

The monovalent organic group X is preferably an alkyl group which may have a substituent or an aromatic ring group which may have a substituent; and more preferably an alkyl group which may have an aromatic ring group.

The above-described alkyl group may be linear, branched, or cyclic. The alicyclic ring may be a monocycle or a polycycle.

The number of carbon atoms in the linear or branched alkyl group is preferably 1 to 30. The number of carbon atoms in the cyclic alkyl group (cycloalkyl group) is preferably 3 to 30.

Examples of the above-described alkyl group include linear or branched alkyl groups such as a methyl group, an ethyl group, a propyl group, a butyl group, a pentyl group, a hexyl group, a heptyl group, an octyl group, a nonyl group, a decyl group, a dodecyl group, a tetradecyl group, an octadecyl group, an isopropyl group, an isobutyl group, a sec-butyl group, a t-butyl group, a 1-ethylpentyl group, and a 2-ethylhexyl group; monocyclic cycloalkyl groups such as a cyclopropyl group, a cyclobutyl group, a cyclopentyl group, a cyclohexyl group, a cycloheptyl group, and a cyclooctyl group; and polycyclic cycloalkyl groups such as an adamantyl group, a norbornyl group, a bornyl group, a camphanyl group, a decahydronaphthyl group, a tricyclodecanyl group, a tetracyclodecanyl group, a camphoroyl group, a dicyclohexyl group, and a pyrenyl group.

As the substituent which can be included in the above-described alkyl group, an aromatic ring group described below is preferable.

The aromatic ring group may be any one of an aromatic hydrocarbon ring group or an aromatic heterocyclic group. In addition, the aromatic ring group may be monocyclic or polycyclic.

Examples of a ring constituting the aromatic ring group include aromatic hydrocarbon rings such as a benzene ring, a naphthalene ring, a biphenyl ring, a fluorene ring, a pentalene ring, an indene ring, an azulene ring, a heptalene ring, an indacene ring, a perylene ring, a pentacene ring, an acenaphthene ring, a phenanthrene ring, an anthracene ring, a naphthacene ring, a chrysene ring, and a triphenylene ring; and aromatic heterocyclic groups such as a pyrrole ring, a furan ring, a thiophene ring, an imidazole ring, an oxazole ring, a thiazole ring, a pyridine ring, a pyrazine ring, a pyrimidine ring, a pyridazine ring, an indridine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring.

As the substituent which can be included in the above-described aromatic ring group, the above-described alkyl group is preferable.

As the repeating unit represented by Formula (1), a repeating unit represented by Formula (1-A) or a repeating unit represented by Formula (1-B) is preferable.

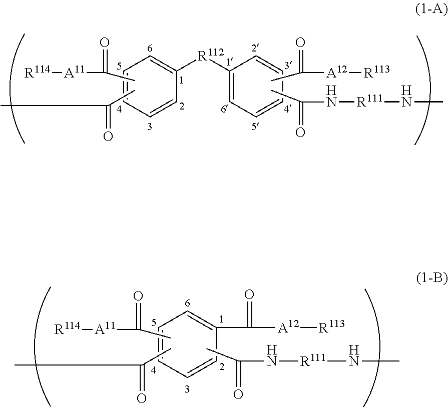

In Formula (1-A) and Formula (1-B), A¹¹ and A¹² represent an oxygen atom or —NH—. R¹¹¹ and R¹¹² each independently represent a divalent organic group. R¹¹³ and R¹¹⁴ each independently represent a hydrogen atom or a monovalent organic group.

A¹¹, A¹², R¹¹¹, R¹¹³, and R¹¹⁴ in Formula (1-A) and Formula (1-B) each have the same meaning as A¹, A², R¹¹¹, R¹¹³, and R¹¹⁴ in Formula (1), and suitable aspects thereof are also the same.

R¹¹² in Formula (1-A) has the same meaning as R¹¹² in Formula (5), and a suitable aspect thereof is also the same.

In Formula (1-A), a bonding position of the carbonyl group to the benzene ring is preferably 4, 5, 3′, or 4′ in Formula (1-A).

In Formula (1-B), a bonding position of the carbonyl group to the benzene ring is preferably 1, 2, 4, or 5 in Formula (1-B).

The polyimide precursor may include other repeating units in addition to the repeating unit represented by Formula (1).

A content of the repeating unit represented by Formula (1) is preferably 50 mol % or more, more preferably 70 mol % or more, and still more preferably 90 mol % or more with respect to all repeating units of the polyimide precursor. The upper limit thereof is preferably 100 mol % or less.

It is also preferable that the polyimide precursor has a fluorine atom.

A content of the fluorine atom in the polyimide precursor is preferably 10% by mass or more and more preferably 20% by mass or more with respect to the total mass of the polyimide precursor. The upper limit thereof is preferably 50% by mass or less.

From the viewpoint of improving adhesiveness with the base material, the polyimide precursor may be obtained by copolymerization with an aliphatic group having a siloxane structure and the repeating unit represented by Formula (1). Examples of the aliphatic group having a siloxane structure include bis(3-aminopropyl)tetramethyldisiloxane and bis(paraminophenyl)octamethylpentasiloxane.

A weight-average molecular weight (Mw) of the polyimide precursor is preferably 2,000 to 500,000, more preferably 5,000 to 100,000, and still more preferably 10,000 to 50,000.

A number-average molecular weight (Mn) of the polyimide precursor is preferably 800 to 250,000, more preferably 2,000 to 50,000, and still more preferably 4,000 to 25,000.

A polydispersity (Mw/Mn) of the polyimide precursor is preferably 1.5 to 3.5, and more preferably 2.0 to 3.0.

### (Polybenzoxazole and Polybenzoxazole Precursor)

The polybenzoxazole is a resin having a benzoxazole ring.

The polybenzoxazole is not particularly limited as long as it is a resin having a benzoxazole ring, and may have a substituent. As the polybenzoxazole, a resin synthesized from a polybenzoxazole precursor having a repeating unit represented by Formula (2) (for example, a resin obtained by a ring closure reaction) is preferable.

The polybenzoxazole precursor preferably has a repeating unit represented by Formula (2).

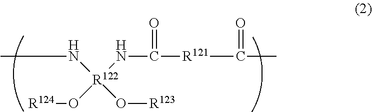

In Formula (2), R¹²¹ represents a divalent organic group, R¹²² represents a tetravalent organic group, and R¹²³ and R¹²⁴ each independently represent a hydrogen atom or a monovalent organic group.

In Formula (2), R¹²¹ represents a divalent organic group.

Examples of the divalent organic group include the divalent organic group represented by R¹¹¹ described above.

In Formula (2), R¹²² represents a tetravalent organic group.

Examples of the tetravalent organic group include the tetravalent organic group represented by R¹¹⁵ described above.

In Formula (2), R¹²³ and R¹²⁴ each independently represent a hydrogen atom or a monovalent organic group.

R¹²³ and R¹²⁴ have the same meanings as R¹¹³ and R¹¹⁴, and suitable aspects thereof are also the same.

The polybenzoxazole precursor may include other repeating units in addition to the repeating unit represented by Formula (2).

Examples of the other repeating units include a repeating unit having a siloxane structure. Examples of the other repeating units described above include repeating units described in paragraphs 0150 to 0154 of JP2020-154205A.

A weight-average molecular weight (Mw) of the polybenzoxazole precursor is preferably 2,000 to 500,000, more preferably 5,000 to 100,000, and still more preferably 10,000 to 50,000.

A number-average molecular weight (Mn) of the polybenzoxazole precursor is preferably 800 to 250,000, more preferably 2,000 to 50,000, and still more preferably 4,000 to 25,000.

A polydispersity (Mw/Mn) of the polybenzoxazole precursor is preferably 1.5 to 3.5, and more preferably 2.0 to 3.0.

### (Phenol Resin)

The phenol resin is a resin having a phenolic hydroxyl group.

Examples of the phenol resin include a phenol novolac resin, a cresol novolac resin, a biphenyl aralkyl-type phenol resin, a naphthol aralkyl resin, and a naphthol novolac resin.

Examples of the phenol resin include AV LITE series manufactured by ASAHI YUKIZAI CORPORATION, such as TR4020G, TR4050G, TR4080G, TR5020G, TR5050G, TR6020G, TR6050G, and TR6080G; photoresist resin series manufactured by Sumitomo Bakelite Co., Ltd.; RESITOP series manufactured by Gun Ei Chemical Industry Co., Ltd.; PR-30-40P, PR-100L, PR-100H, PR-50, PR-55, PR-56-1, PR-56-2, PHENOLITE series manufactured by DIC Corporation, such as WR-101, WR-102, WR-103 and WR-104; photoresist resins Lignyte Inc., such as LF-100, LF-110, LF-120, LF-200, LF-400 and LF-500; MEHC-7851SS, MEHC-780045, MEHC-7851-SS, MEHC-7851-S, MEHC-7851-M, MEHC-7851-H, MEHC-7800-45, MEHC-7800-SS, MEHC-7800-S, MEHC-7800-M, and MEHC-7800-H manufactured by MEIWA PLASTIC INDUSTRIES, LTD.; GPH-65, GPH-103, and MEHC-7841-45 manufactured by Nippon Kayaku Co., Ltd.; BisP-AP, BisP-MIBK, BisP-B, Bis-Z, BisP-CP, o,o′-BPF, BisP-IOTD, BisP-IBTD, BisP-DED, BisP-BA, Bis-C, Bis26X-A, BisOPP-A, BisOTBP-A, BisOCHP-A, BisOFP-A, BisOC-Z, BisOC-FL, BisOC-CP, BisOCHP-Z, methylenebisP-CR, TM-BPF, BisOC-F, Bis3M6B-IBTD, BisOC-IST, BisP-IST, BisP-PRM, BisP-LV, BisE, and BisP-TMC manufactured by Honshu Chemical Industry Co., Ltd.; and BisA, BisF, and BisP-M manufactured by MITSUI FINE CHEMICALS, INC.

Examples of the phenol resin also include resins described in JP2021-157174A.

In addition, examples of the phenol resin also include phenol-based curing agents such as EPICLON series, EXB9451, EXB9460, EXB9460S, and HPC8000-65T (manufactured by DIC Corporation).

### (Epoxy Resin)

The epoxy resin is a resin having an epoxy group.

Examples of the epoxy resin include a bisphenol A-type epoxy resin, a bisphenol F-type epoxy resin, a bisphenol S-type epoxy resin, a bisphenol AF-type epoxy resin, a dicyclopentadiene-type epoxy resin, a trisphenol epoxy resin, a naphthol novolac-type epoxy resin, a phenol novolac-type epoxy resin, a tert-butyl-catechol-type epoxy resin, a naphthalene-type epoxy resin, a naphthol-type epoxy resin, an anthracene-type epoxy resin, a glycidylamine-type epoxy resin, a glycidyl ester-type epoxy resin, a cresol novolac-type epoxy resin, a biphenyl-type epoxy resin, a linear aliphatic epoxy resin, an epoxy resin having a butadiene structure, an alicyclic epoxy resin, a heterocyclic epoxy resin, an epoxy resin containing a spiro ring, a cyclohexanedimethanol epoxy resin, a naphthylene ether-type epoxy resin, and a trimethylol-type epoxy resin.

From the viewpoint of improved flexibility and breaking strength of the film to be formed, it is also preferable that the epoxy resin includes an epoxy resin which is liquid at a temperature of 20° C. (hereinafter, also referred to as “liquid epoxy resin”) and an epoxy resin which is solid at a temperature of 20° C. (hereinafter, also referred to as “solid epoxy resin”).

As the liquid epoxy resin, a bisphenol A-type epoxy resin, a bisphenol F-type epoxy resin, a phenol novolac-type epoxy resin, or a naphthalene-type epoxy resin is preferable; and a bisphenol A-type epoxy resin, a bisphenol F-type epoxy resin, or a naphthalene-type epoxy resin is more preferable.

Examples of the liquid epoxy resin include HP4032, HP4032D, EXA4032SS, and HP4032SS (naphthalene-type epoxy resins) manufactured by DIC Corporation; jER828EL (bisphenol A-type epoxy resin), jER807 (bisphenol F-type epoxy resin), and jER152 (phenol novolac-type epoxy resin) manufactured by Mitsubishi Chemical Corporation; and ZX1059 (mixed product of bisphenol A-type epoxy resin and bisphenol F-type epoxy resin) manufactured by NIPPON STEEL Chemical & Material Co., Ltd.

As the liquid epoxy resin, HP4032SS or ZX1059 is preferable.

As the solid epoxy resin, a tetrafunctional naphthalene-type epoxy resin, a cresol novolac-type epoxy resin, a dicyclopentadiene-type epoxy resin, a trisphenol epoxy resin, a naphthol novolac-type epoxy resin, a biphenyl-type epoxy resin, or a naphthylene ether-type epoxy resin is preferable; a tetrafunctional naphthalene-type epoxy resin, a biphenyl-type epoxy resin, or a naphthylene ether-type epoxy resin is more preferable; and a biphenyl-type epoxy resin is still more preferable.

Examples of the solid epoxy resin include HP-4700 and HP-4710 (tetrafunctional naphthalene-type epoxy resins), N-690 (cresol novolac-type epoxy resin), N-695 (cresol novolac-type epoxy resin), HP7200, HP7200H, HP7200K-65I (dicyclopentadiene-type epoxy resins), EXA7311, EXA7311-G3, and HP6000 (naphthylene ether-type epoxy resins) manufactured by DIC Corporation; EPPN-502H (trisphenol epoxy resin), NC7000L (naphthol novolac epoxy resin), NC3000H, NC3000, NC3000L, and NC3100 (biphenyl-type epoxy resins) manufactured by Nippon Kayaku Co., Ltd.; ESN475 (naphthol novolac-type epoxy resin) and ESN485 (naphthol novolac-type epoxy resin) manufactured by NIPPON STEEL Chemical & Material Co., Ltd.; and YX4000H, YL6121 (biphenyl-type epoxy resins), and YX4000HK (bixylenol-type epoxy resin) manufactured by Mitsubishi Chemical Corporation.

As the solid epoxy resin, YX4000HK, NC3000L, or HP7200H is preferable.

### (Polyphenylene Ether Resin)

The polyphenylene ether resin is a resin having a phenylene ether group.

The polyphenylene ether resin may have a linear structure or a branched structure, and preferably have a branched structure.

In the polyphenylene ether resin having a branched structure, it is preferable that an ether bond is directly bonded to at least three positions of an ipso position, an ortho position, and a para position of a benzene ring in at least one benzene ring constituting the polyphenylene ether resin.

The polyphenylene ether resin having a branched structure is obtained, for example, by polymerization using two or more kinds of phenol compounds.

As the above-described phenol compound, a phenol compound having a hydrogen atom at an ortho position and a para position and having a polymerizable group, or a mixture of a phenol compound having a hydrogen atom at an ortho position and a para position and not having a polymerizable group and a phenol compound not having a hydrogen atom at an ortho position, having a hydrogen atom at a para position, and having a polymerizable group is preferable.

Examples of the phenol compound used for the synthesis of the polyphenylene ether resin include o-vinylphenol, m-vinylphenol, o-allylphenol, m-allylphenol, 3-vinyl-6-methylphenol, 3-vinyl-6-ethylphenol, 3-vinyl-5-methylphenol, 3-vinyl-5-ethylphenol, 3-allyl-6-methylphenol, 3-allyl-6-ethylphenol, 3-allyl-5-methylphenol, 3-allyl-5-ethylphenol, phenol, o-cresol, m-cresol, o-ethylphenol, m-ethylphenol, 2,3-xylenol, 2,5-xylenol, 3,5-xylenol, o-tert-butylphenol, m-tert-butylphenol, o-phenylphenol, m-phenylphenol, 2-dodecylphenol, 2-allyl-6-methylphenol, 2-allyl-6-ethylphenol, 2-allyl-6-phenylphenol, 2-allyl-6-styrylphenol, 2,6-divinylphenol, 2,6-diallylphenol, 2,6-diisopropenylphenol, 2,6-dibutenylphenol, 2,6-diisobutenylphenol, 2,6-diisopentenylphenol, 2-methyl-6-styrylphenol, 2-vinyl-6-methylphenol, 2-vinyl-6-ethylphenol, 2,6-dimethylphenol, 2,3,6-trimethylphenol, 2-methyl-6-ethylphenol, 2-ethyl-6-n-propylphenol, 2-methyl-6-n-butylphenol, 2-methyl-6-phenylphenol, 2,6-diphenylphenol, and 2,6-ditolylphenol.

Among these, 2,6-dimethylphenol or 2-allylphenol is preferable as the above-described phenol compound.

In addition, it is also preferable that the polyphenylene ether resin has a polymerizable group. As the above-described polymerizable group, a group having an ethylenically unsaturated double bond is preferable, and a vinylphenyl group or a (meth)acryloyl group is more preferable.

In addition, in a case where the polyphenylene ether resin has a polymerizable group, the composition preferably contains a maleimide compound. The above-described maleimide compound reacts with the polyphenylene ether resin to obtain a modified polyphenylene ether.

Examples of the modified polyphenylene ether include a resin obtained by curing a resin composition described in WO2022/102756A.

Examples of the polyphenylene ether resin include poly(2,6-diethyl-1,4-phenylene) ether, poly(2-ethyl-6-n-propyl-1,4-phenylene) ether, poly(2,6-di-n-propyl-1,4-phenylene) ether, poly(2-methyl-6-n-butyl-1,4-phenylene) ether, poly(2-ethyl-6-isopropyl-1,4-phenylene) ether, poly(2-methyl-6-chloroethyl-1,4-phenylene) ether, poly(2-methyl-6-hydroxyethyl-1,4-phenylene) ether, and poly(2-methyl-6-chloroethyl-1,4-phenylene) ether.

Examples of the polyphenylene ether resin also include resins described in JP2022-157695A.

### (Silicone Resin)

The silicone resin is a resin having an organosiloxane structure.

Examples of the silicone resin include a curable silicone resin, a silicone graft resin, and a modified silicone resin such as an alkyl-modified silicone resin; and a curable silicone resin is preferable.

Examples of the curable silicone resin include an addition reaction-type silicone resin, a condensation reaction-type silicone resin, and an ultraviolet ray or electron beam-curable silicone resin.

Examples of the addition reaction-type silicone resin include a resin obtained by reacting polydimethylsiloxane in which a vinyl group is introduced into a terminal or a side chain with hydrogen siloxane using a platinum catalyst for curing.

Examples of the condensation reaction-type silicone resin include a resin having a three-dimensional crosslinking structure, which is formed by a condensation reaction of polydimethylsiloxane having a hydroxyl group at a terminal and polydimethylsiloxane having a hydrogen atom at a terminal using an organotin catalyst.

Examples of the ultraviolet ray-curable silicone resin include a silicone resin which uses the same radical reaction as silicone rubber crosslinking, a silicone resin which is photocured by introducing an unsaturated group, a silicone resin which decomposes an onium salt with an ultraviolet ray or an electron beam to produce a strong acid and cleaves an epoxy group for crosslinking, and a silicone resin which is crosslinked by an addition reaction of thiol to vinylsiloxane. Specific examples thereof include acrylate-modified polydimethylsiloxane and glycidoxy-modified polydimethylsiloxane.

Examples of the silicone resin also include a dimethylsiloxane-methylvinylsiloxane copolymer capped at both molecular chain terminals with a trimethylsiloxy group, a dimethylsiloxane-diphenylsiloxane-methylvinylsiloxane copolymer capped at both molecular chain terminals with a trimethylsiloxy group, and a dimethylsiloxane-diphenylsiloxane copolymer capped at both molecular chain terminals with a dimethylvinylsiloxy group.

The silicone resin preferably has an aromatic ring. As the aromatic ring, an aromatic hydrocarbon ring is preferable, an aromatic hydrocarbon ring having 6 to 12 carbon atoms is more preferable, and a benzene ring is still more preferable.

As the silicone resin, a modified silicone resin obtained by reacting an organosilicon compound with a hydrosilylation agent is also preferable.

The organosilicon compound preferably further has a polymerizable group. Examples of the above-described polymerizable group include the polymerizable groups included in the resin.

Examples of the organosilicon compound include a compound having a silyl group, and 1,4-bis(dimethylsilyl)benzene or trivinylphenylsilane is preferable.

A reaction temperature is preferably 100° C. to 200° C., and a reaction time is preferably 1 to 10 hours.

Examples of the silicone resin also include a resin obtained from an organosiloxane and a curable composition, which are described in JP2020-026502A.

### (Other Resins)

The benzocyclobutene resin is a resin having a benzocyclobutene ring.

Examples of the benzocyclobutene resin include a divinylsiloxane-bisbenzocyclobutene resin (for example, CYCLOTENE resin manufactured by Dow Chemical Company).

The fluorene resin is a resin having a fluorene ring.

Examples of the fluorene resin include a resin obtained by reacting a fluorene compound having a hydroxyaryl structure with an aldehyde compound, and a derivative thereof.

Examples of the above-described fluorene compound include 9,9-bis(4-hydroxyphenyl)fluorene, 9,9-bis(4-hydroxyphenyl)fluorene, and 9,9-bis(6-hydroxynaphthyl)fluorene.

The liquid crystal polymer is a resin exhibiting liquid crystallinity.

The liquid crystal polymer is preferably a thermotropic liquid crystal polymer. The thermotropic liquid crystal polymer refers to a polymer which exhibits liquid crystallinity in a predetermined temperature range.

The thermotropic liquid crystal polymer may be any liquid crystal polymer which can be melt-molded; and examples thereof include thermoplastic liquid crystal polyester, and thermoplastic liquid crystal polyester amide in which an amide bond is introduced into the thermoplastic liquid crystal polyester.

The liquid crystal polymer preferably has a repeating unit having an aromatic ring.

As the aromatic ring, an aromatic hydrocarbon ring is preferable, an aromatic hydrocarbon ring having 6 to 12 carbon atoms is more preferable, and a benzene ring is still more preferable.

As a monomer from which the repeating unit having an aromatic ring is derived, p-hydroxybenzoic acid, 4,4′-dihydroxybiphenyl, hydroquinone, terephthalic acid, or isophthalic acid is preferable.

The liquid crystal polymer preferably includes two or more kinds of repeating units derived from compounds selected from p-hydroxybenzoic acid, 4,4′-dihydroxybiphenyl, hydroquinone, terephthalic acid, and isophthalic acid; and more preferably includes four or five kinds of repeating units derived from the compounds.

The liquid crystal polymer may include a repeating unit derived from a compound other than the above-described compounds.

Examples of the liquid crystal polymer include liquid crystal polymers described in JP2006-299254A and WO2015/064437A.

Examples of the polyethersulfone, the polyarylate, the polyether imide, the polybenzimidazole, the polyphenylsulfone, the polycarbonate, the acrylonitrile-butadiene-styrene copolymer resin (ABS resin), and the polyphenylene sulfide include known resins.

As described above, the specific compound contained in the composition may be a precursor of each of the above-described resins.

A weight-average molecular weight (Mw) of the specific compound is preferably 2,000 to 500,000, more preferably 5,000 to 100,000, and still more preferably 5,000 to 50,000.

A number-average molecular weight (Mn) of the specific compound is preferably 800 to 250,000, more preferably 2,000 to 50,000, and still more preferably 4,000 to 25,000.

A polydispersity (Mw/Mn) of the specific compound is preferably 1.0 to 3.5, and more preferably 2.0 to 3.0.

The specific compound may be used alone, or two or more types thereof may be used in combination.

A content of the specific compound is preferably 1.0% to 99.0% by mass, more preferably 5.0% to 90.0% by mass, and still more preferably 20.0% to 50.0% by mass with respect to the total mass of the photosensitive composition layer.

The content of the specific compound is preferably 5.0% to 99.0% by mass with respect to the total mass of the photosensitive composition layer, excluding the filler.

### <Photopolymerization Initiator>

From the viewpoint of more excellent pattern formability, the photosensitive composition layer preferably contains a photopolymerization initiator.

Examples of the photopolymerization initiator include an oxime ester compound (photopolymerization initiator having an oxime ester structure), an aminoacetophenone compound (photopolymerization initiator having an aminoacetophenone structure), a hydroxyacetophenone compound (photopolymerization initiator having a hydroxyacetophenone structure), an acylphosphine oxide compound (photopolymerization initiator having an acylphosphine oxide structure), and a bistriphenylimidazole compound (photopolymerization initiator having a bistriphenylimidazole structure).

As the photopolymerization initiator, an oxime ester compound or an aminoacetophenone compound is preferable, and an oxime ester compound is more preferable.

Examples of the oxime ester compound include 1,2-octanedione, 1-[4-(phenylthio)phenyl-,2-(O-benzoyloxime)](product name: IRGACURE OXE-01; manufactured by BASF SE), ethanone,1-[9-ethyl-6-(2-methylbenzoyl)-9H-carbazol-3-yl]-,1-(0-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoropropoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the photopolymerization initiator also include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

Examples of the photopolymerization initiator also include photopolymerization initiators described in paragraphs 0031 to 0042 of JP2011-095716A and paragraphs 0064 to 0081 of JP2015-014783A.

From the viewpoint of more excellent fine pattern formability, as the photopolymerization initiator, a compound represented by Formula (P1) is also preferable.

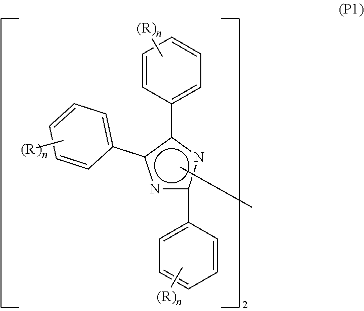

In Formula (P1), R's each independently represent a substituent.

The substituent represented by R is not particularly limited, and examples thereof include a halogen atom, an alkyl group, an alkoxy group, an alkynyl group, an alkenyl group, an aryl group, an aryloxy group, a formyl group, an acyl group, an alkoxycarbonyl group, an acyloxy group, a hydroxy group, an amino group, a carboxy group, a nitro group, and a cyano group; and from the viewpoint of more excellent effects of the present invention, a halogen atom, an alkyl group, or an alkoxy group is preferable, and an alkoxy group is more preferable.

Examples of the above-described halogen atom include a fluorine atom, a chlorine atom, a bromine atom, and an iodine atom, and a chlorine atom is preferable.

The number of carbon atoms in the alkyl group and the alkoxy group described above is preferably 1 to 10, more preferably 1 to 6, and still more preferably 1 to 3.

The number of carbon atoms in the alkynyl group, the alkenyl group, the acyl group, the alkoxycarbonyl group, and the acyloxy group described above is preferably 2 to 10, more preferably 2 to 6, and still more preferably 2 to 4.

Each group represented as the above-described substituent may further have a substituent, if possible. As such a substituent, a halogen atom, a hydroxy group, an alkyl group having 1 to 4 carbon atoms, or an alkoxy group having 1 to 4 carbon atoms is preferable, and a halogen atom or a hydroxy group is more preferable.

In a case where a plurality of R's are present, the plurality of R's may be the same or different from each other.

In Formula (P1), n's each independently represent an integer of 0 to 5, preferably an integer of 0 to 3 and more preferably an integer of 0 to 2.

The total of n's is an integer of 0 or more, and is preferably an integer of 1 or more, more preferably an integer of 0 to 10, and still more preferably an integer of 0 to 5.

In a case where n is 1 or more, it is preferable that R is located at at least one of an ortho position or a para position with respect to a bonding position to a biimidazole skeleton.

Among these, the compound represented by Formula (P1) is preferably a compound represented by Formula (P1-1) or a compound represented by Formula (P1-2), and more preferably a compound represented by Formula (P1-1).

In Formulae (P1-1) and (P1-2), definitions and suitable aspects of R and n are the same as those in Formula (P1).

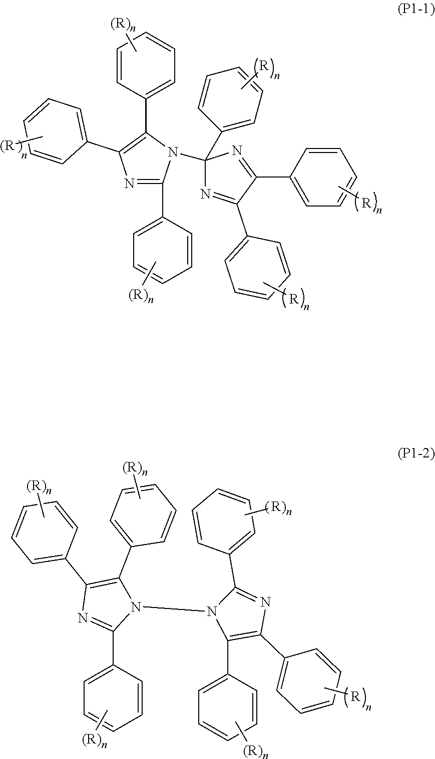

Examples of the compound represented by Formula (P1) include 2,2′-bis(2-chlorophenyl)-4,4′,5,5′-tetraphenyl-1,1′-biimidazole, 2,2′,4-tris(2-chlorophenyl)-5-(3,4-dimethoxyphenyl)-4′,5′-diphenyl-1,1′-biimidazole, 2,2′-bis(2-methoxyphenyl)-4,4′,5,5′-tetraphenyl-1,1′-biimidazole, 2-(o-chlorophenyl)-4,5-diphenylbiimidazole, 2-(o-chlorophenyl)-4,5-bis-(m-methoxyphenyl)biimidazole, 2-(p-methoxyphenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, 2,2′-bis-(2,5-difluorophenyl)-4,4′,5,5′-tetrakis-(3-methoxyphenyl)-biimidazole, 2,2′-bis-(2,6-difluorophenyl)-4,4′,5,5′-tetrakis-(3-methoxyphenyl)-biimidazole, 2,2′-bis-(2,3,4-trifluorophenyl)-4,4′,5,5′-tetrakis-(3-methoxyphenyl)-biimidazole, 2,2′-bis-(2,3,5-trifluorophenyl)-4,4′,5,5′-tetrakis-(3-methoxyphenyl)-biimidazole, 2,2′-bis-(2,3,6-trifluorophenyl)-4,4′,5,5′-tetrakis-(3-methoxyphenyl)-biimidazole, 2,2′-bis-(2,4,5-trifluorophenyl)-4,4′,5,5′-tetrakis-(3-methoxyphenyl)-biimidazole, 2,2′-bis-(2,4,6-trifluorophenyl)-4,4′,5,5′-tetrakis-(3-methoxyphenyl)-biimidazole, 2,2′-bis-(2,3,4,5-tetrafluorophenyl)-4,4′,5,5′-tetrakis-(3-methoxyphenyl)-biimidazole, 2,2′-bis-(2,3,4,6-tetrafluorophenyl)-4,4′,5,5′-tetrakis-(3-methoxyphenyl)-biimidazole, 2,2′-bis-(2,3,4,5,6-pentafluorophenyl)-4,4′,5,5′-tetrakis-(3-methoxyphenyl)-biimidazole, 2,2′,4-tris(2-fluorophenyl)-5-(3,4-dimethoxyphenyl)-4′,5′-diphenyl-1,1′-biimidazole, 2,2′-bis(2,4-dichlorophenyl)-4,4′,5,5′-tetraphenyl 1,1′-biimidazole, and 2,2′-bis(2-methoxyphenyl)-4,4′,5,5′-tetraphenyl 1,1′-biimidazole; and 2,2′-bis(2-chlorophenyl)-4,4′,5,5′-tetraphenyl-1,1′-biimidazole, 2,2′,4-tris(2-chlorophenyl)-5-(3,4-dimethoxyphenyl)-4′,5′-diphenyl-1,1′-biimidazole, or 2,2′-bis(2-methoxyphenyl)-4,4′,5,5′-tetraphenyl-1,1′-biimidazole is preferable.

The photopolymerization initiator may be used alone, or two or more types thereof may be used in combination.

A content of the photopolymerization initiator is preferably 0.01% to 10.0% by mass, more preferably 0.1% to 5.0% by mass, and still more preferably 0.1% to 3.0% by mass with respect to the total mass of the photosensitive composition layer.

### <Chain Transfer Agent>

From the viewpoint of more excellent fine pattern formability, the photosensitive composition layer preferably contains a chain transfer agent.

As the chain transfer agent, known compounds can be used, and examples thereof include an N-phenylglycine compound, a phenoxyacetic acid compound, a thiol compound, a disulfide compound, a thiophenoxy compound, a halogenated hydrocarbon, and a secondary alcohol; and an N-phenylglycine compound is preferable.

Examples of the above-described N-phenylglycine compound include N-phenylglycine and a derivative thereof, and a compound represented by Formula (II) is preferable.

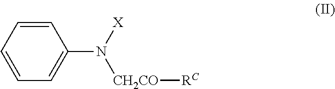

In Formula (II), X represents a hydrogen atom or a monovalent organic group.

As the above-described monovalent organic group, a hydrocarbon group which may have a substituent or a carboxy group is preferable.

The number of carbon atoms in the above-described hydrocarbon group which may have a substituent is preferably 1 to 10, and more preferably 2 to 9.

Examples of the above-described hydrocarbon group include an alkyl group, a phenyl group, and a benzyl group.

Examples of the substituent which may be included in the above-described hydrocarbon group include a carboxy group, an amino group, an alkylamino group, and an anilinocarbonyl group.

Examples of the above-described monovalent organic group include an alkyl group having 1 to 10 carbon atoms, a carboxyalkyl group having 2 to 9 carbon atoms, a carboxyphenyl group, a carboxybenzyl group, an anilinocarbonylalkyl group having 2 to 9 carbon atoms, an anilinocarbonylphenyl group, and an anilinocarbonylbenzyl group.

In Formula (II), R^{c} represents a hydroxy group, an alkoxy group, or —O-M⁺. M⁺ represents an alkali metal cation.

The number of carbon atoms in the above-described alkoxy group is preferably 1 to 3, and more preferably 1.

Examples of the above-described alkali metal cation include Li⁺, Na⁺, and K⁺.

Examples of the compound represented by Formula (II) include the following compounds.

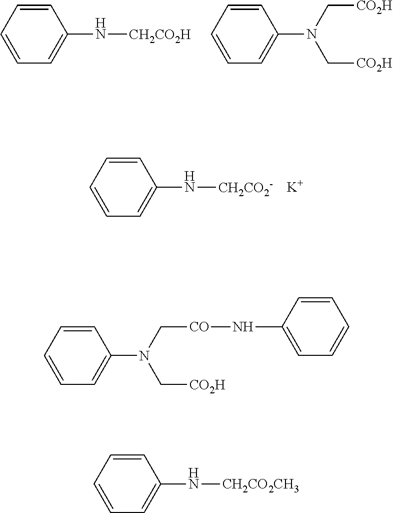

The chain transfer agent may be used alone, or two or more types thereof may be used in combination.

A content of the chain transfer agent is preferably 5.0% by mass or less, and more preferably 3.0% by mass or less with respect to the total mass of the photosensitive composition layer. The content of the chain transfer agent is preferably 0.01% by mass or more, and more preferably 0.1% by mass or more with respect to the total mass of the photosensitive composition layer.

### <Compound Having Ethylenically Unsaturated Double Bond (Polymerizable Compound)>

From the viewpoint of more excellent pattern formability, the photosensitive composition layer preferably contains a compound having an ethylenically unsaturated double bond (hereinafter, also referred to as “polymerizable compound”). The polymerizable compound is a compound different from the specific compound and the photopolymerization initiator described above.

Examples of the ethylenically unsaturated double bond included in the polymerizable compound include a (meth)acryloyl group, a (meth)acrylamide group, a vinyl group, a styryl group, an allyl group, and a vinyl ether group; and a (meth)acryloyl group is preferable.

The polymerizable compound is preferably a low-molecular-weight compound, and specifically, a molecular weight of the polymerizable compound is preferably 2,000 or less, more preferably 1,000 or less, and still more preferably 800 or less. The lower limit of the molecular weight of the polymerizable compound is preferably 120 or more, and more preferably 200 or more.

In a case where the polymerizable compound has a molecular weight distribution, it is preferable that a weight-average molecular weight thereof satisfies the above-described range.

The number of ethylenically unsaturated double bonds included in the polymerizable compound is 1 or more, preferably 2 or more, more preferably 2 to 10, and still more preferably 2 to 6.

Examples of the polymerizable compound include a polymerizable compound having one ethylenically unsaturated double bond in one molecule (hereinafter, also referred to as “monofunctional polymerizable compound”); a polymerizable compound having two ethylenically unsaturated double bonds in one molecule (hereinafter, also referred to as “bifunctional polymerizable compound”); and a polymerizable compound having three or more ethylenically unsaturated double bonds in one molecule (hereinafter, also referred to as “tri- or higher functional polymerizable compound”).

As the polymerizable compound, a bifunctional polymerizable compound or a tri- or higher functional polymerizable compound is preferable.

Examples of the bifunctional polymerizable compound include polyethylene glycol (meth)acrylate, tricyclodecane dimethanol di(meth)acrylate, 1,9-nonanediol di(meth)acrylate, and 1,6-hexanediol di(meth)acrylate.

Examples of a commercially available product of the bifunctional polymerizable compound include diethylene glycol dimethacrylate (2G, manufactured by Shin-Nakamura Chemical Co., Ltd.), triethylene glycol dimethacrylate (3G, manufactured by Shin-Nakamura Chemical Co., Ltd.), polyethylene glycol #200 dimethacrylate (4G, manufactured by Shin-Nakamura Chemical Co., Ltd.), tricyclodecane dimethanol diacrylate (A-DCP, manufactured by Shin-Nakamura Chemical Co., Ltd.), tricyclodecane dimethanol diacrylate (DCP, manufactured by Shin-Nakamura Chemical Co., Ltd.), 1,9-nonandiol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), SR205NS (manufactured by Sartomer Inc.), and SR209 (manufactured by Sartomer Inc.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound include a caprolactone-modified compound of a (meth)acrylate compound (KAYARAD (registered trademark) DPCA-20 and the like manufactured by Nippon Kayaku Co., Ltd.; and A-9300-1CL and the like manufactured by Shin-Nakamura Chemical Co., Ltd.), an alkylene oxide-modified compound of a (meth)acrylate compound (KAYARAD RP-1040 and the like manufactured by Nippon Kayaku Co., Ltd.; ATM-35E, A-9300, and the like manufactured by Shin-Nakamura Chemical Co., Ltd.; and EBECRYL (registered trademark) 135 manufactured by Daicel-Allnex Ltd.), and ethoxylated glycerin triacrylate (A-GLY-9E and the like manufactured by Shin-Nakamura Chemical Co., Ltd.).

Examples of the polymerizable compound also include urethane (meth)acrylate (preferably, tri- or higher functional urethane (meth)acrylate).

The number of polymerizable groups included in the urethane (meth)acrylate is preferably 6 or more, and more preferably 8 or more. The upper limit thereof is 20 or less. Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may have liquid crystallinity.

The polymerizable compound having liquid crystallinity may be a rod-like liquid crystal compound or a disk-like liquid crystal compound, but is preferably a rod-like liquid crystal compound.

Examples of the polymerizable compound having liquid crystallinity include a compound having a polymerizable group and a mesogen group exhibiting liquid crystallinity, and a compound in which the polymerizable group and the mesogen group are linked through a spacer is preferable.

Examples of the above-described spacer include a chain-like aliphatic hydrocarbon group and a (poly)oxyalkylene group.

Examples of the mesogen group include known mesogen groups, and examples thereof include a group in which two or more (preferably two or three) divalent ring groups (for example, a divalent aromatic ring group and a divalent alicyclic ring group) which may have a substituent are linked by a single bond or a divalent linking group.

Examples of the polymerizable compound having liquid crystallinity include compounds described in JP1999-513019A (JP-H11-513019A).

The polymerizable compound may be used alone, or two or more types thereof may be used in combination.

A content of the polymerizable compound is preferably 0.1% to 40.0% by mass, and more preferably 1.0% to 25.0% by mass with respect to the total mass of the photosensitive composition layer.

### <Filler>

From the viewpoint of more excellent dielectric characteristics of the film to be formed, the photosensitive composition layer preferably contains a filler.

From the viewpoint of more excellent insulating reliability, an average particle diameter of the filler is preferably 500 nm or less, more preferably 300 nm or less, and still more preferably 150 nm or less. The lower limit of the average particle diameter of the filler is more than 0 nm, preferably 5 nm or more, more preferably 10 nm or more, still more preferably 50 nm or more, and particularly preferably 60 nm or more. In addition, the average particle diameter of the filler is also preferably 5 to 300 nm and more preferably 10 to 150 nm.

The average particle diameter of the filler is a value calculated by the following particle diameter measuring method.

Particle diameter measuring method: a rectangular region of 3 μm×10 μm in a cross section of the photosensitive composition layer along a normal direction of a surface of the photosensitive composition layer is observed with a scanning electron microscope, an operation of measuring a major diameter of all the fillers observed in the region is performed at five different locations on the photosensitive composition layer, and an average value of all major diameters of the fillers measured in each operation is obtained as the average particle diameter of the filler.

The above-described particle diameter measuring method will be described in detail.

A photosensitive composition layer is formed on a base material (preferably a glass substrate). A thickness of the photosensitive composition layer is preferably 3 μm or more. In addition, in the formation of the photosensitive composition layer, a drying treatment may be performed as necessary after applying a composition for forming the photosensitive composition layer.

A cross section of the obtained photosensitive composition layer along the normal direction of a surface (surface opposite to the base material side) of the photosensitive composition layer is cut out, a rectangular region of 3 μm×10 μm in the cross section is observed with a scanning electron microscope, and a major diameter of all fillers observed in the region is measured. As the scanning electron microscope, S-4800 manufactured by Hitachi High-Tech Corporation is used. A magnification in the observation is 50,000 times.

The above-described operation is performed at five different positions on the photosensitive composition layer, and an average value (arithmetic mean value) of the major diameters of all the fillers measured in each operation is defined as the average particle diameter of the filler.

The above-described major diameter refers to a length of the longest line segment among line segments connecting any two points on a contour line of an outer shape of the filler in the observation image.

In addition, in a case where the fillers are aggregated in the observation image to constitute an aggregate, the major diameter of each filler constituting the aggregate is measured.

Examples of the filler include an organic filler and a mineral filler, and a mineral filler is preferable.

Examples of the filler include silicon dioxide (silica); silicate such as kaolinite, kaolin clay, calcined clay, talc, and non-doped glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler preferably includes at least one selected from the group consisting of silicon dioxide (silica), boron nitride, barium sulfate, and silicate, and more preferably includes silicon dioxide (silica).

A shape of the filler may be a spherical shape or a non-spherical shape (for example, a crushed shape and a fibrous shape), and a spherical shape is preferable.

The filler may be subjected to a surface treatment. Examples of the surface treatment include a treatment of introducing a functional group and a treatment using a known surface treatment agent. Examples of the above-described functional group include a polymerizable group (for example, a polymerizable group included in the polymerizable compound) and a hydrophobic group.

Examples of the surface treatment agent include a silane coupling agent, a titanate-based coupling agent, and a silazane compound.

Examples of a method of the surface treatment of the filler include a dry method of performing the surface treatment in a gas phase, and a wet method of performing the surface treatment in a liquid phase.

Examples of the filler include NHM-5N (manufactured by Tokuyama Corporation, silicon dioxide, concentration of solid contents: 100% by mass), NHM-3N (manufactured by TOKUYAMA CORPORATION, silicon dioxide, concentration of solid contents of 100% by mass), Sea Foster KE-S30 (manufactured by Nippon Shokubai Co., Ltd., silicon dioxide, concentration of solid contents of 100% by mass), YA050C-MJE (manufactured by Admatechs Co., Ltd., silicon dioxide, MEK slurry having a concentration of solid contents of 50% by mass), SFP-20M (manufactured by Denka Company Limited, silicon dioxide), PMA-ST (manufactured by Nissan Chemical Corporation, silicon dioxide), MEK-ST-L (manufactured by Nissan Chemical Corporation, silicon dioxide), MEK-AC-5140Z (manufactured by Nissan Chemical Corporation, silicon dioxide), MEK-EC-2430Z (manufactured by NISSAN CHEMICAL CORPORATION, concentration of solid contents of 30% by mass), barium sulfate (manufactured by SOLVAY SPECIALTY CHEMICALS JAPAN, concentration of solid contents of 100% by mass), Y50SP-AM1 (manufactured by Admatechs Co., Ltd., silicon dioxide, MEK slurry having a concentration of solid contents of 50% by mass), and Y50SZ-AM1 (manufactured by Admatechs Co., Ltd., silicon dioxide, MEK slurry having a concentration of solid contents of 50% by mass).

A refractive index of the filler is preferably 0.5 to 30.0 and more preferably 1.2 to 1.8. The refractive index can be measured by the above-described method.

The filler may be used alone or in combination of two or more thereof.

From the viewpoint of more excellent dielectric characteristics and heat resistance, a content of the filler is preferably 20.0% by mass or more, and more preferably 30.0% by mass or more with respect to the total mass of the photosensitive composition layer. In addition, from the viewpoint of level difference followability, the content of the filler is preferably 90.0% by mass or less, more preferably 80.0% by mass or less, and still more preferably 70.0% by mass or less with respect to the total mass of the photosensitive composition layer.

A mass ratio of the content of the filler to the content of the specific compound is preferably 0.5 to 30.0, more preferably 1.0 to 20.0, and still more preferably 1.0 to 4.0.

### <Thermal-Base Generator>

It is also preferable that the photosensitive composition layer contains a thermal-base generator.

In a case where the photosensitive composition layer contains a resin precursor (for example, the polyimide precursor or the polybenzoxazole precursor), reaction of the resin precursor is promoted by further containing the thermal-base generator.

As the thermal-base generator, an acidic compound or an onium salt compound (a compound consisting of a cation and an anion), which generates a base by heating, is preferable.

As the onium salt compound, an ammonium salt compound (a compound consisting of an ammonium cation and an anion), an iminium salt compound (a compound consisting of an iminium cation and an anion), a sulfonium salt compound (a compound consisting of a sulfonium cation and an anion), an iodonium salt compound (a compound consisting of an iodonium cation and an anion), or a phosphonium salt compound (a compound consisting of a phosphonium cation and an anion) is preferable; and an ammonium salt compound or an iminium salt compound is more preferable.

As the anion constituting the onium salt compound, a carboxylate anion, a phenolate anion, a phosphate anion, or a sulfate anion is preferable; and a carboxylate anion is more preferable.

It is also preferable that the anion constituting the ammonium salt compound further has an aromatic ring.

Examples of the above-described aromatic ring include an aromatic ring constituting an aromatic ring group represented by A^{a1} in Formula (A1) described later.

The base generated by the thermal-base generator is preferably a secondary amine or a tertiary amine, and more preferably a tertiary amine. The above-described base may be linear, branched, or cyclic, and is preferably cyclic.

As the acidic compound, a compound represented by Formula (A1) is preferable.

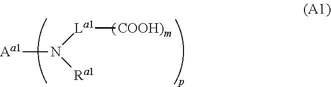

In Formula (A1), A^{a1} represents a p-valent organic group, R^{a1} represents a monovalent organic group, L^{a1} represents an (m+1)-valent linking group, m represents an integer of 1 or more, and p represents an integer of 1 or more.

In Formula (A1), A^{a1} represents a p-valent organic group.

Examples of the above-described organic group include an aliphatic hydrocarbon group and an aromatic ring group; and an aromatic ring group is preferable.

Examples of a monovalent aliphatic hydrocarbon group include an alkyl group and an alkenyl group.

The above-described alkyl group may be linear, branched, or cyclic. The number of carbon atoms in the above-described alkyl group is preferably 1 to 30, more preferably 1 to 20, and still more preferably 1 to 10.

Examples of the above-described alkyl group include a methyl group, an ethyl group, a tert-butyl group, a dodecyl group, a cyclopentyl group, a cyclohexyl group, a cycloheptyl group, and an adamantyl group.

The alkenyl group may be linear, branched, or cyclic. The number of carbon atoms in the alkenyl group is preferably 2 to 30, more preferably 2 to 20, and still more preferably 2 to 10.

Examples of the alkenyl group include a vinyl group, an allyl group, and a methallyl group.

Examples of the p-valent (p is an integer of 2 or more) aliphatic hydrocarbon group include a group formed by removing (p−1) hydrogen atoms from the above-described monovalent aliphatic hydrocarbon group.

The aliphatic hydrocarbon group may further have a substituent.

The aromatic ring group may be monocyclic or polycyclic.

The aromatic ring group may be any one of an aromatic hydrocarbon ring group or an aromatic heterocyclic group.

Examples of the aromatic ring group include a benzene ring group, a naphthalene ring group, a biphenyl ring group, a fluorene ring group, a pentalene ring group, an indene ring group, an azulene ring group, a heptalene ring group, an indacene ring group, a perylene ring group, a pentacene ring group, an acenaphthene ring group, a phenanthrene ring group, an anthracene ring group, a naphthacene ring group, a chrysene ring group, and a triphenylene ring group, a fluorene ring group, a biphenyl ring group, a pyrrole ring group, a furan ring group, a thiophene ring group, an imidazole ring group, an oxazole ring group, a thiazole ring group, a pyridine ring group, a pyrazine ring group, a pyrimidine ring group, a pyridazine ring group, an indridine ring group, an indole ring group, a benzofuran ring group, a benzothiophene ring group, an isobenzofuran ring group, a quinolizine ring group, a quinoline ring group, a phthalazine ring group, a naphthyridine ring group, a quinoxaline ring group, a quinoxazoline ring group, an isoquinoline ring group, a carbazole ring group, a phenanthridine ring group, an acridine ring group, a phenanthroline ring group, a thianthrene ring group, a chromene ring group, a xanthene ring group, a phenoxathiin ring group, a phenothiazine ring group, and a phenazine ring group; and a benzene ring group is preferable.

The aromatic ring group may further have a substituent.

In Formula (A1), R^{a1} represents a monovalent organic group.

Examples of the monovalent organic group include the monovalent aliphatic hydrocarbon group and the monovalent aromatic ring group represented by A^{a1}.

The monovalent organic group may further have a substituent. The above-described substituent is preferably a carboxy group.

In Formula (A1), Lai represents an (m+1)-valent linking group.

Examples of the (m+1)-valent linking group include a divalent linking group such as an ether group (—O—), a carbonyl group (—CO—), an ester group (—COO—), a thioether group (—S—), —SO₂—, —NR^{N}— (R^{N} represents a hydrogen atom or a substituent), an alkylene group (preferably having 1 to 10 carbon atoms), and an alkenylene group (preferably having 2 to 10 carbon atoms); a trivalent linking group having a group represented by “—N<” and a trivalent linking group having a group represented by “—CR<” (R represents a hydrogen atom or a substituent); a tetravalent linking group having a group represented by “>C<”; a k-valent linking group having a ring group such as an aromatic ring group and an alicyclic ring group; and a group formed by a combination of these groups.

In Formula (A1), m represents an integer of 1 or more.

m is preferably 1 or 2, and more preferably 1.

In Formula (A1), p represents an integer of 1 or more.

p is preferably 1 or 2, and more preferably 1.

Examples of the thermal-base generator include thermal-base generators described in WO2018/038002A.

A temperature at which the thermal-base generator generates a base is preferably a heating temperature of a step 5 in a pattern forming method described later.

The temperature at which the thermal-base generator generates a base is, for example, preferably 50° C. to 400° C. and more preferably 100° C. to 250° C.

A measurement value or a literature value by a known measuring method can be used as the temperature at which the thermal-base generator generates a base. For example, a peak temperature of a heat generation peak having the lowest temperature in a case where a measurement target compound is heated up to 250° C. at 5° C./min in a pressure-resistant capsule using differential scanning calorimetry can be used as the base generation temperature.

The thermal-base generator may be used alone or in combination of two or more thereof.

A content of the thermal-base generator is preferably 0.01% to 10.0% by mass, and more preferably 0.1% to 5.0% by mass with respect to the total mass of the photosensitive composition layer.

A mass ratio of the content of the thermal-base generator to the content of the specific compound is preferably 0.0005 to 1.0, more preferably 0.001 to 0.1, and still more preferably 0.01 to 0.05.

### <Plasticizer>

The photosensitive composition layer may contain a plasticizer.

In a case of containing the plasticizer, it is preferable from the viewpoint that the level difference followability of the photosensitive composition layer in a case of being bonded (laminated) to an adherend is excellent and the pattern formability is more excellent.

The plasticizer is a compound different from the above-described various components, and preferably does not have a polymerizable group.

A molecular weight of the plasticizer is preferably 200 to 1,000, more preferably 250 to 800, and still more preferably 300 to 600.

In a case where the plasticizer has a molecular weight distribution, the above-described molecular weight is intended to be a weight-average molecular weight.

A boiling point of the plasticizer is preferably 230° C. to 500° C., more preferably 280° C. to 480° C., still more preferably 300° C. to 450° C., and particularly preferably 350° C. to 450° C.

The above-described boiling point is a boiling point at normal pressure (760 mmHg).

In the present specification, a boiling point of a compound is a value obtained by the following measuring method.

In a case where the compound is distilled under normal pressure (760 mmHg), a temperature of a gas at a point in time when condensation of the evaporated gas starts is defined as the boiling point (measured at 23° C. to 300° C.; temperature rising rate: 1° C./min).

The compound is distilled using a Liebig condenser, and in a case where the distillation does not start at 300° C. under normal pressure, the compound Y is distilled under reduced pressure. The same distillation is performed in the order of an atmospheric pressure of 100 mmHg, 50 mmHg, and 5 mmHg (measured at 23° C. to 300° C.; temperature rising rate: 1° C./min; in a case where the distillation does not start at 300° C., the distillation is performed at the next pressure), and from the temperature and pressure at which the condensation of the evaporated gas starts, the boiling point under normal pressure is defined as the boiling point (calculated value) obtained using a nomograph described in Science of Petroleum, Vol. II, p. 1281 (1938). In a case where the distillation does not start at 300° C. under 5 mmHg, the boiling point under normal pressure is considered to be higher than 500° C. The nomograph is used by a known method. Specifically, a boiling point of the A line under reduced pressure and a degree of reduction of the C line are connected by a straight line (procedure 1), a numerical value of an intersection of the straight line drawn in the procedure 1 and the B line is read (procedure 2), and this is regarded as the boiling point under normal pressure.

A viscosity of the plasticizer at 25° C. is preferably 0.01 to 500 mPa·s, more preferably 0.05 to 300 mPa·s, and still more preferably 0.1 to 100 mPa·s.

The above-described viscosity can be measured with a B-type viscometer.

Examples of the plasticizer include polycarboxylic acid esters, phosphoric acid esters, polyether esters, alkylene glycol monoalkyl ethers, alkylene glycol dialkyl ethers, and benzyl benzoate; and polycarboxylic acid esters are preferable.

Examples of the polycarboxylic acid esters include aliphatic dicarboxylic acid esters (for example, adipic acid esters, azelaic acid esters, and sebacic acid esters); aromatic dicarboxylic acid esters (for example, phthalic acid esters); trimellitic acid esters; and citric acid esters (for example, acetyl citric acid tributyl esters).

Examples of the polycarboxylic acid esters include ethyl phthalyl ethyl glycolate, dihexyl phthalate, tributyl o-acetyl citrate, benzyl 2-ethylhexyl phthalate, bis(2-ethylhexyl) isophthalate, tris(2-ethylhexyl) trimellitate, and bis(2-butoxyethyl) adipate.

Examples of the phosphoric acid esters include triamyl phosphate and tris(2-butoxyethyl) phosphate.

The polyether esters are preferably organic acid esters of polyalkylene glycol. Examples of the organic acid include monocarboxylic acids (for example, butyric acid, isobutyric acid, 2-ethylbutyric acid, 2-ethylhexyl acid, and decanoic acid). Specific examples of the polyether esters include triethylene glycol bis(2-ethylhexanoate).

Examples of the alkylene glycol monoalkyl ethers and alkylene glycol dialkyl ethers include hexaethylene glycol monomethyl ether (mPEG6-OH), pentaethylene glycol monomethyl ether, tetraethylene glycol monomethyl ether, heptaethylene glycol monomethyl ether, octaethylene glycol monomethyl ether, nonaethylene glycol monomethyl ether, pentaethylene glycol dimethyl ether, hexaethylene glycol dimethyl ether, heptaethylene glycol dimethyl ether, octaethylene glycol dimethyl ether, and nonaethylene glycol dimethyl ether.

The plasticizer may be used alone or in combination of two or more thereof.

A content of the plasticizer is preferably 1.0% to 50.0% by mass, and more preferably 3.0% to 30.0% by mass with respect to the total mass of the photosensitive composition layer.

A mass ratio of the content of the plasticizer to the content of the specific compound is preferably 0.1 to 10.0 and more preferably 0.5 to 7.0.

A mass ratio of the content of the plasticizer to the content of the filler is preferably 0.01 to 1.0 and more preferably 0.2 to 0.7.

### <Surfactant>

It is also preferable that the photosensitive composition layer contains a surfactant.

Examples of the surfactant include a fluorine-based surfactant, a hydrocarbon-based surfactant, and a silicone-based surfactant. As the surfactant, a silicone-based surfactant is preferable. From the viewpoint of improving environmental suitability, it is also preferable that the surfactant does not contain a fluorine atom.

Examples of the surfactant include the surfactants which may be contained in the water-soluble resin layer described above.

The surfactant may be used alone, or two or more types thereof may be used in combination.

A content of the surfactant is preferably 0.01% to 3.0% by mass, more preferably 0.05% to 1.0% by mass, and still more preferably 0.1% to 0.8% by mass with respect to the total mass of the photosensitive composition layer.

### <Rust Inhibitor>

It is also preferable that the photosensitive composition layer contains a rust inhibitor.

Examples of the rust inhibitor include a heterocyclic compound. Examples of the heterocyclic compound include a triazole compound, a benzotriazole compound, a tetrazole compound, a thiadiazole compound, a triazine compound, a rodanin compound, a thiazole compound, a benzothiazole compound, a benzimidazole compound, a benzoxazole compound, a pyrimidine compound, and a pyridine compound; and a triazole compound, a benzotriazole compound, or a tetrazole compound is preferable.

Examples of the heterocyclic compound include compounds described in WO2022/039027A.

The rust inhibitor may be used alone or in combination of two or more thereof.

A content of the rust inhibitor is preferably 0.01% to 3.0% by mass, more preferably 0.05% to 1.0% by mass, and still more preferably 0.1% to 0.8% by mass with respect to the total mass of the photosensitive composition layer.

### <Other Additives>

The photosensitive composition layer may contain other additives other than those described above.

Examples of the other additives include a photoacid generator, a curing agent, an aliphatic thiol compound, a thermal crosslinking compound, a polymerization inhibitor, a hydrogen donating compound, a solvent, impurities, a sensitizer, an alkoxysilane compound, a maleimide compound, and a hydrosilylation agent.

### (Solvent)

The photosensitive composition layer may contain a solvent.

The solvent is not particularly limited as long as it can dissolve or disperse the various components which can be contained in the photosensitive composition layer, other than the solvent.

Examples of the solvent include water, an alkylene glycol ether solvent, an alkylene glycol ether acetate solvent, an alcohol solvent (for example, methanol, ethanol, and the like), a ketone solvent (for example, acetone, methyl ethyl ketone, and the like), an aromatic hydrocarbon solvent (for example, toluene and the like), an aprotic polar solvent (for example, N,N-dimethylformamide and the like), a cyclic ether solvent (for example, tetrahydrofuran and the like), an ester solvent (for example, n-propyl acetate and the like), an amide solvent, a lactone solvent, and a solvent including two or more kinds thereof.

The solvent may be used alone or in combination of two or more kinds thereof.

A content of the solvent is preferably 50 to 1,900 parts by mass, more preferably 100 to 1,200 parts by mass, and still more preferably 100 to 900 parts by mass with respect to 100 parts by mass of the total solid content of the photosensitive composition layer.

### (Polymerization Inhibitor)

From the viewpoint of more excellent fine pattern formability, the photosensitive composition layer also preferably contains a polymerization inhibitor.

Examples of the polymerization inhibitor include radical scavengers, and specific examples thereof include imino compounds such as phenothiazine, phenoxazine, and bis(2,2,6,6-tetramethyl-4-piperidyl) sebacate, phenolic compounds such as hydroquinone, 4-tert-butylcatechol, 2-tert-butylhydroquinone, hydroquinone monomethyl ether, 2,6-di-tert-butyl-p-cresol, 2,2′-methylenebis(4-methyl-6-tert-butylphenol), 1,1,3-tris(2-methyl-4-hydroxy-5-tert-butylphenyl)butane, 1,3,5-trimethyl-2,4,6-tris(3, 5-di-tert-butyl-4-hydroxybenzyl)benzene, and 1,3,5-tris(3′,5′-di-tert-butyl-4-hydroxybenzyl)-S-triazine-2,4,6-(1H,3H,5H)trione, quinone compounds such as methaquinone and benzoquinone, nitro compounds, and nitroso compounds; and phenothiazine, phenoxazine, or a quinone compound is preferable.

The polymerization inhibitor may be used alone, or two or more types thereof may be used in combination.

A content of the polymerization inhibitor is preferably 0.01% to 5.0% by mass, and more preferably 0.1% to 3.0% by mass with respect to the total mass of the photosensitive composition layer.

### (Sensitizer)

From the viewpoint of more excellent fine pattern formability, the photosensitive composition layer also preferably contains a sensitizer.

The sensitizer is not particularly limited, and examples thereof include a benzoin-based compound, a benzophenone-based compound, a xanthone-based compound, a thioxanthone-based compound, an acetophenone-based compound, an anthraquinone-based compound, a ketal-based compound, a fluorene-based compound, a naphthoquinone-based compound, and a coumarin-based compound; and a benzophenone-based compound or a thioxanthone-based compound is preferable, and a benzophenone-based compound is more preferable.

Examples of the benzophenone-based compound include benzophenone, 4,4′-bis(dimethylamino)benzophenone, 4,4′-bis(diethylamino)benzophenone (EAB-F), and 4,4′-bis(ethylmethylamino)benzophenone; and EAB-F is preferable.

Examples of the sensitizer also include compounds described in paragraphs 0113 to 0116 of JP2021-120946A, the contents of which are incorporated herein by reference.

A content of the sensitizer is preferably 5.0% by mass or less, and more preferably 1.0% by mass or less with respect to the total mass of the photosensitive composition layer. The content of the sensitizer is preferably 0.01% by mass or more, and more preferably 0.1% by mass or more with respect to the total mass of the photosensitive composition layer.

Examples of the aliphatic thiol compound, the thermal crosslinking compound, the polymerization inhibitor, and the hydrogen donating compound include various components described in WO2022/039027A.

Examples of the sensitizer and the alkoxysilane compound also include components described in paragraphs 0097 to 0119 of WO2018/179640A.

Examples of the maleimide compound (a compound having a maleimide ring) include known maleimide compounds and maleimide compounds described in WO2022/102756A.

Examples of the hydrosilylation agent include platinum catalysts such as carbon powder carrying a platinum metal, platinum black, second platinum chloride, platinum chloric acid, a reaction product of platinum chloric acid and monohydric alcohol, a complex of platinum chloric acid and olefins, and platinum bisacetoacetate; and platinum group metal-based catalysts such as a palladium-based catalyst and a rhodium-based catalyst. The hydrosilylation agent is preferably used as a curing agent in a case where a silicone resin or a precursor thereof is used as the resin.

The photosensitive composition layer may contain a component derived from the water-soluble resin layer (for example, the water-soluble resin).

### <Requirement 1 and Requirement 2>

From the viewpoint of more excellent pattern formability and heat resistance, the photosensitive composition layer preferably satisfies at least one of a requirement 1 or a requirement 2, and more preferably satisfies both the requirement 1 and the requirement 2.

Requirement 1: the specific compound has an ethylenically unsaturated double bond.

Requirement 2: the photosensitive composition layer contains a compound having an ethylenically unsaturated double bond (polymerizable compound).

A film thickness of the photosensitive composition layer is not particularly limited, but is preferably 1 to 100 μm, more preferably 3 to 50 μm, and still more preferably 3 to 30 μm.

### [Other Layers]

The transfer film may include other layers.

### <Cover Film>

The transfer film may include a cover film. It is preferable that the cover film is provided on the outermost surface of the photosensitive composition layer opposite to the water-soluble resin layer.

The number of fisheyes with a diameter of 80 μm or more in the cover film is preferably 5 pieces/m² or less. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, and still more preferably 5 particles/mm² or less. As a result, it is possible to suppress defects caused by ruggedness due to the particles contained in the cover film being transferred to the composition layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film is excellent. In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

Examples of the cover film include cover films described in paragraphs 0083 to 0087 and 0093 of JP2006-259138A.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

The transfer film may include a layer of high refractive index.

Examples of the layer of high refractive index include those described in paragraphs 0168 to 0188 of WO2021/187549A, the contents of which are incorporated in the present specification.

### [Surface Free Energy]

From the viewpoint that adhesiveness between the film formed from the transfer film and the insulating film is more excellent and the effects of the present invention are more excellent, a surface free energy of the transfer film measured by a measurement X is preferably 30 mJ/m² or more, and more preferably 40 mJ/m² or more. In addition, the above-described surface free energy is often 80 mJ/m² or less, and is preferably 70 mJ/m² or less, and more preferably 60 mJ/m² or less.

A polarity component of the above-described surface free energy is preferably 5 mJ/m² or more, more preferably 10 mJ/m² or more, and still more preferably 15 mJ/m² or more. In addition, the polarity component of the above-described surface free energy is often 50 mJ/m² or less, and is preferably 40 mJ/m² or less, and more preferably 30 mJ/m² or less.

Measurement X: in a case where a laminate is obtained by bonding the transfer film and a base material in a state in which the photosensitive composition layer of the transfer film faces the base material, the temporary support is peeled off from the laminate, an entire surface of the photosensitive composition layer is exposed from an exposed water-soluble resin layer side to remove the water-soluble resin layer, and an exposed photosensitive composition layer is heated at 200° C. for 1.5 hours in a nitrogen atmosphere to obtain a cured layer, a surface free energy of a surface of the cured layer, opposite to the base material side, is measured.

A bonding method of the transfer film and the substrate is not particularly limited, and examples thereof include a method described in a step 1 of the pattern forming method described later.

An exposure method of the photosensitive composition layer is not limited as long as the exposure is performed on the entire surface of the photosensitive composition layer from the water-soluble resin layer side exposed by peeling off the temporary support.

A light source used for the exposure may be any light source as long as it irradiates various components which can be photo-sensitized in the photosensitive composition layer with light in a photosensitive wavelength range (for example, light in a wavelength range of 254 nm, 313 nm, 365 nm, 405 nm, and the like). Specific examples thereof include an ultra-high pressure mercury lamp, a high pressure mercury lamp, a metal halide lamp, and a light emitting diode (LED).

An exposure amount is preferably 5 to 2,000 mJ/cm² and more preferably 100 to 1,500 mJ/cm².

Among these, the exposure amount (integrated illuminance) measured with an illuminance meter at a wavelength of 365 nm is preferably 1,000 mJ/cm².

A removing method of the water-soluble resin layer is not particularly limited, and examples thereof include removal using water or an alkali developer.

Examples of the alkali developer include an alkali developer which can be used in a step 4 of the pattern forming method described later.

Specifically, the surface free energy of the cured layer is measured by the following method according to Owens and Wendt method (J. Appl. Polym. Sci., 13, pp. 1741 to 1747 (1969)).

A contact angle between the cured layer and a test liquid is measured using a contact angle meter. As the test liquid, pure water and methylene iodide are used. The above-described contact angle is measured three times at different positions, and an average value thereof is adopted. As the contact angle meter, for example, a contact angle meter CA-A manufactured by Kyowa Interface Science Co., Ltd. can be used.

The surface free energy of the cured layer, and the polarity component and the dispersion component of the surface free energy of the cured layer are calculated from the obtained contact angle and the surface free energy of the test liquid (pure water and methylene iodide) based on Expressions (1) to (3).

$$1 + cos θ = ( 2 / {γ}_{L} ) ( {( γ {s}^{d} {γ}_{L}^{d} )}^{1 / 2} + {( γ {s}^{p} {γ}_{L}^{p} )}^{1 / 2} ) \qquad Expression ( 1 )$$

$$γ s = γ {s}^{d} + γ {s}^{p} \qquad Expression ( 2 )$$

$${γ}_{L} = {γ}_{L}^{d} + {γ}_{L}^{p} \qquad Expression ( 3 )$$

In Expressions (1) to (3), θ represents a contact angle between the cured layer and each test liquid. γ_{S} represents the surface free energy of the cured layer, γ_{S}^{d} represents the dispersion component of the surface free energy of the cured layer, and γ_{S}^{p} represents the polarity component of the surface free energy of the cured layer. γ_{L} represents the surface free energy of the test liquid, γ_{L}^{d} represents the dispersion component of the surface free energy of the test liquid, and γ_{L}^{p} represents the polarity component of the surface free energy of the test liquid. As the surface free energy of the test liquid, pure water: γ_{L}^{d}=21.8 mJ/m², γ_{L}^{p}=51.0 mJ/m², and methylene iodide: γ_{L}^{d}=49.5 mJ/m², γ_{L}^{p}=1.3 mJ/m² are used.

A more detailed measurement method of the surface free energy of the cured layer by the measurement X is as described in Examples later.

A method of adjusting the surface free energy of the cured layer is not particularly limited, and examples thereof include a method of bringing into contact with a hydrophilic composition (for example, a water-soluble resin layer) before curing and a method of adjusting the formulation of the photosensitive composition layer. It is presumed that, in a case of bringing into contact with the hydrophilic composition before curing, a part of components of the hydrophilic composition is transferred to the photosensitive composition layer side, and as a result, the surface free energy of the cured layer is affected.

The transfer film according to the embodiment of the present invention includes the photosensitive composition layer and the water-soluble resin layer, whereby the surface free energy of the cured layer can be easily adjusted to a suitable value while maintaining the performance of the film to be formed.

### [Manufacturing Method of Transfer Film]

As a manufacturing method of the transfer film, a known manufacturing method can be adopted.

Specific examples thereof include a method of forming the water-soluble resin layer by applying a composition for forming the water-soluble resin layer onto a temporary support and then forming the photosensitive composition layer by applying a composition for forming the photosensitive composition layer onto the water-soluble resin layer.

It is preferable that the water-soluble resin layer is formed by drying a coating film after applying the composition for forming the water-soluble resin layer.

In addition, it is preferable that the photosensitive composition layer is formed by drying a coating film after applying the composition for forming the photosensitive composition layer.

Examples of an applying method include slit coating, spin coating, curtain coating, and inkjet coating.

Examples of a manufacturing method of the transfer film 100 shown in FIG. 1 include a method including a step of forming the water-soluble resin layer 14 by applying a composition for forming a water-soluble resin layer onto a surface of the temporary support 12 to form a coating film, and then drying the coating film, and a step of forming the photosensitive composition layer 16 by applying a composition for forming a photosensitive composition layer onto a surface of the water-soluble resin layer 14 to form a coating film, and then drying the coating film.

Furthermore, a transfer film including a cover film may be manufactured by pressure-bonding a cover film to the photosensitive composition layer 16 of the transfer film manufactured by the above-described manufacturing method. In addition, the transfer film may be wound after the manufacturing to be stored as the transfer film in a roll form. The roll-shaped transfer film is provided as it is in a bonding step described later with the base material in a roll-to-roll method.

### [Applications]

It is preferable that the transfer film is used for forming a pattern and/or forming a film.

The pattern and film described above can be applied to various applications, for example, as an electrode protective film, an insulating film, a flattening film, an overcoat film, a hard coat film, a passivation film, a partition wall, a spacer, a microlens, an optical filter, an anti-reflection film, an etching resist, or a plating member.

More specific examples thereof include a protective film or an insulating film for a touch panel electrode, a protective film or an insulating film for a printed wiring board, a protective film or an insulating film for a TFT substrate, an interlayer insulating film in a build-up substrate of a semiconductor package, an organic interposer, a color filter, an overcoat film for a color filter, and an etching resist for a wiring formation.

Among these, the transfer film can be suitably used for forming an insulating film, and the insulating film is preferably used as an insulating film for a semiconductor package. That is, the transfer film is preferably used for forming an insulating film for a semiconductor package.

In addition, it is also preferable that the above-described transfer film is used for manufacturing a laminate including a composition layer having a pattern on a base material.

### [Pattern Forming Method]

The pattern forming method according to the embodiment of the present invention is not particularly limited as long as it is a method of forming a pattern derived from the photosensitive composition layer on a base material using the above-described transfer film, but it is preferably a method of forming a pattern having a via on a base material, and specifically, it preferably includes the following steps 1 to 4.
Step 1: step of obtaining a laminate by bonding the transfer film and a base material in a state in which the photosensitive composition layer of the transfer film faces the base material
Step 2: step of removing the temporary support from the laminate
Step 3: step of exposing the photosensitive composition layer from the water-soluble resin layer side of the laminate from which the temporary support is removed in a patterned manner
Step 4: step of removing the water-soluble resin layer and an unexposed photosensitive composition layer from the pattern-exposed laminate to form a pattern having a via Hereinafter, each of the steps will be described in detail.

### [Step 1]

The step 1 is a step of obtaining a laminate by bonding the transfer film and a base material in a state in which the photosensitive composition layer of the transfer film faces the base material.

Examples of the bonding method include a known transfer method and a known laminating method; and a method in which the base material is superimposed on the surface of the photosensitive composition layer and pressurization and heating are performed using a roll or the like is preferable.

Examples of the above-described laminating method include known laminators such as a vacuum laminator and an auto-cut laminator.

A laminating temperature is not particularly limited, but is preferably 70° C. to 130° C.

In a case of using the transfer film, the step 1 is preferably performed by a roll-to-roll method. The base material to which the transfer film is bonded is preferably a resin film or a resin film having a conductive layer.

The roll-to-roll method refers to a method in which, as the base material, a base material which can be wound up and unwound is used, a step of unwinding the base material before any of the steps included in the pattern forming method according to the embodiment of the present invention, a step of winding the base material is included after any of the steps, and at least one of the steps (preferably, all steps or all steps other than the heating step) is performed while transporting the base material.

As an unwinding method in the unwinding step and a winding method in the winding step, a known method may be used in the manufacturing method to which the roll-to-roll method is adopted.

### <Base Material>

Examples of the base material include a glass substrate, a glass epoxy substrate, a silicon substrate, a resin substrate, and a substrate having a conductive layer.

A refractive index of the base material is preferably 1.50 to 1.52.

The base material may be composed of a translucent substrate such as a glass substrate, and for example, tempered glass typified by Gorilla glass of Corning Incorporated can also be used. In addition, examples of the material contained in the above-described base material also include materials used in JP2010-086684A, JP2010-152809A, and JP2010-257492A.

In a case where the above-described base material includes a resin substrate, as the resin substrate, a resin film having a small optical distortion and/or a high transparency is more preferable. Specific examples thereof include polyethylene terephthalate (PET), polyethylene naphthalate, polycarbonate, triacetyl cellulose, a cycloolefin polymer, and polyimide.

As the substrate having a conductive layer, from the viewpoint that it is possible to manufacture by a roll-to-roll method, a resin substrate having a conductive layer is preferable and a resin film having a conductive layer is more preferable. The substrate having a conductive layer may be the laminate obtained by the above-described pattern forming method.

Examples of the conductive layer include any conductive layer used for general circuit wiring or touch panel wiring.

As the conductive layer, from the viewpoint of conductivity and fine line formability, one or more layers selected from the group consisting of a metal layer (for example, a metal foil or the like), a conductive metal oxide layer, a graphene layer, a carbon nanotube layer, and a conductive polymer layer are preferable, a metal layer is more preferable, and a copper layer or a silver layer is still more preferable.

The conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, preferably less than 1×10⁴ Ω·cm.

The conductive layer may be patterned.

Examples of a manufacturing method of the patterned conductive layer include a subtractive method such as an etching method, and an additive method. Examples of the etching method include a method by wet etching, which is described in paragraphs 0048 to 0054 of JP2010-152155A, and a method by dry etching such as a known plasma etching. In addition, the etching method may be a method using an etching resist.

### [Step 2]

The step 2 is a step of removing the temporary support from the laminate including the base material, the photosensitive composition layer, the water-soluble resin layer, and the temporary support in this order, which is obtained in the step 1. By including the step 2, the pattern forming method according to the embodiment of the present invention can exclude the influence of the temporary support during the exposure, and thus the pattern formability is excellent.

A method of removing the temporary support is not particularly limited, and a known method can be used. Examples thereof include a method of peeling off the temporary support, and the peeling may be performed by a roll-to-roll method. Details of the roll-to-roll method are as described above.

From the viewpoint of preventing contamination of the exposed water-soluble resin layer and photosensitive composition layer, it is also preferable that the laminate from which the temporary support is removed by the roll-to-roll method is continuously subjected to the treatment of the step 3 without passing through a winding step.

### [Step 3]

The step 3 is a step of exposing the photosensitive composition layer from the water-soluble resin layer side of the laminate including the base material, the photosensitive composition layer, and the water-soluble resin layer in this order, which is obtained in the step 2, in a patterned manner.

The “pattern exposure” refers to exposure in a patterned manner, that is, exposure in which an exposed portion and a non-exposed portion are present. A positional relationship between the exposed portion and the non-exposed portion in the pattern exposure is not particularly limited and is appropriately adjusted.

A light source used for the exposure may be any light source as long as it irradiates various components (for example, the photopolymerization initiator and the like) which can be photo-sensitized in the photosensitive composition layer with light in a photosensitive wavelength range (for example, light in a wavelength range of 254 nm, 313 nm, 365 nm, 405 nm, and the like). Specific examples thereof include an ultra-high pressure mercury lamp, a high pressure mercury lamp, a metal halide lamp, and a light emitting diode (LED).

An exposure amount is preferably 5 to 2,000 mJ/cm² and more preferably 10 to 1,500 mJ/cm².

The pattern exposure may be an exposure through a mask or a direct exposure using a laser or the like. In a case of performing the exposure through a mask, the exposure may be performed in a state in which the mask and the water-soluble resin layer are in contact with each other, or the exposure may be performed in a state in which the mask and the water-soluble resin layer are not in contact with each other.

Examples of the mask include a quartz mask, a soda-lime glass mask, and a film mask. From the viewpoint of excellent dimensional accuracy, a quartz mask is preferable, and from the viewpoint that it is easy to increase the size, a film mask is preferable.

As a material of the film mask, a polyester film is preferable, and a polyethylene terephthalate film is more preferable. Specific examples of the material of the film mask include XPR-7S SG (manufactured by Fujifilm Global Graphic Systems).

### [Step 4]

The step 4 is a step of removing the water-soluble resin layer and an unexposed photosensitive composition layer from the pattern-exposed laminate obtained in the step 3 to form a pattern having a via.

A known method can be used as a method of removing the water-soluble resin layer and the photosensitive composition layer, and examples thereof include a method using a developer.

Examples of the method of removing the water-soluble resin layer include removal using water or an alkali developer.

Examples of the method of removing the unexposed photosensitive composition layer include removal using an alkali developer or an organic solvent developer.

The water-soluble resin layer and the unexposed photosensitive composition layer described above may be sequentially removed or simultaneously removed according to the formulation of each layer. For example, after removing the water-soluble resin layer using an alkali developer, the unexposed photosensitive composition layer may be removed using an organic solvent developer; or the water-soluble resin layer and the unexposed photosensitive composition layer may be simultaneously removed using an alkali developer.

As the alkali developer, an alkali aqueous solution is preferable.

As the alkali aqueous solution, a liquid containing a compound having a pKa of 7 to 13 at a concentration of 0.05 to 5 mol/L is preferable.

A content of the water in the alkali developer is preferably 50% by mass or more, more preferably 60% by mass or more, still more preferably 85% by mass or more, particularly preferably 90% by mass or more, and most preferably 95% by mass or more with respect to the total mass of the alkali developer. The upper limit thereof is preferably less than 100% by mass with respect to the total mass of the alkali developer.

Examples of the alkali developer include a sodium carbonate aqueous solution, a potassium carbonate aqueous solution, a sodium hydroxide aqueous solution, a potassium hydroxide aqueous solution, and a tetramethylammonium hydroxide (TMAH) aqueous solution. Examples of a concentration of alkali components constituting the above-described alkali developer include a 0.1% by mass aqueous solution, a 1.0% by mass aqueous solution, and a 2.38% by mass aqueous solution.

In addition, the alkali developer may contain a water-soluble organic solvent, a surfactant, and the like. Examples of the alkali developer include developers described in paragraph 0194 of WO2015/093271A.

Examples of the organic solvent developer include developers containing an organic solvent such as a ketone solvent, an ester solvent, an alcohol solvent, an amide solvent, an ether solvent, and a hydrocarbon solvent.

As the organic solvent developer, cyclopentanone or propylene glycol monomethyl ether acetate is preferable.

In the organic solvent developer, a plurality of organic solvents may be mixed, or may be mixed with an organic solvent other than the above or water. A content of water in the organic solvent developer is preferably less than 10% by mass with respect to the total mass of the organic solvent developer, and it is more preferable that the organic solvent developer does not substantially contain water. A content of the organic solvent in the organic solvent developer is preferably 50% by mass or more, more preferably 60% by mass or more, still more preferably 85% by mass or more, particularly preferably 90% by mass or more, and most preferably 95% by mass or more with respect to the total mass of the organic solvent developer. The upper limit thereof is preferably 100% by mass or less with respect to the total mass of the organic solvent developer.

A known development method can be used as the method of removing the developer. Examples thereof include puddle development, shower development, spin development, and dip development. In the shower development, unnecessary portions can be removed by spraying the developer on the composition layer after the exposure with a shower. In addition, after the development, it is also preferable to spray a washing agent and the like with a shower and rub with a brush and the like to remove the developing residue. A liquid temperature of the developer is preferably 20° C. to 40° C.

The pattern having a via may be formed only on the photosensitive composition layer, or may be formed on both the photosensitive composition layer and the base material.

The pattern having a via may be a through-hole or a via hole.

Examples of a shape of the above-described via include, as a cross-sectional shape, a quadrangular shape, a trapezoidal shape, and an inverted trapezoidal shape; and as a front shape, a circular shape and a quadrangular shape (a shape in a case where the via is observed from a direction in which a via bottom is seen). Among these, an inverted trapezoidal shape is preferable as the cross-sectional shape from the viewpoint of improving attachability of the copper plating to the via wall surface.

A size (diameter) of the via is preferably 300 μm or less, more preferably 100 μm or less, still more preferably 50 μm or less, and particularly preferably 5 μm or less. The lower limit thereof is preferably 1 μm or more.

The number of the above-described vias may be 1 or more, preferably 2 or more.

### [Step 5]

It is also preferable that the pattern forming method according to the embodiment of the present invention includes, after the step 4, a step 5 of performing at least one of a heating treatment or an exposure treatment on the pattern obtained in the step 4.

In the step 5, the reaction of the resin precursor in the photosensitive composition layer (for example, ring closure reaction of the polyimide precursor and the polybenzoxazole precursor) is promoted, and the resin can be formed.

It is preferable that the step 5 is at least a step of performing heating.

A temperature and a time of the heating treatment can be appropriately selected according to the type of the resin and the precursor thereof.

The temperature of the heating treatment is preferably 120° C. to 400° C., more preferably 150° C. to 400° C., and still more preferably 180° C. to 350° C.

The time of the heating treatment is preferably 1 to 24 hours, more preferably 1 to 12 hours, and still more preferably 1 to 9 hours.

The heating treatment may be performed in any of an air environment or a nitrogen replacement environment.

The atmospheric pressure under the heating treatment environment is preferably 8.1 kPa or more, and more preferably 50.66 kPa or more. The upper limit thereof is preferably 121.6 kPa or less, more preferably 111.46 kPa or less, and still more preferably 101.3 kPa or less.

A light source and an exposure amount of the exposure treatment can be appropriately selected according to the type of the photosensitive component in the photosensitive composition layer.

Examples of the light source include an ultra-high pressure mercury lamp, a high pressure mercury lamp, a metal halide lamp, and a light emitting diode (LED).

An exposure amount is preferably 5 to 2,000 mJ/cm² and more preferably 10 to 2,000 mJ/cm².

### [Other Steps]

The pattern forming method may include other steps in addition to the above-described steps.

Examples of the other steps include the following steps.

### <Cover Film Peeling Step>

In a case where the transfer film in the above-described pattern forming method includes a cover film, it is preferable that the pattern forming method includes a step of peeling off the cover film of the transfer film.

As a method of peeling off the cover film, and a known method can be adopted.

### <Step of Reducing Visible Light Reflectivity>

In a case where the base material is a substrate having a conductive layer, the above-described pattern forming method may further include a step of performing a treatment of reducing a visible light reflectivity of the conductive layer.

In a case where the above-described base material is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Examples of a suitable aspect of the treatment of reducing the visible light reflectivity include aspects described in paragraphs 0017 to 0025 of JP2014-150118A, and paragraphs 0041, 0042, 0048, and 0058 of JP2013-206315A, the contents of which are incorporated in the present specification.

### <Etching Step>

In a case where the base material is a substrate having a conductive layer, the above-described pattern forming method may include a step (etching step) of etching, using the formed pattern (film) as an etching resist film, the conductive layer in a region where the etching resist film is not disposed.

Examples of a method of the etching treatment include a method by wet etching, which is described in paragraphs 0048 to 0054 of JP2010-152155A, and a method by dry etching such as a known plasma etching.

In the above-described pattern forming method, it is also preferable to use a substrate having a plurality of conductive layers on both surfaces, and sequentially or simultaneously form patterns on the conductive layers formed on both surfaces.

With such a configuration, it is possible to form a first conductive pattern on one surface of the substrate and form a second conductive pattern on the other surface. The patterns may be formed on both surfaces of the base material by a roll-to-roll method.

It is also preferable that the above-described pattern forming method is used in a manufacturing method of a laminate having a pattern. The manufacturing method of a laminate having a pattern is not particularly limited as long as it includes the above-described pattern forming method.

### [Laminate]

The laminate is a laminate having a pattern obtained by the above-described pattern forming method. The laminate includes, for example, a base material and a pattern having a via, which is formed from an exposed photosensitive composition layer.

The above-described laminate may further include at least one layer of a wiring layer or an insulating layer.

It is also preferable that the laminate includes, on a surface of the pattern opposite to the base material side, the wiring layer and the insulating layer in this order from the pattern side. The film formed from the transfer pattern according to the embodiment of the present invention has excellent adhesiveness to the layer laminated on the surface side opposite to the base material, and in the above-described aspect, it can more effectively suppress the migration in the wiring layer.

The above-described insulating layer may be a layer formed from the transfer film according to the embodiment of the present invention.

A method of forming the wiring layer and the insulating layer described above is not particularly limited, and a known method can be used. As a method of forming the wiring layer, for example, the same method as a step Z6 described later can be used. As a method of forming the insulating layer, for example, a method of applying and curing a composition for forming an insulating layer, a method of using the transfer film, and the pattern forming method according to the embodiment of the present invention can be used.

The above-described laminate is used, for example, in a semiconductor device. Examples of the semiconductor device include various semiconductor devices such as a semiconductor package provided in an electrical product (for example, a computer, a mobile phone, a digital camera, and a television) and a vehicle (for example, a motorcycle, an automobile, a train, a ship, and an airplane).

### [Manufacturing Method of Semiconductor Package]

The above-described pattern forming method can be suitably applied to a manufacturing method of a semiconductor package. Examples of the manufacturing method of a semiconductor package include a known manufacturing method such as a manufacturing method of a build-up substrate.

Specific examples thereof include a manufacturing method including steps Z1 to Z6 in this order.
Step Z1: step of bonding the transfer film and a base material, in a state in which the photosensitive composition layer of the transfer film faces the base material, on a substrate having a conductive layer
Step Z2: step of removing the temporary support from the laminate obtained in the step Z1
Step Z3: step of exposing the photosensitive composition layer from the water-soluble resin layer side of the laminate from which the temporary support is removed in a patterned manner
Step Z4: step of removing the water-soluble resin layer and an unexposed photosensitive composition layer from the pattern-exposed laminate to form a pattern having a via
Step Z5: step of performing at least one of a heating treatment or an exposure treatment on the obtained pattern
Step Z6: step of forming a circuit pattern on the pattern

Examples of each of the steps Z1 to Z5 described above include the above-described steps 1 to 5.

### [Step Z6]

The step Z6 is a step of forming a circuit pattern on the above-described pattern.

As a method of forming the circuit pattern, a semi-additive process is preferable from the viewpoint that a fine wiring can be formed. Examples of the semi-additive process include the following methods.

First, a seed layer is formed by performing an electroless copper plating treatment on the entire surface of the via bottom, the via wall surface, and the pattern after the above-described step Z4 or step Z5 using a palladium catalyst or the like.

The above-described seed layer is for forming a power feeding layer for performing the electrolytic copper plating, and a thickness of the seed layer is preferably 0.1 to 2.0 μm. In a case where the thickness of the above-described seed layer is 0.1 μm or more, the tendency is that the deterioration in connection insulating reliability during the electroless copper plating can be suppressed; and in a case where the thickness of the above-described seed layer is 2.0 μm or less, the tendency is that it is not necessary to increase the etching amount in a case of flash-etching the seed layer between the wirings, and the damage to the wirings during the etching can be suppressed.

The electroless copper plating treatment is performed by precipitating metallic copper on the surface of the pattern having a via by a reaction between copper ions and a reducing agent.

Examples of the electroless plating treatment method and the electrolytic plating treatment method include known plating treatment methods.

As the catalyst in the electroless plating treatment step, a palladium-tin mixed catalyst is preferable. An average primary particle diameter of the above-described mixed catalyst is preferably 10 nm or less. In addition, as the plating composition of the electroless plating treatment step, it is preferable to contain hypophosphorous acid as a reducing agent.

Examples of a commercially available product of the electroless copper plating liquid include “MSK-DK” manufactured by Atotech Japan K.K. and “SULKACUP (registered trademark) PEA ver. 4” series manufactured by Uemura Kogyo Co., Ltd.

It is also preferable that, after the electroless copper plating treatment, the surface of the photosensitive composition layer in the transfer film on the side opposite to the temporary support is thermocompression-bonded to the electroless copper plating by a roll laminator.

From the viewpoint that the thickness of the above-described photosensitive composition layer can be higher than the wiring height after the electro copper plating, the thickness of the photosensitive composition layer is preferably 5 to 30 μm.

After the thermal compression bonding of the transfer film, the photosensitive composition layer is exposed through, for example, a mask on which a desired wiring pattern is drawn. Examples of the above-described exposing method include the exposing method in the step 3. The temporary support may be peeled off before or after the exposure.

After the exposure, the water-soluble resin layer and the exposed photosensitive composition layer are developed using a developer to form a pattern. In addition, after the above-described pattern is formed, the development residue may be removed using a plasma or the like.

After the development, the copper circuit layer is formed and the via filling is performed by performing the electro copper plating.

After the electro copper plating, the pattern is peeled off using an alkaline aqueous solution or an amine-based release agent.

After the pattern is peeled off, the seed layer between the wirings is removed (flash etching).

The flash etching is performed using, for example, an oxidative solution containing sulfuric acid and an acidic solution such as hydrogen peroxide. Examples of the oxidative solution include “SAC” manufactured by JCU CORPORATION and “CPE-800” manufactured by MITSUBISHI GAS CHEMICAL COMPANY, INC. After the flash etching, removal of palladium or the like adhering to a part between the wirings is performed as necessary. The removal of palladium can be performed using an acidic solution such as nitric acid and hydrochloric acid.

It is preferable to perform a post-baking treatment after the peeling of the pattern or after the flash etching step. The post-baking treatment sufficiently thermosets the unreacted thermosetting component, and further improves the electrical insulation reliability, the curing characteristics, and the adhesive strength with the plated copper.

The thermal curing conditions are preferably a curing temperature of 150° C. to 240° C. and a curing time of 15 to 500 minutes.

The manufacturing method of a semiconductor package may include a roughening step of roughening a pattern having a via. It is preferable that the above-described roughening step is performed after the above-described step Z5 and before the above-described step Z6. By performing the roughening step, the above-described patterned surface can be roughened, and the adhesiveness with the circuit wiring can be improved. In addition, the smearing can be removed at the same time.

Examples of the roughening step include a known desmutting treatment, and a treatment of bringing the roughening liquid into contact is preferable.

Examples of the roughening liquid include a roughening liquid containing chromium and sulfuric acid, a roughening liquid containing an alkali permanganate (for example, a sodium permanganate roughening liquid or the like), and a roughening liquid containing sodium fluoride, chromium, and sulfuric acid.

Each of the above-described steps is repeated according to the required number of layers, thereby manufacturing a semiconductor package. In addition, it is preferable that a solder resist is formed on the outermost layer.

### [Semiconductor Package]

The above-described transfer film is suitably used for manufacturing a semiconductor package.

The semiconductor package is not particularly limited as long as it includes a layer formed from the transfer film; and it preferably includes the above-described laminate and it is more preferably manufactured by the above-described manufacturing method of a semiconductor package.

In the semiconductor package, the layer formed from the transfer film may be used as an insulating film, or may be used as an organic interposer or an insulating film in a so-called build-up substrate.

### EXAMPLES

Hereinafter, the present invention will be described in more detail with reference to Examples.

The material, the amount used, the proportion, the process contents, the process procedure, and the like shown in the following examples can be appropriately changed, within a range not departing from the gist of the present invention. Therefore, the scope of the present invention should not be construed as being limited to Examples shown below.

In Examples, unless otherwise specified, “%” means “% by mass”.

### [Preparation of Composition for Forming Water-Soluble Resin Layer]

A mixture was obtained to have the formulation amount (formulation amount of solid content ratio) shown in Table 1, and the mixture was diluted with a mixed solvent of ion exchange water/methanol (manufactured by Mitsubishi Gas Chemical Company, Inc.)=40/60 (mass ratio) as a solvent such that the concentration of solid contents was 5%.

Hereinafter, various components contained in the water-soluble resin layer are shown.

### [Water-Soluble Resin]

PVA: polyvinyl alcohol, Kuraray Poval PVA-205, manufactured by Kuraray
PVP: polyvinylpyrrolidone, Polyvinylpyrrolidone K-30, manufactured by Nippon Shokubai Co., Ltd.
HPMC: hydroxypropyl methyl cellulose, METOLOSE 60SH-03, manufactured by Shin-Etsu Chemical Co., Ltd.

### [Surfactant]

Surfactant A: silicone-based surfactant, BYK-345, manufactured by BYK Chemie Japan
Surfactant B: silicone-based surfactant, BYK-348, manufactured by BYK Chemie Japan
Surfactant C: silicone-based surfactant, EXP.S-506, manufactured by DIC Corporation
Surfactant D: fluorine-based surfactant, MEGAFACE (registered trademark) F-444, manufactured by DIC Corporation

TABLE 1

| | 1 | 2 | 3 | 4 | 5 | 6 | 7 |
|---|---|---|---|---|---|---|---|
| PVA | 66.50 | 66.50 | 66.50 | 66.50 | 68.00 | 68.00 | 68.00 |
| PVP | 31.00 | 31.00 | 31.00 | 31.00 | 30.45 | 30.40 | 30.00 |
| HPMC | 1.00 | 1.00 | 1.00 | 1.00 | 0.05 | 0.10 | 0.50 |
| Surfactant A | 1.50 | — | — | — | 1.50 | 1.50 | 1.50 |
| Surfactant B | — | 1.50 | — | — | — | — | — |
| Surfactant C | — | — | 1.50 | — | — | | — |
| Surfactant D | — | — | — | 1.50 | — | | |

### [Preparation of Composition for Forming Photosensitive Composition Layer]

Various components were mixed to have the formulation amounts (formulation amounts of solid content ratio) shown in Table 2 to prepare a mixture. Next, the above-described mixture was diluted with a mixed solvent having a concentration of 25% by mass of methyl ethyl ketone (MEK) and a concentration of 75% by mass of N-methylpyrrolidone (NMP) such that the concentration of solid contents was 30% by mass.

Hereinafter, various components contained in the composition for forming a photosensitive composition layer are shown.

Various components contained in the composition are shown below.

### [Resin (Specific Compound or Comparative Compound)]

Resin A: polyimide precursor, resin synthesized by a synthesis method of a resin A, which will be described below
Resin B: polyimide precursor, resin synthesized by a synthesis method of a resin B, which will be described below
Resin C: polyphenylene ether resin having a branched structure, resin synthesized by a synthesis method of a resin C, which will be described below
Resin D: phenol resin, TR4020G, manufactured by ASAHI YUKIZAI CORPORATION
Resin E: epoxy resin, ZX1059 (mixture (1:1) of bisphenol A-type epoxy resin and bisphenol F-type epoxy resin), manufactured by NIPPON STEEL Chemical & Material Co., Ltd.
Resin Z: acrylic resin, styrene/acrylic acid=71% by mass/29% by mass, resin synthesized by a synthesis method of a resin Z, which will be described below

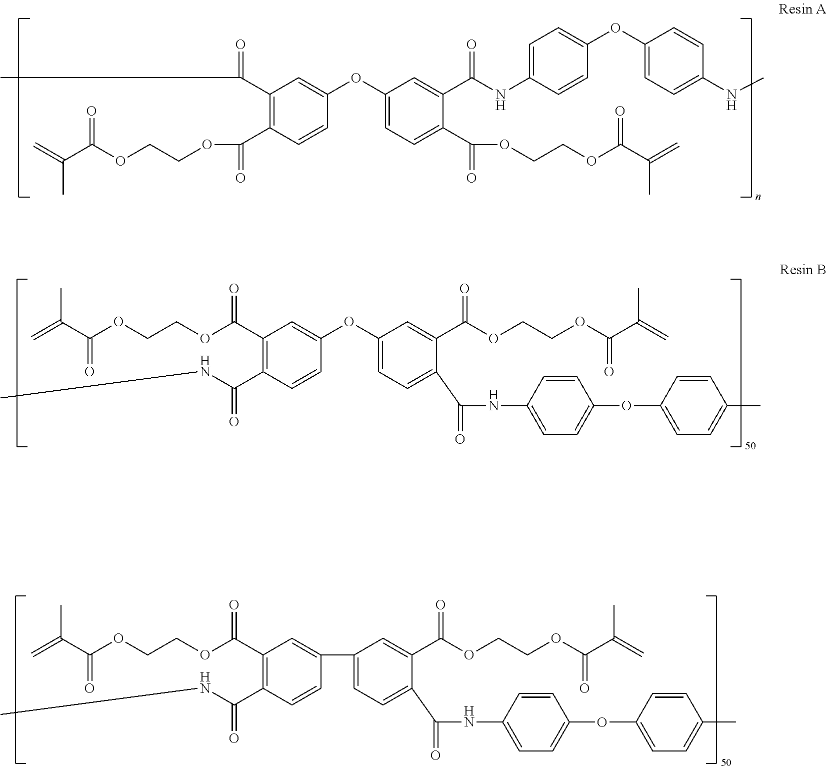

### <Synthesis Method of Resin A>

4,4′-oxydiphthalic acid anhydride (used after being dried at 140° C. for 12 hours; 20.0 g, 64.5 mmol), 2-hydroxyethyl methacrylate (16.8 g, 129 mmol), hydroquinone (0.05 g), pyridine (20.4 g, 258 mmol), and diethylene glycol dimethyl ether (100 g) were mixed, and the mixture was stirred at 60° C. for 18 hours to obtain a reaction mixture (a diester of 4,4′-oxydiphthalic acid and 2-hydroxyethyl methacrylate). Next, a chlorination reaction using thionyl chloride (SOCl₂) was carried out on the obtained diester to obtain a reaction mixture.

Next, a solution obtained by dissolving 4,4′-diaminodiphenyl ether (11.08 g, 58.7 mmol) in N-methylpyrrolidone (100 mL) was added dropwise to the reaction mixture at −5° C. to 0° C. over 20 minutes. The reaction mixture was reacted at 0° C. for 1 hour, ethanol (70 g) was added thereto, and the mixture was stirred at room temperature for 1 day. The obtained reaction solution was added to water (5 L), and the mixture was stirred at a speed of 5,000 rpm for 15 minutes to obtain a precipitate which was a crude polymer. The precipitate collected from the above-described mixture was stirred in water (3 L) for 30 minutes, and collected by filtration again. The obtained precipitate was dried at 45° C. for 3 days under reduced pressure to obtain the resin A which was a polyimide precursor. A weight-average molecular weight (Mw) of the resin A was 18,000.

### <Synthesis Method of Resin B>

4,4′-oxydiphthalic acid dianhydride (77.6 g) and diphenyl-3,3′,4,4′-tetracarboxylic acid dianhydride (73.6 g) were charged into a 2 L separable flask, 2-hydroxyethyl methacrylate (134.0 g) and γ-butyrolactone (400 mL) were added thereto with stirring at room temperature, and pyridine (79.1 g) further was added thereto to obtain a reaction mixture. After heat generation due to the reaction was stopped, the reaction mixture was further allowed to cool to room temperature and left to stand for 16 hours. Next, a solution obtained by dissolving dicyclohexylcarbodiimide (DCC, 206.3 g) in γ-butyrolactone (180 mL) was added to the reaction mixture over 40 minutes with stirring under ice cooling. Subsequently, a liquid obtained by suspending 4,4′-oxydianiline (ODA, Mw=200.24, 93.0 g) in γ-butyrolactone (350 mL) was added thereto over 60 minutes with stirring. After further stirring at room temperature for 2 hours, ethanol (30 mL) was added thereto and stirred for 1 hour, and then γ-butyrolactone (400 mL) was added thereto. The precipitate formed in the reaction mixture was removed by filtration to obtain a reaction solution. The obtained reaction solution was added to ethyl alcohol (3 L) to obtain a precipitate as a crude polymer. The obtained crude polymer was collected by filtration and dissolved in tetrahydrofuran (1.5 L) to obtain a crude polymer solution. The obtained crude polymer solution was purified using an anion exchange resin (Amberlite TM15, manufactured by Organo Corporation) to obtain a polymer solution. The obtained polymer solution was added dropwise to water (28 L) to precipitate a polymer, and the obtained precipitate was collected by filtration and then vacuum-dried to obtain the resin B as a powdery polyimide precursor. A weight-average molecular weight (Mw) of the resin B was 22,000. A content of the imide group in the polyimide obtained from the resin B was 27.4% by mass per repeating unit.

### <Synthesis Method of Resin C>

1.3 g of di-μ-hydroxo-bis[(N,N,N′,N′-tetramethylethylenediamine)copper(II)] chloride (Cu/TMEDA) and 1.59 mL of tetramethylethylenediamine (TMEDA) were charged into a two-neck eggplant flask and sufficiently dissolved, and oxygen was supplied thereto at 10 mL/min. 52.5 g of 2,6-dimethylphenol and 6.5 g of 2-allylphenol were dissolved in 0.75 L of toluene to prepare a raw material solution. The raw material solution was added dropwise to the above-described eggplant flask, and the reaction was carried out at 45° C. for 5 hours while stirring at a rotation speed of 600 rpm. After completion of the reaction, the precipitate was reprecipitated with a mixed solution of 10 L of methanol and 11 mL of concentrated hydrochloric acid, collected by filtration, and dried at 70° C. for 24 hours to obtain the resin C. A number-average molecular weight of the resin C was 25,000, and a weight-average molecular weight thereof was 66,000.

### <Synthesis Method of Resin Z>

1-methoxy-2-acetoxypropane (PGMEA, 60 parts) and propylene glycol monomethyl ether (PGME, 240 parts) were charged into a flask to prepare a mixed solution. The obtained mixed solution was heated to 90° C. while stirring at a stirring speed of 250 rpm.

Styrene (71 parts by mass) and acrylic acid (29 parts by mass) were mixed and diluted with PGMEA (60 parts by mass) to obtain a dropping liquid (1).

V-601 (dimethyl 2,2′-azobis(2-methylpropionate), 9.637 parts by mass) was dissolved in PGMEA (136.56 parts) to obtain a dropping liquid (2).

Next, the dropping liquid (1) and the dropping liquid (2) were simultaneously added dropwise to the flask containing the above-described mixed solution heated to 90° C. over 3 hours. After the dropwise addition, V-601 (2.401 parts by mass) was added to the flask three times every hour. Thereafter, stirring was further carried out at 90° C. for 3 hours. Thereafter, the obtained reaction solution was diluted with PGMEA to obtain a solution containing the resin Z (concentration of solid contents: 36.3% by mass).

### [Polymerizable Compound]

D-1: compound having the following structure

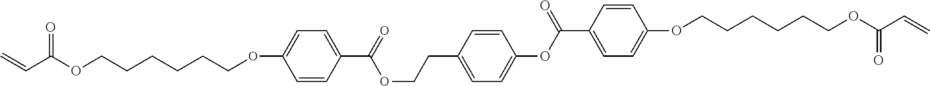 [SMILES: C=CC(=O)OCCCCCCOc1ccc(C(=O)OCCc2ccc(OC(=O)c3ccc(OCCCCCCOC(=O)C=C)cc3)cc2)cc1]

DPHA: dipentaerythritol hexaacrylate, manufactured by Tokyo Chemical Industry Co., Ltd.
SR205NS: bifunctional polymerizable compound, manufactured by Sartomer Inc.
SR209: bifunctional polymerizable compound, manufactured by Sartomer Inc.

### [Photopolymerization Initiator]

Oxe-01: Irgacure OXE-01, manufactured by BASF SE

### [Filler]

NHM-5N: silicon dioxide, surface-treated product, average particle diameter: 100 nm, manufactured by TOKUYAMA CORPORATION
YA050C-MJE: spherical silica slurry, surface-treated product, average particle diameter: 50 nm, MEK slurry with a concentration of solid contents of 50% by mass, manufactured by Admatechs Co., Ltd.

### [Other Additives]

C-1: thermal-base generator, compound having the following structure

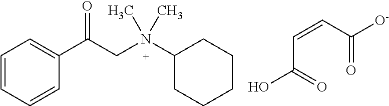

EPEG: plasticizer, ethyl phthalyl ethyl glycolate, manufactured by Tokyo Chemical Industry Co., Ltd.
HAT: rust inhibitor, 5-amino-1H-tetrazole
Z-1: jER828; bisphenol A-type epoxy resin, manufactured by Mitsubishi Chemical Corporation
   Z-2: HPC8000-65T; dicyclopentadiene-type diphenol compound (polycyclopentadiene-type diphenol compound) active ester curing agent, toluene solution having a concentration of solid contents of 65% by mass, manufactured by DIC Corporation
S-506: silicone-based surfactant, manufactured by DIC Corporation
F-551A: fluorine-based surfactant, manufactured by DIC Corporation

### [Production of Transfer Film]

The prepared composition for forming a water-soluble resin layer was applied onto a temporary support (QS62, manufactured by Toray Industries, Inc., 31 μm-thick PET film), and dried at 100° C. to form a water-soluble resin layer shown in Table 2 below. The coating amount was adjusted such that the film thickness after drying was the value shown in Table 2.

The prepared composition for forming a photosensitive composition layer was applied onto the formed water-soluble resin layer, and dried at 100° C. to form a photosensitive composition layer. The coating amount was adjusted such that the film thickness after drying was the value shown in Table 2.

Next, a protective film (manufactured by Oji F-Tex Co., Ltd., polypropylene film, FG-201, thickness: 30 μm) was bonded to the surface of the photosensitive composition layer opposite to the water-soluble resin layer side, thereby obtaining a transfer film of each of Examples and Comparative Examples.

### [Calculation of Surface Free Energy]

A surface free energy was calculated according to the following procedure.

A copper-clad polyimide film (METALOYAL, manufactured by Toray Industries, Inc.) was used as a base material, and the transfer film of each of Examples and Comparative Examples was laminated on the base material such that the photosensitive composition layer faced the base material, thereby obtaining a laminate including the base material, the photosensitive composition layer, the water-soluble resin layer, and the temporary support in this order. The lamination was carried out under the following conditions using a vacuum laminator manufactured by MCK Co., Ltd.: a substrate temperature of 50° C., a rubber roller temperature of 100° C., a linear pressure of 3 N/cm, and a transportation speed of 1 m/min.

The temporary support was peeled off from the obtained laminate, and the entire surface was exposed (high pressure mercury lamp, integrated illuminance measured with an illuminance meter at a wavelength of 365 nm: 1,000 mJ/cm²) from the exposed water-soluble resin layer side. After the exposure, the water-soluble resin layer was removed by immersing the laminate in a 1% sodium carbonate aqueous solution for 60 seconds. The obtained laminate was heated at 200° C. for 1.5 hours in an oven adjusted to a nitrogen atmosphere to form a cured layer, thereby producing an evaluation sample.

Contact angles with respect to pure water and methylene iodide were measured using a contact angle meter CA-A (manufactured by Kyowa Interface Science Co., Ltd.) for the surface of the cured layer of the obtained evaluation sample opposite to the base material side. The above-described contact angle was measured three times at different positions, and an average value thereof was adopted. The surface free energy and the polarity component of the surface free energy were calculated from the obtained contact angle according to the Owens and Wendt method described above.

### [Evaluation]

Using the obtained transfer film of each of Examples and Comparative Examples, pattern formability and film thinning, and heat resistance, dielectric characteristics, insulating film adhesiveness, and migration suppression of the obtained film were evaluated.

### [Heat Resistance]

The evaluation sample obtained in [Calculation of surface free energy] described above was subjected to a peeling treatment by being immersed in 2 M hydrochloric acid for 8 hours, rinsed (with pure water at normal temperature for 1 hour), and then peeled off from the base material to obtain a self-supporting film derived from the photosensitive composition layer. In a case where the self-supporting film could not be peeled off in the above-described peeling treatment, the film was further immersed in a 2 M hydrochloric acid for approximately 1 week and peeled off. The obtained self-supporting film was cut into a strip shape.

The produced self-supporting film was cut into a strip shape (19 mm×5 mm), and a coefficient of thermal expansion was measured using a TMA (thermomechanical analyzer, “TMA450EM” manufactured by TA Instruments). The measurement conditions were set to a temperature rising rate of 10° C./min, a distance between chucks of 10 mm, and a load of 40 mN. The coefficient of thermal expansion was a value (ppm/K) in a range of 50° C. to 150° C. during temperature rising, and was obtained as an average value in a case of being measured three times. The heat resistance was evaluated according to the following evaluation standard from the obtained coefficient of thermal expansion.

### <Evaluation Standard>

A: coefficient of thermal expansion was 25 ppm/K or less.
B: coefficient of thermal expansion was more than 25 ppm/K and 60 ppm/K or less.
C: coefficient of thermal expansion was more than 60 ppm/K.

### [Dielectric Characteristics]

A self-supporting film derived from the photosensitive composition layer was obtained by the same procedure as the evaluation of [Heat resistance] described above. The obtained self-supporting film was cut into a size of 2 cm×3 cm, and relative permittivity was measured using a 28 GHz split cylinder type resonator (manufactured by Kanto Electronics Application & Development Inc.). The measurement was carried out on three samples, and an average value thereof was used. The dielectric characteristics were evaluated according to the following evaluation standard from the obtained relative permittivity.

### <Evaluation Standard>

A: relative permittivity was 2.9 or less.
B: relative permittivity was more than 2.9 and 3.5 or less.
C: relative permittivity was more than 3.5.

### [Insulating Film Adhesiveness]

The insulating film adhesiveness, which is adhesiveness between the cured layer formed from the photosensitive composition layer and the insulating film formed on the cured layer, was evaluated according to the following procedure.

The photosensitive composition layer of the produced transfer film was laminated on the surface of the cured layer of the evaluation sample obtained in [Calculation of surface free energy] described above such that the photosensitive composition layer faced the cured layer, thereby obtaining a laminate including the base material, the cured layer, the photosensitive composition layer, the water-soluble resin layer, and the temporary support in this order. The above-described lamination was carried out using a vacuum laminator manufactured by MCK Co., Ltd. under conditions of a nip pressure of 0.6 MPa, a rubber roller temperature of 100° C., and a transport speed of 1 m/min.

The temporary support was peeled off from the obtained laminate, and the entire surface was exposed (high pressure mercury lamp, integrated illuminance measured with an illuminance meter at a wavelength of 365 nm: 1,000 mJ/cm²) from the exposed water-soluble resin layer side. After the exposure, the water-soluble resin layer was removed by immersing the laminate in a 1% sodium carbonate aqueous solution for 60 seconds. The obtained laminate was heated at 200° C. for 1.5 hours in an oven adjusted to a nitrogen atmosphere to produce an adhesiveness evaluation sample including the base material, the cured layer, and the cured layer (insulating film) in this order.

A cross-cut test (JIS K 5600) was carried out on the obtained adhesiveness evaluation sample according to the following procedure.

Six cuts at 1 mm intervals were formed on the surface of the adhesiveness evaluation sample opposite to the base material side, and then six cuts at 1 mm intervals orthogonal to the formed cuts were formed to form a 25-square crosshatch having a square of 1 mm.

Next, a tape (CT-24 manufactured by NICHIBAN CO., LTD., adhesion force: more than 4 N/cm) was bonded to the crosshatch, and the peeling condition of the cured layer on the outermost surface side during peeling was confirmed. The insulating film adhesiveness was evaluated according to the following evaluation standard from the peeling condition.

### <Evaluation Standard>

A: number of squares in which half or more of the area of one square was peeled off was 10 or less.
B: number of squares in which half or more of the area of one square was peeled off was more than 10, or the transfer film could not be laminated and the adhesiveness evaluation sample could not be produced.

### [Pattern Formability]

Pattern formability of the photosensitive composition layer was evaluated according to the following procedure.

A copper-clad polyimide film (METALOYAL, manufactured by Toray Industries, Inc.) was used as a base material, and the transfer film was laminated on the base material such that the photosensitive composition layer faced the base material, thereby obtaining a laminate having the base material, the photosensitive composition layer, the water-soluble resin layer, and the temporary support in this order. The above-described lamination was carried out using a vacuum laminator manufactured by MCK Co., Ltd. under conditions of a nip pressure of 0.6 MPa, a rubber roller temperature of 100° C., and a transport speed of 1 m/min.

The temporary support was peeled off from the obtained laminate.

The exposed water-soluble resin layer side was exposed (high pressure mercury lamp, integrated illuminance measured with an illuminance meter at a wavelength of 365 nm: 100 mJ/cm²) through a mask having five sets of patterns of L/S=5/5, 10/10, 15/15, 20/20, 25/25, and 30/30 (μm/μm).

After the exposure, the water-soluble resin layer was removed by immersing the laminate in a 1% sodium carbonate aqueous solution for 60 seconds, the laminate was immersed in cyclopentanone for 120 seconds, and then immersed in PGMEA for 30 seconds to remove the non-exposed portion of the photosensitive composition layer, thereby forming a pattern.

In Comparative Example 2, after the exposure, the water-soluble resin layer and the non-exposed portion of the photosensitive composition layer were removed by immersing the laminate in a 1% sodium carbonate aqueous solution for 60 seconds to form a pattern, and the cross-sectional shape of the pattern was confirmed.

The cross-sectional shapes of five patterns having the same L/S size as the film thickness of the photosensitive composition layer before the exposure (aspect ratio: 1:1 (=film thickness before exposure of photosensitive composition layer: L/S size); for example, in a case of a film thickness before the exposure of 10 μm, five patterns of L/S=10/10 (μm/μm)) were observed using a scanning electron microscope (manufactured by Hitachi, Ltd., S-4800). The pattern formability was evaluated according to the following evaluation standard from the state of the observed pattern.

### <Evaluation Standard>

A: number of patterns in which the defect was confirmed was 1 or less.
B: number of patterns in which the defect was confirmed was 2 or more.

### [Film Thinning]

The film thinning was evaluated according to the following evaluation standard from the film thickness of the pattern observed in the evaluation of [Pattern formability] described above and the film thickness before the exposure. The film thinning is a characteristic indicating a degree of reduction in the film thickness of the formed pattern with respect to the film thickness of the photosensitive composition layer before the exposure related to the transfer film, and it is preferable that the film thinning is low.

### <Evaluation Standard>

A: film thickness of the pattern was 80% or more with respect to the film thickness before the exposure.
B: film thickness of the pattern was less than 80% with respect to the film thickness before the exposure.

### [Migration Suppression]

Cu/Ti sputtering was carried out on the surface of the cured layer of the evaluation sample obtained in [Calculation of surface free energy] described above to form a seed layer having a thickness of 0.2 μm. A resist layer was formed on the seed layer, and the resist layer was subjected to pattern exposure and development to form a resist pattern of L/S=10/10 (km/km). Next, an electrolytic plating treatment was carried out using a copper sulfate aqueous solution, the resist was peeled off by immersing the sample in a 3% sodium hydroxide aqueous solution, and the exposed seed layer was removed by immersing the sample in an aqueous solution containing 0.1% sulfuric acid and 0.1% hydrogen peroxide. As a result, a laminate in which a comb-shaped copper pattern of L/S=10/10 μm was formed on the surface of the cured layer was obtained. The total film thickness of the above-described copper pattern and the seed layer was 1 μm.

The transfer film was laminated on the obtained laminate such that the surface side on which the copper pattern was formed and the photosensitive composition layer faced each other, and the cured layer was formed by the same method as [Calculation of surface free energy] described above to produce a migration evaluation sample. A voltage application portion of the copper pattern was protected by bonding a Kapton tape before the lamination of the transfer film, and the Kapton tape was removed for each photosensitive composition layer to prevent the formation of the cured layer.

10 samples of the above-described migration evaluation sample were produced, and the migration suppression was evaluated according to the following evaluation standard from the number of samples in which the migration occurred in a case of applying a voltage of 3.0 V and installing the samples in a chamber at 130° C. and 80% RH (relative humidity) for 168 hours using a HAST tester. In a sample in which the initial resistance value measured at room temperature was 1×10¹⁴Ω or more, the time at which migration occurred at a time when the resistance value was 1×10³Ω or less was counted as occurrence of the migration. In practical use, it is preferable that the migration suppression is evaluated as A or higher.

### <Evaluation Standard>

A: number of samples in which the migration occurred was 2 or less.
B: number of samples in which the migration occurred was 3 to 5.
C: number of samples in which the migration occurred was 6 to 10.

### Result

Tables 2 to 4 below show the configurations and evaluation results of each transfer film.

In the tables, “amount” represents a content (% by mass) with respect to the total solid content of the photosensitive composition layer.

Table 3 is a continuation of Table 2. For example, regarding the transfer film of Example 1, a water-soluble resin layer of type 1 was provided; the photosensitive composition layer contained the resin A, Oxe-01, C-1, EPEG, HAT, and S-506; the above-described surface free energy was 40 mJ/m²; and the polarity component of the surface free energy was 10 mJ/m².

TABLE 2

| | Water-soluble resin | | | Photosensitive composition layer | | | | | | | | |
|---|---|---|---|---|---|---|---|---|---|---|---|---|
| | layer | | | | | Polymerizable compound | | | Photopolymerization | | | |
| | | Film | | Resin | | | Molecular | | initiator | | Filler | |
| | Type | thickness | | Type | Amount | Type | weight | Amount | Type | Amount | Type | Amount |
| Example 1 | 1 | 1 | μm | Resin A | 75.2% | — | — | — | Oxe-01 | 1.0% | — | — |
| Example 2 | 1 | 1 | μm | Resin A | 70.2% | D-1 | 687 | 5.0% | Oxe-01 | 1.0% | — | — |
| Example 3 | 1 | 1 | μm | Resin A | 70.2% | DPHA | 579 | 5.0% | Oxe-01 | 1.0% | — | — |
| Example 4 | 1 | 1 | μm | Resin A | 22.0% | D-1 | 687 | 3.2% | Oxe-01 | 1.0% | NHM-5N | 50.0% |
| Example 5 | 1 | 1 | μm | Resin A | 75.2% | SR205NS | 286 | 22.9% | Oxe-01 | 1.0% | — | — |
| Example 6 | 1 | 1 | μm | Resin A | 75.2% | SR209 | 330 | 22.9% | Oxe-01 | 1.0% | — | — |
| Example 7 | 1 | 1 | μm | Resin A | 75.2% | SR205NS | 286 | 15.0% | Oxe-01 | 1.0% | — | — |
| Example 8 | 1 | 1 | μm | Resin A | 75.2% | SR209 | 330 | 15.0% | Oxe-01 | 1.0% | | |
| Example 9 | 1 | 1 | μm | Resin A | 16.0% | SR205NS | 286 | 11.1% | Oxe-01 | 1.0% | YA050C-MJE | 71.0% |
| Example 10 | 1 | 1 | μm | Resin A | 16.0% | SR209 | 330 | 11.1% | Oxe-01 | 1.0% | YA050C-MJE | 71.0% |
| Example 11 | 1 | 1 | μm | Resin A | 16.0% | SR205NS | 286 | 7.0% | Oxe-01 | 1.0% | YA050C-MJE | 71.0% |
| Example 12 | 1 | 1 | μm | Resin A | 16.0% | SR209 | 330 | 7.0% | Oxe-01 | 1.0% | YA050C-MJE | 71.0% |
| Example 13 | 1 | 1 | μm | Resin B | 75.2% | — | — | — | Oxe-01 | 1.0% | — | — |
| Example 14 | 1 | 1 | μm | Resin B | 75.2% | SR205NS | 286 | 15.0% | Oxe-01 | 1.0% | — | — |
| Example 15 | 1 | 1 | μm | Resin B | 75.2% | SR209 | 330 | 15.0% | Oxe-01 | 1.0% | — | — |
| Example 16 | 1 | 1 | μm | Resin B | 16.0% | SR205NS | 286 | 11.1% | Oxe-01 | 1.0% | YA050C-MJE | 71.0% |
| Example 17 | 1 | 1 | μm | Resin B | 16.0% | SR209 | 330 | 11.1% | Oxe-01 | 1.0% | YA050C-MJE | 71.0% |
| Example 18 | 2 | 1 | μm | Resin A | 75.2% | — | — | — | Oxe-01 | 1.0% | — | — |
| Example 19 | 2 | 1 | μm | Resin A | 22.0% | D-1 | 687 | 3.2% | Oxe-01 | 1.0% | NHM-5N | 50.0% |
| Example 20 | 2 | 1 | μm | Resin A | 75.2% | SR205NS | 286 | 15.0% | Oxe-01 | 1.0% | — | — |
| Example 21 | 2 | 1 | μm | Resin A | 16.0% | SR205NS | 286 | 11.1% | Oxe-01 | 1.0% | YA050C-MJE | 71.0% |
| Example 22 | 3 | 1 | μm | Resin A | 75.2% | — | — | — | Oxe-01 | 1.0% | — | — |
| Example 23 | 3 | 1 | μm | Resin A | 22.0% | D-1 | 687 | 3.2% | Oxe-01 | 1.0% | NHM-5N | 50.0% |
| Example 24 | 3 | 1 | μm | Resin A | 75.2% | SR205NS | 286 | 15.0% | Oxe-01 | 1.0% | — | — |
| Example 25 | 3 | 1 | μm | Resin A | 16.0% | SR205NS | 286 | 11.1% | Oxe-01 | 1.0% | YA050C-MJE | 71.0% |
| Example 26 | 4 | 1 | μm | Resin A | 75.2% | — | — | — | Oxe-01 | 1.0% | — | — |
| Example 27 | 4 | 1 | μm | Resin A | 22.0% | D-1 | 687 | 3.2% | Oxe-01 | 1.0% | NHM-5N | 50.0% |
| Example 28 | 4 | 1 | μm | Resin A | 75.2% | SR205NS | 286 | 15.0% | Oxe-01 | 1.0% | — | — |
| Example 29 | 4 | 1 | μm | Resin A | 16.0% | SR205NS | 286 | 11.1% | Oxe-01 | 1.0% | YA050C-MJE | 71.0% |
| Example 30 | 5 | 1 | μm | Resin A | 75.2% | — | — | — | Oxe-01 | 1.0% | — | — |
| Example 31 | 5 | 1 | μm | Resin A | 22.0% | D-1 | 687 | 3.2% | Oxe-01 | 1.0% | NHM-5N | 50.0% |
| Example 32 | 5 | 1 | μm | Resin A | 75.2% | SR205NS | 286 | 15.0% | Oxe-01 | 1.0% | — | — |
| Example 33 | 5 | 1 | μm | Resin A | 16.0% | SR205NS | 286 | 11.1% | Oxe-01 | 1.0% | YA050C-MJE | 71.0% |
| Example 34 | 6 | 1 | μm | Resin A | 75.2% | — | — | — | Oxe-01 | 1.0% | — | — |
| Example 35 | 6 | 1 | μm | Resin A | 22.0% | D-1 | 687 | 3.2% | Oxe-01 | 1.0% | NHM-5N | 50.0% |
| Example 36 | 6 | 1 | μm | Resin A | 75.2% | SR205NS | 286 | 15.0% | Oxe-01 | 1.0% | — | — |
| Example 37 | 6 | 1 | μm | Resin A | 16.0% | SR205NS | 286 | 11.1% | Oxe-01 | 1.0% | YA050C-MJE | 71.0% |
| Example 38 | 7 | 1 | μm | Resin A | 75.2% | — | — | — | Oxe-01 | 1.0% | — | — |
| Example 39 | 7 | 1 | μm | Resin A | 22.0% | D-1 | 687 | 3.2% | Oxe-01 | 1.0% | NHM-5N | 50.0% |
| Example 40 | 7 | 1 | μm | Resin A | 75.2% | SR205NS | 286 | 15.0% | Oxe-01 | 1.0% | — | — |
| Example 41 | 7 | 1 | μm | Resin A | 16.0% | SR205NS | 286 | 11.1% | Oxe-01 | 1.0% | YA050C-MJE | 71.0% |
| Example 42 | 1 | 3 | μm | Resin A | 75.2% | — | — | — | Oxe-01 | 1.0% | — | — |
| Example 43 | 1 | 3 | μm | Resin A | 22.0% | D-1 | 687 | 3.2% | Oxe-01 | 1.0% | NHM-5N | 50.0% |
| Example 44 | 1 | 3 | μm | Resin A | 75.2% | SR205NS | 286 | 15.0% | Oxe-01 | 1.0% | — | — |
| Example 45 | 1 | 3 | μm | Resin A | 16.0% | SR205NS | 286 | 11.1% | Oxe-01 | 1.0% | YA050C-MJE | 71.0% |
| Example 46 | 1 | 0.5 | μm | Resin A | 75.2% | — | — | — | Oxe-01 | 1.0% | — | — |
| Example 47 | 1 | 0.5 | μm | Resin A | 22.0% | D-1 | 687 | 3.2% | Oxe-01 | 1.0% | NHM-5N | 50.0% |
| Example 48 | 1 | 0.5 | μm | Resin A | 75.2% | SR205NS | 286 | 15.0% | Oxe-01 | 1.0% | — | — |
| Example 49 | 1 | 0.5 | μm | Resin A | 16.0% | SR205NS | 286 | 11.1% | Oxe-01 | 1.0% | YA050C-MJE | 71.0% |
| Example 50 | 1 | 1 | μm | Resin C | 60.6% | DPHA | 579 | 15.0% | Oxe-01 | 1.0% | — | — |
| Example 51 | 1 | 1 | μm | Resin D | 51.0% | DPHA | 579 | 5.0% | Oxe-01 | 1.0% | — | — |
| Example 52 | 1 | 1 | μm | Resin E | 35.6% | DPHA | 579 | 5.0% | Oxe-01 | 1.0% | — | — |
| Comparative | — | — | | Resin A | 75.2% | — | — | — | Oxe-01 | 1.0% | — | — |
| Example 1 | | | | | | | | | | | | |
| Comparative | 1 | 1 | μm | Resin Z | 58.8% | DPHA | 579 | 40% | Oxe-01 | 1.0% | — | — |

Example 2

TABLE 3

| | Photosensitive composition layer | | | | | | | | | | | | | |
|---|---|---|---|---|---|---|---|---|---|---|---|---|---|---|
| | | | | | | | | | | | | | | Polarity component |
| | Thermal-base | | | | | | | | | | Film | | Surface free | of surface |
| | generator | | Plasticizer | | Others | | | | Surfactant | | thick- | | energy | free energy |
| | Name | Amount | Name | Amount | Name | Amount | Name | Amount | Name | Amount | ness | | [mJ/m²] | [mJ/m²] |
| Example 1 | C-1 | 0.4% | EPEG | 22.9% | HAT | 0.3% | — | — | S-506 | 0.2% | 10 | μm | 40 | 10 |
| Example 2 | C-1 | 0.4% | EPEG | 22.9% | HAT | 0.3% | — | — | S-506 | 0.2% | 10 | μm | 45 | 15 |
| Example 3 | C-1 | 0.4% | EPEG | 22.9% | HAT | 0.3% | — | — | S-506 | 0.2% | 10 | μm | 50 | 20 |
| Example 4 | C-1 | 0.4% | EPEG | 22.9% | HAT | 0.3% | — | — | S-506 | 0.2% | 10 | μm | 60 | 25 |
| Example 5 | C-1 | 0.4% | — | — | HAT | 0.3% | — | — | S-506 | 0.2% | 10 | μm | 40 | 10 |
| Example 6 | C-1 | 0.4% | — | — | HAT | 0.3% | — | — | S-506 | 0.2% | 10 | μm | 40 | 10 |
| Example 7 | C-1 | 0.4% | EPEG | 7.9% | — | 0.3% | — | — | S-506 | 0.2% | 10 | μm | 40 | 10 |
| Example 8 | C-1 | 0.4% | EPEG | 7.9% | — | 0.3% | — | — | S-506 | 0.2% | 10 | μm | 40 | 10 |
| Example 9 | C-1 | 0.4% | — | — | HAT | 0.3% | — | — | S-506 | 0.2% | 10 | μm | 60 | 25 |
| Example 10 | C-1 | 0.4% | — | — | HAT | 0.3% | — | — | S-506 | 0.2% | 10 | μm | 60 | 25 |
| Example 11 | C-1 | 0.4% | EPEG | 4.1% | — | 0.3% | — | — | S-506 | 0.2% | 10 | μm | 60 | 25 |
| Example 12 | C-1 | 0.4% | EPEG | 4.1% | — | 0.3% | — | — | S-506 | 0.2% | 10 | μm | 60 | 25 |
| Example 13 | C-1 | 0.4% | EPEG | 22.9% | HAT | 0.3% | — | — | S-506 | 0.2% | 10 | μm | 40 | 10 |
| Example 14 | C-1 | 0.4% | EPEG | 7.9% | — | 0.3% | — | — | S-506 | 0.2% | 10 | μm | 40 | 10 |
| Example 15 | C-1 | 0.4% | EPEG | 7.9% | — | 0.3% | — | — | S-506 | 0.2% | 10 | μm | 40 | 10 |
| Example 16 | C-1 | 0.4% | — | — | HAT | 0.3% | — | — | S-506 | 0.2% | 10 | μm | 60 | 25 |
| Example 17 | C-1 | 0.4% | — | — | HAT | 0.3% | — | — | S-506 | 0.2% | 10 | μm | 60 | 25 |
| Example 18 | C-1 | 0.4% | EPEG | 22.9% | HAT | 0.3% | — | — | S-506 | 0.2% | 10 | μm | 40 | 10 |
| Example 19 | C-1 | 0.4% | EPEG | 22.9% | HAT | 0.3% | — | — | S-506 | 0.2% | 10 | μm | 60 | 25 |
| Example 20 | C-1 | 0.4% | EPEG | 7.9% | — | 0.3% | — | — | S-506 | 0.2% | 10 | μm | 40 | 10 |
| Example 21 | C-1 | 0.4% | — | — | HAT | 0.3% | — | — | S-506 | 0.2% | 10 | μm | 60 | 25 |
| Example 22 | C-1 | 0.4% | EPEG | 22.9% | HAT | 0.3% | — | — | S-506 | 0.2% | 10 | μm | 40 | 10 |
| Example 23 | C-1 | 0.4% | EPEG | 22.9% | HAT | 0.3% | — | — | S-506 | 0.2% | 10 | μm | 60 | 25 |
| Example 24 | C-1 | 0.4% | EPEG | 7.9% | — | 0.3% | — | — | S-506 | 0.2% | 10 | μm | 40 | 10 |
| Example 25 | C-1 | 0.4% | — | — | HAT | 0.3% | — | — | S-506 | 0.2% | 10 | μm | 60 | 25 |
| Example 26 | C-1 | 0.4% | EPEG | 22.9% | HAT | 0.3% | — | — | S-506 | 0.2% | 10 | μm | 40 | 10 |
| Example 27 | C-1 | 0.4% | EPEG | 22.9% | HAT | 0.3% | — | — | S-506 | 0.2% | 10 | μm | 60 | 25 |
| Example 28 | C-1 | 0.4% | EPEG | 7.9% | — | 0.3% | — | — | S-506 | 0.2% | 10 | μm | 40 | 10 |
| Example 29 | C-1 | 0.4% | — | — | HAT | 0.3% | — | — | S-506 | 0.2% | 10 | μm | 60 | 25 |
| Example 30 | C-1 | 0.4% | EPEG | 22.9% | HAT | 0.3% | — | — | S-506 | 0.2% | 10 | μm | 40 | 10 |
| Example 31 | C-1 | 0.4% | EPEG | 22.9% | HAT | 0.3% | — | — | S-506 | 0.2% | 10 | μm | 60 | 25 |
| Example 32 | C-1 | 0.4% | EPEG | 7.9% | — | 0.3% | — | — | S-506 | 0.2% | 10 | μm | 40 | 10 |
| Example 33 | C-1 | 0.4% | — | — | HAT | 0.3% | — | — | S-506 | 0.2% | 10 | μm | 60 | 25 |
| Example 34 | C-1 | 0.4% | EPEG | 22.9% | HAT | 0.3% | — | — | S-506 | 0.2% | 10 | μm | 40 | 10 |
| Example 35 | C-1 | 0.4% | EPEG | 22.9% | HAT | 0.3% | — | — | S-506 | 0.2% | 10 | μm | 60 | 25 |
| Example 36 | C-1 | 0.4% | EPEG | 7.9% | — | 0.3% | — | — | S-506 | 0.2% | 10 | μm | 40 | 10 |
| Example 37 | C-1 | 0.4% | — | — | HAT | 0.3% | — | — | S-506 | 0.2% | 10 | μm | 60 | 25 |
| Example 38 | C-1 | 0.4% | EPEG | 22.9% | HAT | 0.3% | — | — | S-506 | 0.2% | 10 | μm | 40 | 10 |
| Example 39 | C-1 | 0.4% | EPEG | 22.9% | HAT | 0.3% | — | — | S-506 | 0.2% | 10 | μm | 60 | 25 |
| Example 40 | C-1 | 0.4% | EPEG | 7.9% | — | 0.3% | — | — | S-506 | 0.2% | 10 | μm | 40 | 10 |
| Example 41 | C-1 | 0.4% | — | — | HAT | 0.3% | — | — | S-506 | 0.2% | 10 | μm | 60 | 25 |
| Example 42 | C-1 | 0.4% | EPEG | 22.9% | HAT | 0.3% | — | — | S-506 | 0.2% | 25 | μm | 40 | 10 |
| Example 43 | C-1 | 0.4% | EPEG | 22.9% | HAT | 0.3% | — | — | S-506 | 0.2% | 25 | μm | 60 | 25 |
| Example 44 | C-1 | 0.4% | EPEG | 7.9% | — | 0.3% | — | — | S-506 | 0.2% | 25 | μm | 40 | 10 |
| Example 45 | C-1 | 0.4% | — | — | HAT | 0.3% | — | — | S-506 | 0.2% | 25 | μm | 60 | 25 |
| Example 46 | C-1 | 0.4% | EPEG | 22.9% | HAT | 0.3% | — | — | S-506 | 0.2% | 5 | μm | 40 | 10 |
| Example 47 | C-1 | 0.4% | EPEG | 22.9% | HAT | 0.3% | — | — | S-506 | 0.2% | 5 | μm | 60 | 25 |
| Example 48 | C-1 | 0.4% | EPEG | 7.9% | — | 0.3% | — | — | S-506 | 0.2% | 5 | μm | 40 | 10 |
| Example 49 | C-1 | 0.4% | — | — | HAT | 0.3% | — | — | S-506 | 0.2% | 5 | μm | 60 | 25 |
| Example 50 | — | — | EPEG | 22.9% | HAT | 0.3% | — | — | F-551A | 0.2% | 10 | μm | 50 | 20 |
| Example 51 | — | — | EPEG | 22.9% | HAT | 0.3% | Z-1 | 19.6% | F-551A | 0.2% | 10 | μm | 60 | 25 |
| Example 52 | — | — | EPEG | 22.9% | HAT | 0.3% | Z-2 | 35.0% | F-551A | 0.2% | 10 | μm | 60 | 25 |
| Comparative | C-1 | 0.4% | EPEG | 22.9% | HAT | 0.3% | — | — | S-506 | 0.2% | 10 | μm | 20 | 2 |
| Example 1 | | | | | | | | | | | | | | |
| Comparative | — | — | — | — | — | — | — | — | S-506 | 0.2% | 10 | μm | 50 | 20 |

Example 2

TABLE 4

| | Evaluation | | | | | |
|---|---|---|---|---|---|---|
| | Heat | Dielectric | Insulating film | Pattern | Film | Migration |
| | resistance | characteristics | adhesiveness | formability | thinning | suppression |
| Example 1 | B | B | A | A | A | A |
| Example 2 | B | B | A | A | A | A |
| Example 3 | B | B | A | A | A | A |
| Example 4 | A | A | A | A | A | A |
| Example 5 | B | B | A | A | A | A |
| Example 6 | B | B | A | A | A | A |
| Example 7 | B | B | A | A | A | A |
| Example 8 | B | B | A | A | A | A |
| Example 9 | A | B | A | A | A | A |
| Example 10 | A | B | A | A | A | A |
| Example 11 | A | B | A | A | A | A |
| Example 12 | A | B | A | A | A | A |
| Example 13 | B | B | A | A | A | A |
| Example 14 | B | B | A | A | A | A |
| Example 15 | B | B | A | A | A | A |
| Example 16 | A | B | A | A | A | A |
| Example 17 | A | B | A | A | A | A |
| Example 18 | B | B | A | A | A | A |
| Example 19 | A | A | A | A | A | A |
| Example 20 | B | B | A | A | A | A |
| Example 21 | A | B | A | A | A | A |
| Example 22 | B | B | A | A | A | A |
| Example 23 | A | A | A | A | A | A |
| Example 24 | B | B | A | A | A | A |
| Example 25 | A | B | A | A | A | A |
| Example 26 | B | B | A | A | A | A |
| Example 27 | A | A | A | A | A | A |
| Example 28 | B | B | A | A | A | A |
| Example 29 | A | B | A | A | A | A |
| Example 30 | B | B | A | A | A | A |
| Example 31 | A | A | A | A | A | A |
| Example 32 | B | B | A | A | A | A |
| Example 33 | A | B | A | A | A | A |
| Example 34 | B | B | A | A | A | A |
| Example 35 | A | A | A | A | A | A |
| Example 36 | B | B | A | A | A | A |
| Example 37 | A | B | A | A | A | A |
| Example 38 | B | B | A | A | A | A |
| Example 39 | A | A | A | A | A | A |
| Example 40 | B | B | A | A | A | A |
| Example 41 | A | B | A | A | A | A |
| Example 42 | B | B | A | A | A | A |
| Example 43 | A | A | A | A | A | A |
| Example 44 | B | B | A | A | A | A |
| Example 45 | A | B | A | A | A | A |
| Example 46 | B | B | A | A | A | A |
| Example 47 | A | A | A | A | A | A |
| Example 48 | B | B | A | A | A | A |
| Example 49 | A | B | A | A | A | A |
| Example 50 | B | B | A | A | A | A |
| Example 51 | B | B | A | A | A | A |
| Example 52 | B | B | A | A | A | A |
| Comparative | B | B | B | B | C | B |
| Example 1 | | | | | | |
| Comparative | C | C | A | A | A | C |
| Example 2 | | | | | | |

From the results shown in the tables, it was found that the transfer film according to the embodiment of the present invention was capable of forming a film which contributes to suppressing the migration between the wirings.

In a case where the photosensitive composition layer contained the filler, it was found that the heat resistance was more excellent (comparison of Examples 1 to 8).

In a case where the content of the filler was 60.0% by mass or less, it was found that the dielectric characteristics were more excellent (comparison of Example 4 with Examples 9 to 12).

### Examples 53 to 56

A transfer film was produced by the same method as in Example 1, except that various components were mixed to have the formulation amounts (formulation amounts of solid content ratio) shown in Tables 5 and 6. The pattern formability and film thinning, and as the heat resistance, dielectric characteristics, insulating film adhesiveness, and migration suppression of the obtained film were evaluated according to the same procedure as in Example 1.

In addition, fine pattern formability was evaluated according to the following procedure.

Details of the photopolymerization initiator, the chain transfer agent, the polymerization inhibitor, and the sensitizer used in Examples 54 to 56 are shown below.
B-1: TR-HABI 101, manufactured by Tronly
B-2: TR-HABI 103, manufactured by Tronly
B-3: TR-HABI 107, manufactured by Tronly
E-1: chain transfer agent, compound shown below

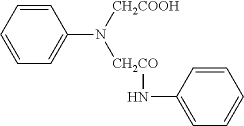

MEHQ: polymerization inhibitor, 4-methoxyphenol
EAB-F: sensitizer, 4,4′-bis(diethylamino)benzophenone

### [Fine Pattern Formability]

Cross-sectional shapes of five patterns having an aspect ratio (film thickness before the exposure of the photosensitive composition layer: L/S size) of L/S size with respect to the film thickness before the exposure of photosensitive composition layer of 10:3.5 (for example, in a case of a film thickness before exposure of 10 μm, a pattern of L/S=3.5/3.5 (μm/μm)) were observed using a scanning electron microscope (manufactured by Hitachi, Ltd., S-4800) for the evaluation method of [Pattern formability] described above. Fine pattern formability was evaluated according to the following evaluation standard from the state of the observed pattern.

### <Evaluation Standard>

A: number of patterns in which the defect was confirmed was 1 or less.
B: number of patterns in which the defect was confirmed was 2 or more.

Tables 5 to 7 below show the configurations and evaluation results of each transfer film. In the tables, the meaning of “Amount” is the same as in Tables 2 to 4.

Table 6 is a continuation of Table 5.

TABLE 5

| | | | Photosensitive composition layer | | | | |
|---|---|---|---|---|---|---|---|
| | | | | | Polymerizable | | |
| | Water-soluble resin layer | | | | compound | | |
| | | Film | Resin | | | Molecular | |
| | Type | thickness | Type | Amount | Type | weight | Amount |
| Example | 1 | 1 μm | Resin | 75.2% | SR205NS | 286 | 22.9% |
| 53 | | | A | | | | |
| Example | 1 | 1 μm | Resin | 71.8% | SR205NS | 286 | 18.8% |
| 54 | | | A | | | | |
| Example | 1 | 1 μm | Resin | 71.8% | SR205NS | 286 | 18.8% |
| 55 | | | A | | | | |
| Example | 1 | 1 μm | Resin | 71.8% | SR205NS | 286 | 18.8% |
| 56 | | | A | | | | |

| Photosensitive composition layer | | | |
|---|---|---|---|
| Photopoly- | | | |
| merization | Chain transfer | Polymerization | |
| initiator | agent | inhibitor | Sensitizer |

| | Type | Amount | Type | Amount | Type | Amount | Type | Amount |
|---|---|---|---|---|---|---|---|---|
| Example | Oxe-01 | 1.0% | — | — | — | — | — | — |
| 53 | | | | | | | | |
| Example | B-1 | 6.3% | E-1 | 0.5% | MEHQ | 0.3% | EAB-F | 0.1% |
| 54 | | | | | | | | |
| Example | B-2 | 6.3% | E-1 | 0.5% | MEHQ | 0.3% | EAB-F | 0.1% |
| 55 | | | | | | | | |
| Example | B-3 | 6.3% | E-1 | 0.5% | MEHQ | 0.3% | EAB-F | 0.1% |
| 56 | | | | | | | | |

TABLE 6

| | Photosensitive composition layer | | | | | | | | | | | | |
|---|---|---|---|---|---|---|---|---|---|---|---|---|---|
| | Thermal-base | | | | | | | | | | | Surface | Polarity component |
| | generator | | Plasticizer | | Others | | | | Surfactant | | Film | free energy | of surface free energy |
| | Name | Amount | Name | Amount | Name | Amount | Name | Amount | Name | Amount | thickness | [mJ/m²] | [mJ/m²] |
| Example 53 | C-1 | 0.4% | — | — | HAT | 0.3% | — | — | S-506 | 0.2% | 10 μm | 40 | 10 |
| Example 54 | C-1 | 1.7% | — | — | HAT | 0.3% | — | — | S-506 | 0.2% | 10 μm | 40 | 10 |
| Example 55 | C-1 | 1.7% | — | — | HAT | 0.3% | — | — | S-506 | 0.2% | 10 μm | 40 | 10 |
| Example 56 | C-1 | 1.7% | — | — | HAT | 0.3% | — | — | S-506 | 0.2% | 10 μm | 40 | 10 |

TABLE 7

| | Evaluation | | | | | | |
|---|---|---|---|---|---|---|---|
| | Heat | Dielectric | Insulating film | Pattern | Film | Migration | Fine pattern |
| | resistance | characteristics | adhesiveness | formability | thinning | suppression | formability |
| Example 53 | B | B | A | A | A | A | B |
| Example 54 | B | B | A | A | A | A | A |
| Example 55 | B | B | A | A | A | A | A |
| Example 56 | B | B | A | A | A | A | A |

From the comparison of Examples 53 to 56, it was found that, in a case where the photopolymerization initiator included the compound represented by Formula (P1), the fine pattern formability was more excellent.

From the comparison of Examples 53 to 56, it was found that, in a case where the photosensitive composition layer contained the chain transfer agent, the fine pattern formability was more excellent.

From the comparison of Examples 53 to 56, it was found that, in a case where the photosensitive composition layer contained the polymerization inhibitor, the fine pattern formability was more excellent.

From the comparison of Examples 53 to 56, it was found that, in a case where the photosensitive composition layer contained the sensitizer, the fine pattern formability was more excellent.

### [Production of Semiconductor Package]

The transfer film of each of Examples was laminated on both surfaces of a glass epoxy base material (CCL-EL190T, thickness: 1.0 mm, manufactured by Mitsubishi Gas Chemical Company, Inc.) on which a circuit pattern was formed. The lamination was carried out under the following conditions using a vacuum laminator manufactured by MCK Co., Ltd.: a substrate temperature of 50° C., a rubber roller temperature of 100° C., a linear pressure of 3 N/cm, and a transportation speed of 1 m/min.

The temporary support was peeled off from the obtained laminate, and the laminate was subjected to pattern exposure (high pressure mercury lamp, integrated illuminance measured with an illuminance meter at a wavelength of 365 nm: 500 mJ/cm²) from the water-soluble resin layer side through a mask having a light shielding portion of Φ100 μm. After the exposure, the water-soluble resin layer was removed by immersing the laminate in a 1% sodium carbonate aqueous solution for 60 seconds, the laminate was immersed in cyclopentanone for 120 seconds, and then immersed in PGMEA for 30 seconds to remove the non-exposed portion of the photosensitive composition layer, thereby forming a pattern having a via of Φ100 μm. After the above-described pattern was subjected to a heating treatment (200° C., 90 minutes), the residue was removed with a sodium permanganate aqueous solution as a roughening liquid, and an electroless plating treatment was carried out. Next, a resist pattern was formed at a predetermined position using a known dry film resist, and an electrolytic plating treatment was carried out. Next, the resist pattern was peeled off with a stripper.

Finally, a seed layer etching treatment was carried out to form a copper wire on the cured layer.

The above-described process from the lamination to the heating treatment was carried out three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was found that the obtained semiconductor package substrate normally operated.

### EXPLANATION OF REFERENCES

12: temporary support
14: water-soluble resin layer
16: photosensitive composition layer
100: transfer film

What is claimed is:

1. A transfer film comprising, in the following order:
a temporary support;
a water-soluble resin layer; and
a photosensitive composition layer,
wherein the photosensitive composition layer contains at least one specific compound selected from the group consisting of a polyimide precursor, a polyimide, a polybenzoxazole precursor, a polybenzoxazole, a phenol resin, an epoxy resin, a polyphenylene ether resin, a silicone resin, a benzocyclobutene resin, a fluorene resin, a liquid crystal polymer, a polyethersulfone, a polyarylate, a polyetherimide, a polybenzimidazole, a polyphenylsulfone, a polycarbonate, an acrylonitrile-butadiene-styrene copolymer resin, and a polyphenylene sulfide.

2. The transfer film according to claim 1,
wherein the photosensitive composition layer contains a photopolymerization initiator.

3. The transfer film according to claim 1,
wherein a surface free energy measured by a measurement X is 40 mJ/m² or more,
the measurement X: in a case where a laminate is obtained by bonding the transfer film and a base material in a state in which the photosensitive composition layer of the transfer film faces the base material, the temporary support is peeled off from the laminate, an entire surface of the photosensitive composition layer is exposed from an exposed water-soluble resin layer side to remove the water-soluble resin layer, and an exposed photosensitive composition layer is heated at 200° C. for 1.5 hours in a nitrogen atmosphere to obtain a cured layer, a surface free energy of a surface of the cured layer, opposite to the base material side, is measured.

4. The transfer film according to claim 3,
wherein a polarity component of the surface free energy is 10 mJ/m² or more.

5. The transfer film according to claim 1,
wherein at least one of a requirement 1 or a requirement 2 is satisfied,
the requirement 1: the specific compound has an ethylenically unsaturated double bond,
the requirement 2: the photosensitive composition layer contains a compound having an ethylenically unsaturated double bond.

6. The transfer film according to claim 5,
wherein a molecular weight of the compound having an ethylenically unsaturated double bond is 800 or less.

7. The transfer film according to claim 1,
wherein the specific compound includes at least one selected from the group consisting of a polyimide precursor, a polyimide, a polybenzoxazole precursor, and a polybenzoxazole.

8. The transfer film according to claim 2,
wherein the photopolymerization initiator includes a compound represented by Formula (P1), 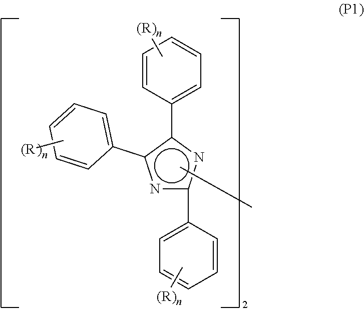
in Formula (P1), R's each independently represent a substituent, and n's each independently represent an integer of 0 to 5.

9. The transfer film according to claim 8,
wherein the specific compound includes at least one selected from the group consisting of a polyimide precursor, a polyimide, a polybenzoxazole precursor, and a polybenzoxazole.

10. The transfer film according to claim 8,
wherein the photosensitive composition layer contains a chain transfer agent.

11. The transfer film according to claim 1,
wherein the photosensitive composition layer contains a filler.

12. The transfer film according to claim 11,
wherein the filler includes at least one selected from the group consisting of silicon dioxide, boron nitride, barium sulfate, and silicate.

13. The transfer film according to claim 11,
wherein an average particle diameter of the filler is 300 nm or less.

14. The transfer film according to claim 11,
wherein an average particle diameter of the filler is 150 nm or less.

15. The transfer film according to claim 11,
wherein a content of the filler is 30.0% by mass or more with respect to a total mass of the photosensitive composition layer.

16. The transfer film according to claim 11,
wherein a content of the filler is 90.0% by mass or less with respect to a total mass of the photosensitive composition layer.

17. The transfer film according to claim 1,
wherein a film thickness of the photosensitive composition layer is 3 to 30 μm.

18. The transfer film according to claim 1,
wherein a film thickness of the water-soluble resin layer is 5 μm or less.

19. The transfer film according to claim 1,
wherein the water-soluble resin layer contains polyvinyl alcohol.

20. The transfer film according to claim 19,
wherein a content of the polyvinyl alcohol is 15.0% to 90.0% by mass with respect to a total mass of the water-soluble resin layer.

21. The transfer film according to claim 1,
wherein the water-soluble resin layer contains hydroxypropyl methyl cellulose.

22. The transfer film according to claim 1,
wherein the transfer film is used for forming an insulating film.

23. A pattern forming method comprising:
a step 1 of obtaining a laminate by bonding the transfer film according to claim 1 and a base material in a state in which the photosensitive composition layer of the transfer film faces the base material;
a step 2 of removing the temporary support from the laminate obtained in the step 1;
a step 3 of exposing the photosensitive composition layer from the water-soluble resin layer side of the laminate from which the temporary support is removed in the step 2 in a patterned manner; and
a step 4 of removing the water-soluble resin layer and an unexposed photosensitive composition layer from the pattern-exposed laminate to form a pattern having a via.

24. A laminate comprising:
a pattern formed by the pattern forming method according to claim 23.

25. A semiconductor package comprising:
the laminate according to claim 24.
